(19) United States
(12) Patent Application Publication
(10) Pub. No.: US 2026/0190848 A1
(43) Pub. Date: Jul. 2, 2026

(54) ORGANIC ELECTROLUMINESCENT DOPANT MATERIAL AND LIGHT-EMITTING DEVICE

(71) Applicant: JILIN OLED OPTICAL AND ELECTRONIC MATERIALS CO., LTD., Changchun (CN)

(72) Inventors: Hui WANG, Changchun (CN); Xiaolong LI, Changchun (CN); Xingwang LANG, Changchun (CN); Weihan XU, Changchun (CN); Zhenyang LU, Changchun (CN); Sheng SUN, Changchun (CN); Haishan FEI, Changchun (CN)

(21) Appl. No.: 19/423,448

(22) Filed: Dec. 17, 2025

(30) Foreign Application Priority Data
Dec. 30, 2024 (CN) 202411959417.0

(51) Int. Cl. H10K 85/30; C07B 59/00; C07F 15/00; C09K 11/06; H10K 50/12; H10K 50/15; H10K 50/16; H10K 85/40

(52) U.S. Cl. CPC H10K 85/342; C07B 59/004; C07F 15/0033; C09K 11/06; H10K 85/40; C07B 2200/05; C09K 2211/1007; C09K 2211/1011; C09K 2211/1037; C09K 2211/185; H10K 50/12; H10K 50/156; H10K 50/166

(57) ABSTRACT

The present invention provides an organic electroluminescent dopant material and a light-emitting device. By introducing a deuterium atom group at a specific position on a thiophene ring and adjusting the molecular spacing and bond energy of the obtained compound, a dopant material having a specific atomic structure is obtained. After the obtained organic compound having a specific atomic structure is used in the organic electroluminescent device, the driving voltage is reduced, and the luminous efficiency of the device is improved.

The present disclosure claims priority to Chinese Patent Application No. 202411959417.0 filed with China National Intellectual Property Administration on Dec. 30, 2024 and entitled “ORGANIC ELECTROLUMINESCENT DOPANT MATERIAL AND LIGHT-EMITTING DEVICE”, which is incorporated herein by reference in its entirety.

### TECHNICAL FIELD

The present invention relates to the technical field of organic electroluminescent materials, in particular to an organic electroluminescent material doping and a light-emitting device, and in particular to an organic electroluminescent material as a dopant material in an organic light-emitting diode and a related electronic device, and a light-emitting device.

### BACKGROUND

Organic semiconductor materials belong to a new type of photoelectric materials, which originate in large scale from doped polyethylene with a conductivity of up to copper level, which was discovered in 1977 by Shirakawa Hideki, A. Heeger and A. McDiamid. Subsequently, in 1987, C. Tang et al. of Kodak Company invented an organic small molecule light-emitting diode (OLED). OLEDs, which emit light when a voltage is applied to a device containing an OLED organic thin film, are increasingly gaining attention in flat panel display, lighting, and backlight applications.

Deuteration strategies have been widely used in the photoelectric material industry since 2000. A light-emitting material of an OLED gradually becomes a key material that affects a display effect and a service life of the OLED due to a characteristic of a fast attenuation speed. In OLED matrix materials, hydrogen/deuterium exchange of unstable heterocyclic carbon-hydrogen bonds can extend device lifetime, and replacing unstable C—H bonds in the main structure with C-D bonds can increase device lifetime by about 5 times without loss of efficiency. Therefore, the deuterated material can not only improve the luminous efficiency and flexible display of the OLED device, but also have the characteristics of improving brightness and having a long half-life.

Deuterium is non-toxic, non-radioactive, and safe for human body. More importantly, the C-D bond is more stable (6-9 times) than the C—H bond. When a deuterium atom is introduced into the material, the spin-orbit coupling effect of the light-emitting molecule is enhanced, thereby facilitating the generation of phosphorescence and increasing the quantum efficiency thereof. In addition, after the deuterium atom is introduced, since the bond length of the carbon-deuterium bond is short and the bond energy is large, the energy of the light-emitting material is reduced, so that the stability and life span of the light-emitting device are significantly enhanced.

It is pointed out in the document “Isotope Effect of Host Material on Device Stability of Thermally Activated Delayed Fluorescence Organic Light-Emitting Diodes” that the green TADF-OLED based on the deuterated compound (PYD₂ Cz-d16) shows more balanced carrier transport characteristics than the non-deuterated compound (PYD₂ Cz), so as to obtain better device stability. At an initial luminance of 1000 cd/m², LT95 is 134 h, which is 1.7 times that of the compound (PYD₂ Cz). It can be seen that the lifetime of the device can be improved by deuteration, but the improvement of the driving voltage and the device efficiency is unexpected.

The document “Synthesis of all-deuterated tris(2-phenylpyridine) iridium for highly stable electrophosphorescence: the ‘deuterium effect’” also confirms that the deuteration of Ir(ppy)₃ only slightly improves the photophysical properties thereof, but has a significant impact on the stability and lifetime of the device. At an initial luminance of 1000 cd/m², the device based on Ir(ppy)₃-D24 has a high current density of 20 times and a service life 6 times longer than that of Ir(ppy)₃. Through infrared spectrum comparison and DFT calculation, it can be proved that Ir(ppy)₃-D24 has much lower internal energy than Ir(ppy)₃, especially C-D stretching and bending, which are the main factors for improving the stability and prolonging the service life of the device, which is referred to as “deuterium effect”.

That is, it can be known that deuteration of the OLED material can improve the service life of the OLED device, but how to improve the driving voltage and luminous efficiency of the device is a technical problem that needs to be solved urgently.

### SUMMARY

In view of the above, in order to solve the above problems, the present invention provides an organic electroluminescent dopant material and a light-emitting device. By introducing a deuterium atom group at a specific position on a thiophene ring and adjusting the molecular spacing and bond energy of the obtained compound, a dopant material having a specific atomic structure is obtained. After the obtained organic compound having a specific atomic structure is used in the organic electroluminescent device, the driving voltage is reduced, and the luminous efficiency of the device is improved.

In order to achieve the aforementioned objectives, the present invention provides the following technical solutions:
The present invention provides an organic electroluminescent dopant material, which is a compound having a structure shown in formula I: M(L_{A})₂(L_{B}),
wherein M is a metal;
L_{A} and L_{B} are both ligands, and L_{A} and L_{B} have general formulas shown below:

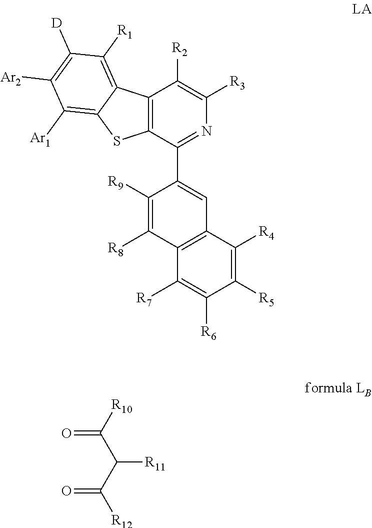

wherein Ar₁ and Ar₂ are independently selected from any one of —F, —CN, —CH₃, —CD₃, —CT₃, —CF₃, —CH₂F, —CHF₂, -Ge(Me)₃, —Si(Me)₃, substituted or unsubstituted C₂-C₆ alkyl, substituted or unsubstituted C₃-C₂₀ cycloalkyl, substituted or unsubstituted C₆-C₁₀ aryl, and substituted or unsubstituted 4- to 8-membered aromatic heterocyclyl;
R₁, R₂, R₃, R₄, R₅, R₆, R₇, R₈, and R₉ are independently selected from any one of —H, —F, —CN, —CH₃, —CD₃, —CT₃, —CF₃, —CH₂F, —CHF₂, —Ge(Me)₃, —Si(Me)₃, substituted or unsubstituted C₂-C₆ alkyl, substituted or unsubstituted C₃-C₂₀ cycloalkyl, substituted or unsubstituted C₆-C₁₀ aryl, and substituted or unsubstituted 4- to 8-membered aromatic heterocyclyl;
R₁₀, R₁₁, and R₁₂ are independently selected from any one of —H, -D (deuterium), -T (tritium), —F, —CN, —CH₃, —CD₃, —CT₃, —CF₃, —CH₂F, —CHF₂, —Ge(Me)₃, —Si(Me)₃, substituted or unsubstituted C₂-C₆ alkyl, substituted or unsubstituted C₃-C₂₀ cycloalkyl, substituted or unsubstituted C₆-C₁₀ aryl, and substituted or unsubstituted 4- to 8-membered aromatic heterocyclyl.

According to an embodiment of the present invention, Mis preferably metal Ir.

According to an embodiment of the present invention, Ar₁ and Ar₂ are independently selected from any one of —F, —CN, —CF₃, —CH₂F, —CHF₂, methyl, ethyl, n-propyl, isopropyl, n-butyl, isobutyl, tert-butyl, cyclopropyl, cyclobutyl, cyclopentyl, cyclohexyl, terphenyl, fluorenyl, phenanthryl, triphenylenyl, furyl, benzofuryl, benzothienyl, dibenzofuryl, dibenzothienyl, and the following substituents:

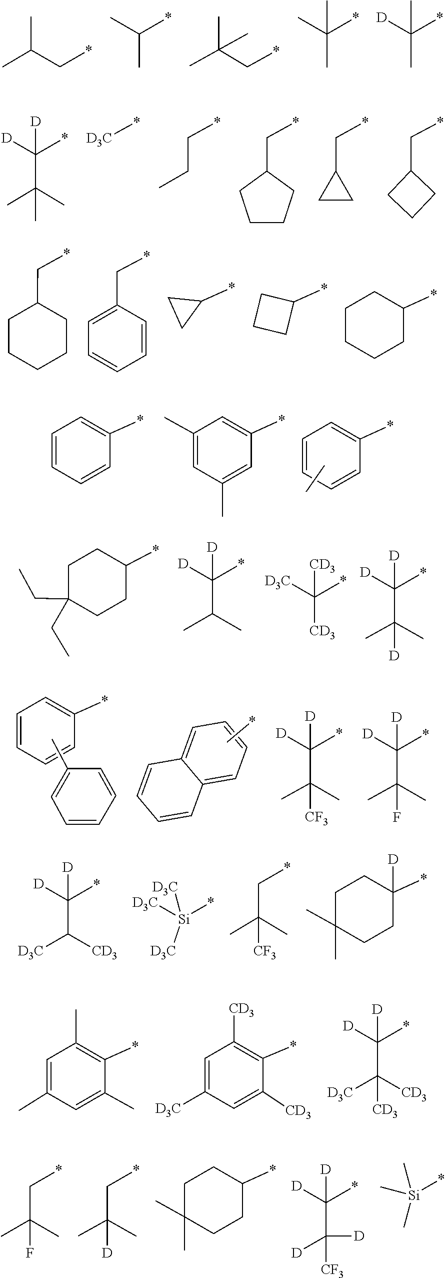

It should be noted that, in the present invention, * represents a connection position; “substitution” means that it may be substituted with —H, -D (deuterium), -T (tritium), —F, —CN, —CH₃, —CD₃, —CT₃, —CF₃, —CH₂F, —CHF₂, —Ge(Me)₃, —Si(Me)₃, ethyl, n-propyl, isopropyl, n-butyl, isobutyl, tert-butyl, cyclopropyl, cyclobutyl, cyclopentyl, cyclohexyl, thiocyclopentane, phenyl, biphenyl, terphenyl, naphthyl, fluorenyl, phenanthryl, anthracyl, indenyl, triphenylenyl, fluoranthenyl, furyl, thienyl, imidazolyl, pyrazolyl, thiazolyl, pyridinyl, pyrazinyl, pyrimidinyl, benzofuryl, benzothienyl, isobenzofuryl, dibenzofuryl, dibenzothienyl, benzimidazolyl, benzothiazolyl, benzisothiazolyl, benzothiadiazolyl, quinolyl, isoquinolyl, quinazolinyl, quinoxalinyl, carbazolyl groups, and the like.

According to an embodiment of the present invention, R₁-R₉ are selected from one or more of the following groups: —H, —F, —CN, —CH₃, —CD₃, —CT₃, —CF₃, —CH₂F, —CHF₂, —Ge(Me)₃, —Si(Me)₃, ethyl, n-propyl, isopropyl, n-butyl, isobutyl, tert-butyl, cyclopropyl, cyclobutyl, cyclopentyl, cyclohexyl, thiocyclopentane, phenyl, biphenyl, terphenyl, naphthyl, fluorenyl, phenanthryl, anthracyl, indenyl, triphenylenyl, fluoranthenyl, furyl, thienyl, imidazolyl, pyrazolyl, thiazolyl, pyridinyl, pyrazinyl, pyrimidinyl, benzofuryl, benzothienyl, isobenzofuryl, dibenzofuryl, dibenzothienyl, benzimidazolyl, benzothiazolyl, benzisothiazolyl, benzothiadiazolyl, quinolyl, isoquinolyl, quinazolinyl, quinoxalinyl, carbazolyl groups, and the like.

According to an embodiment of the present invention, R₁₀, R₁₁, and R₁₂ are independently selected from one or more of —H, -D (deuterium), -T (tritium), —F, —CN, —CH₃, —CD₃, —CT₃, —CF₃, —CH₂F, —CHF₂, —Ge(Me)₃, —Si(Me)₃, ethyl, n-propyl, isopropyl, n-butyl, isobutyl, tert-butyl, cyclopropyl, cyclobutyl, cyclopentyl, cyclohexyl, tetrahydrofuran, pyrrolidine, thiocyclopentane, tetrahydropyran, phenyl, biphenyl, terphenyl, naphthyl, fluorenyl, phenanthryl, anthracyl, indenyl, triphenylenyl, pyrenyl, tetracenyl, perylenyl, chrysenyl, fused tetraphenyl, fluoranthenyl, furyl, thienyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridinyl, pyrazinyl, pyrimidinyl, pyridazinyl, benzofuryl, benzothienyl, isobenzofuryl, dibenzofuryl, dibenzothienyl, benzimidazolyl, benzothiazolyl, benzoisothiazolyl, benzisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenanthridinyl, benzodioxolyl groups, and the like.

According to an embodiment of the present invention, the organic electroluminescent dopant material is selected from any one of the following structures:

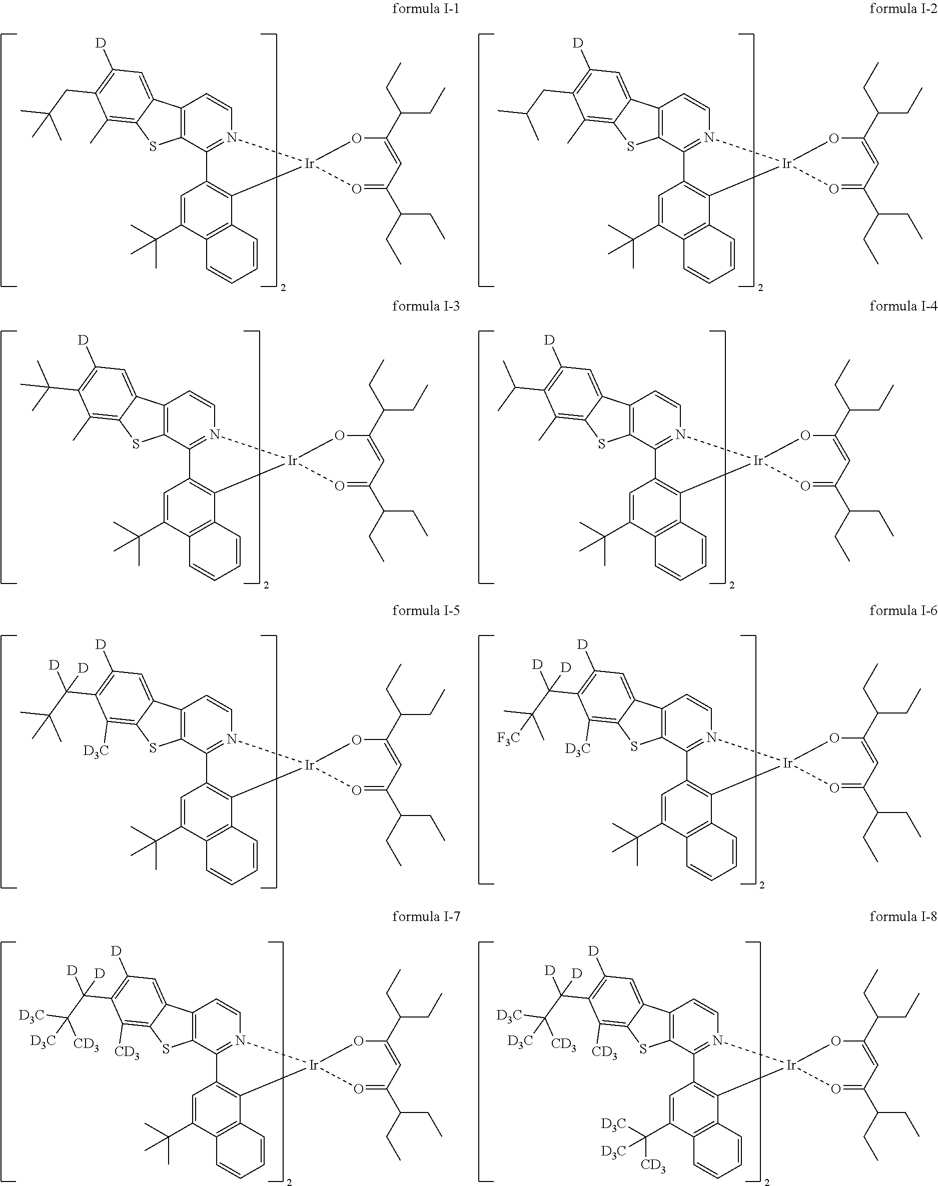

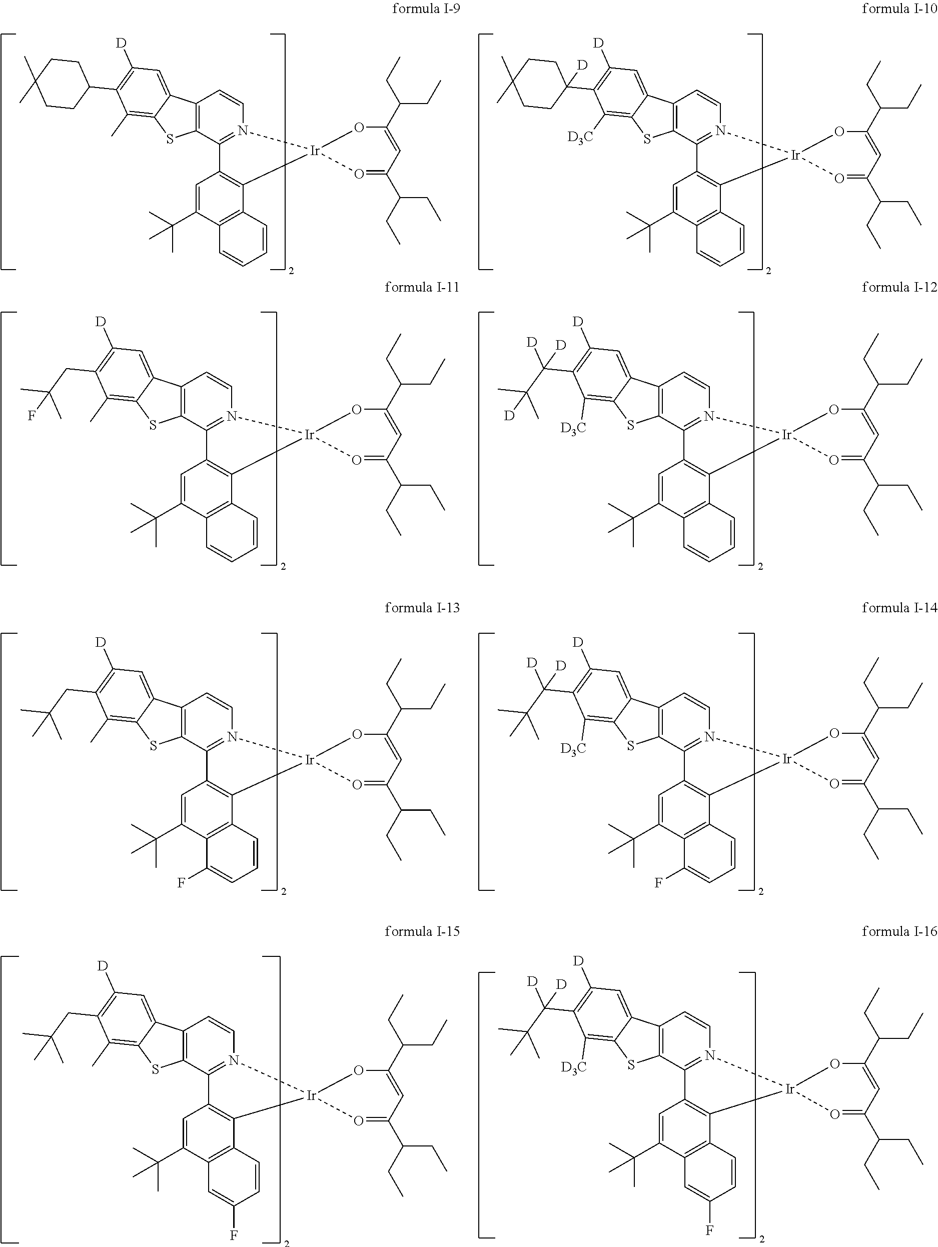

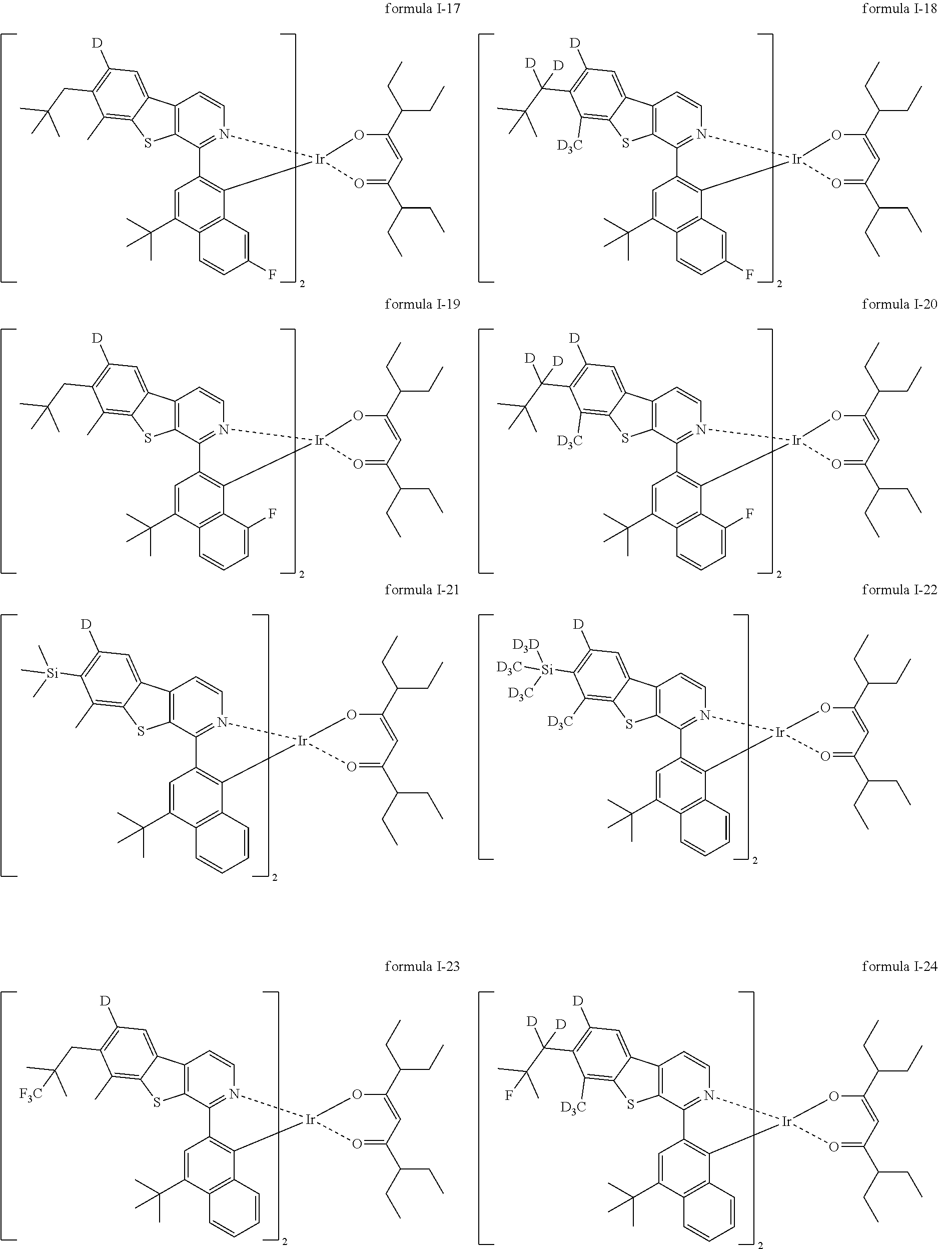

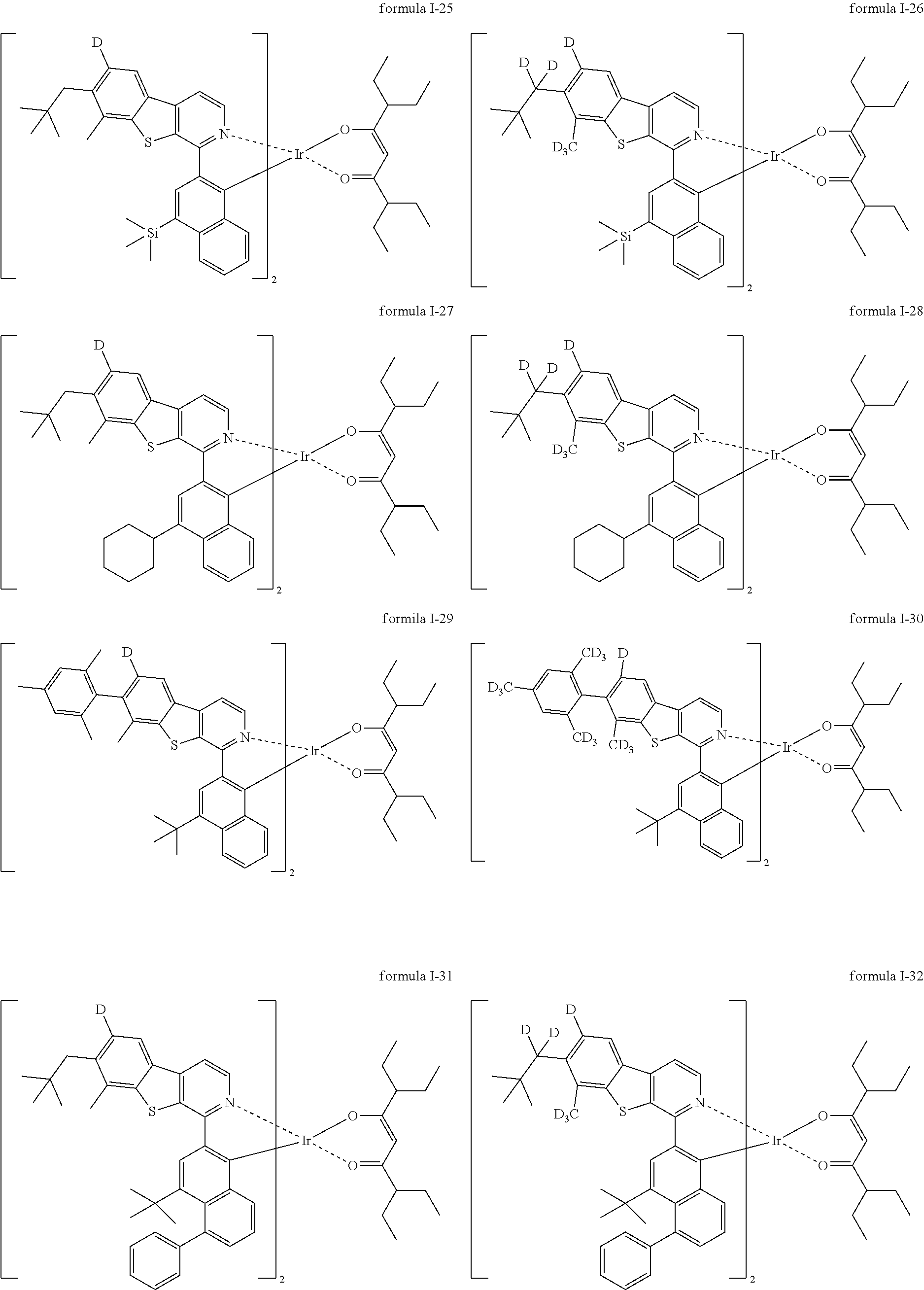

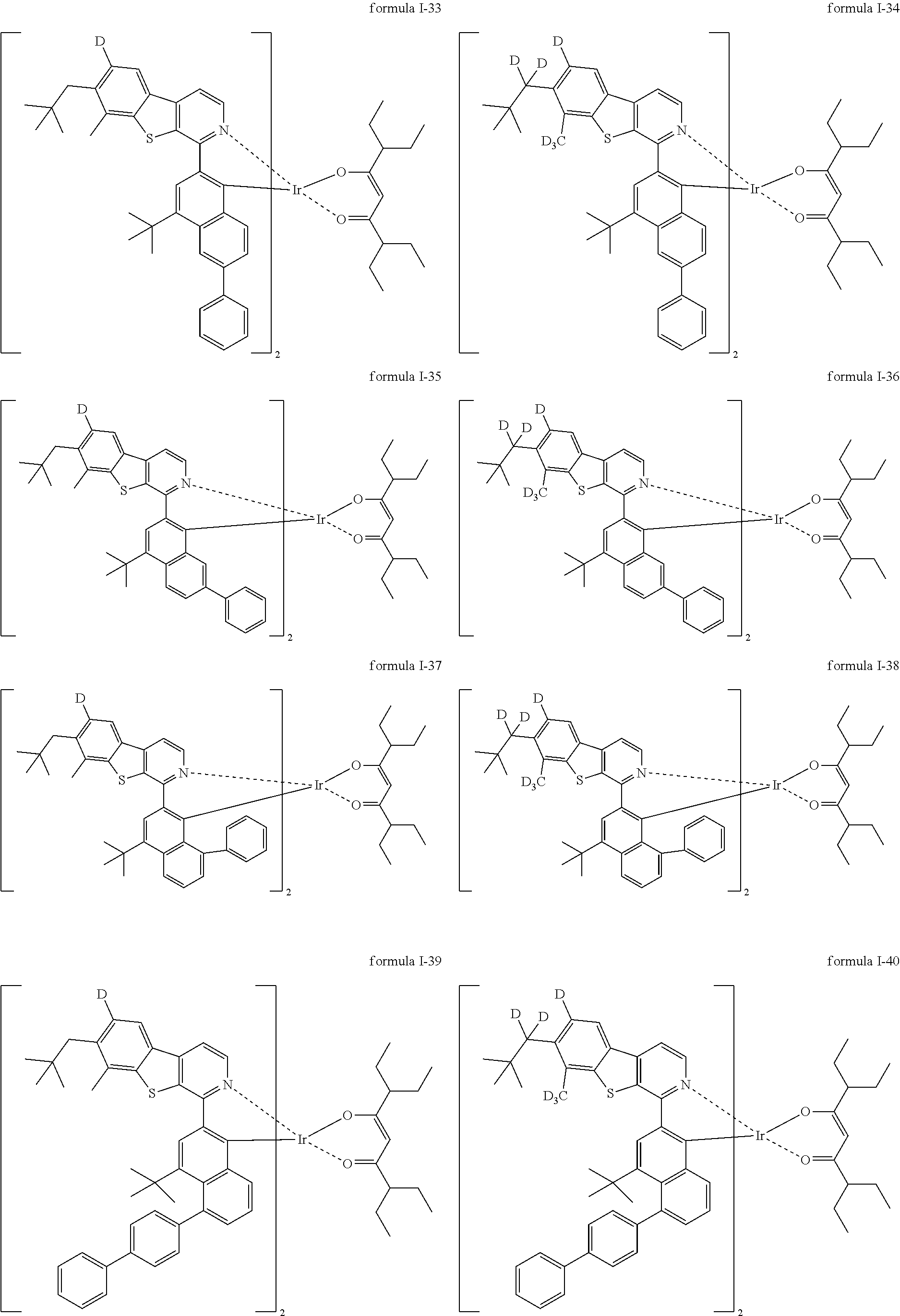

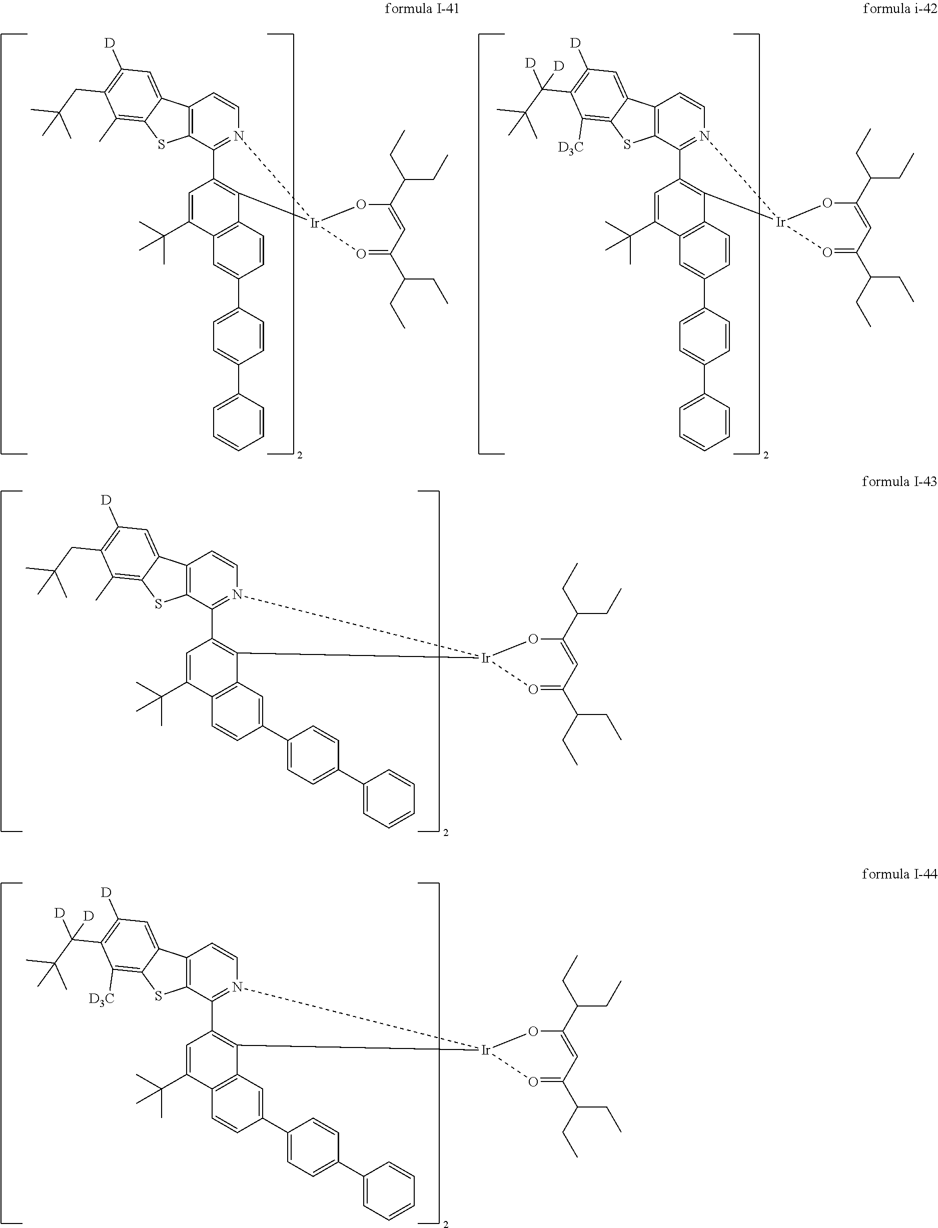

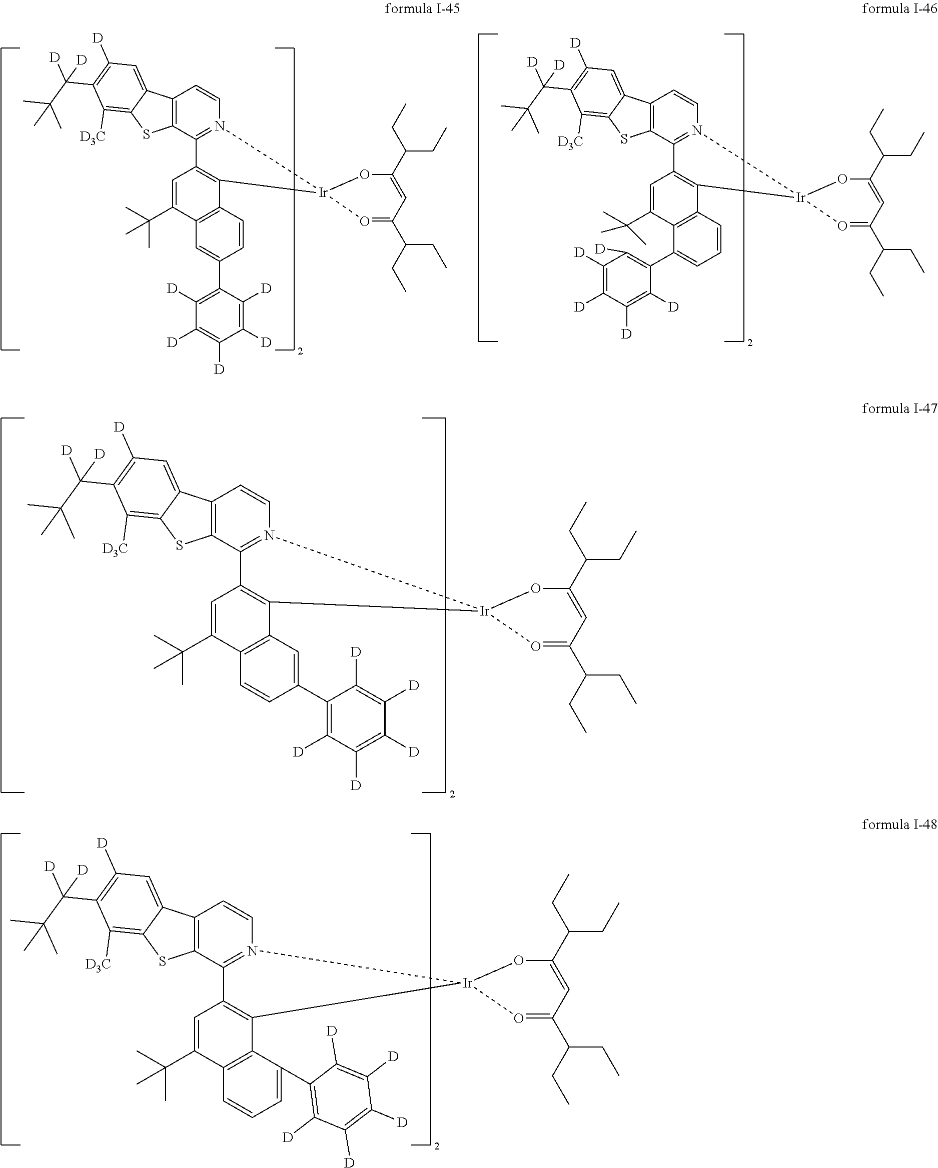

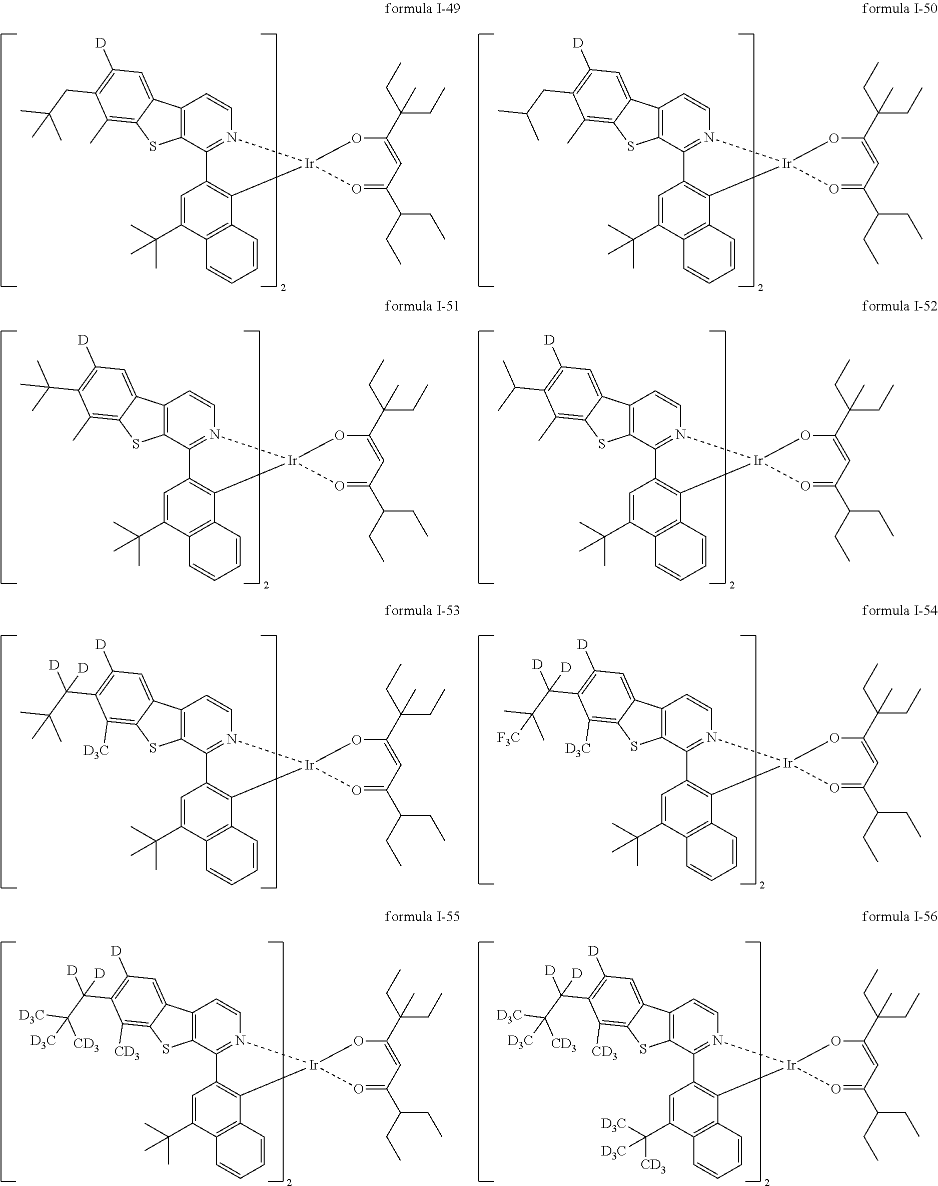

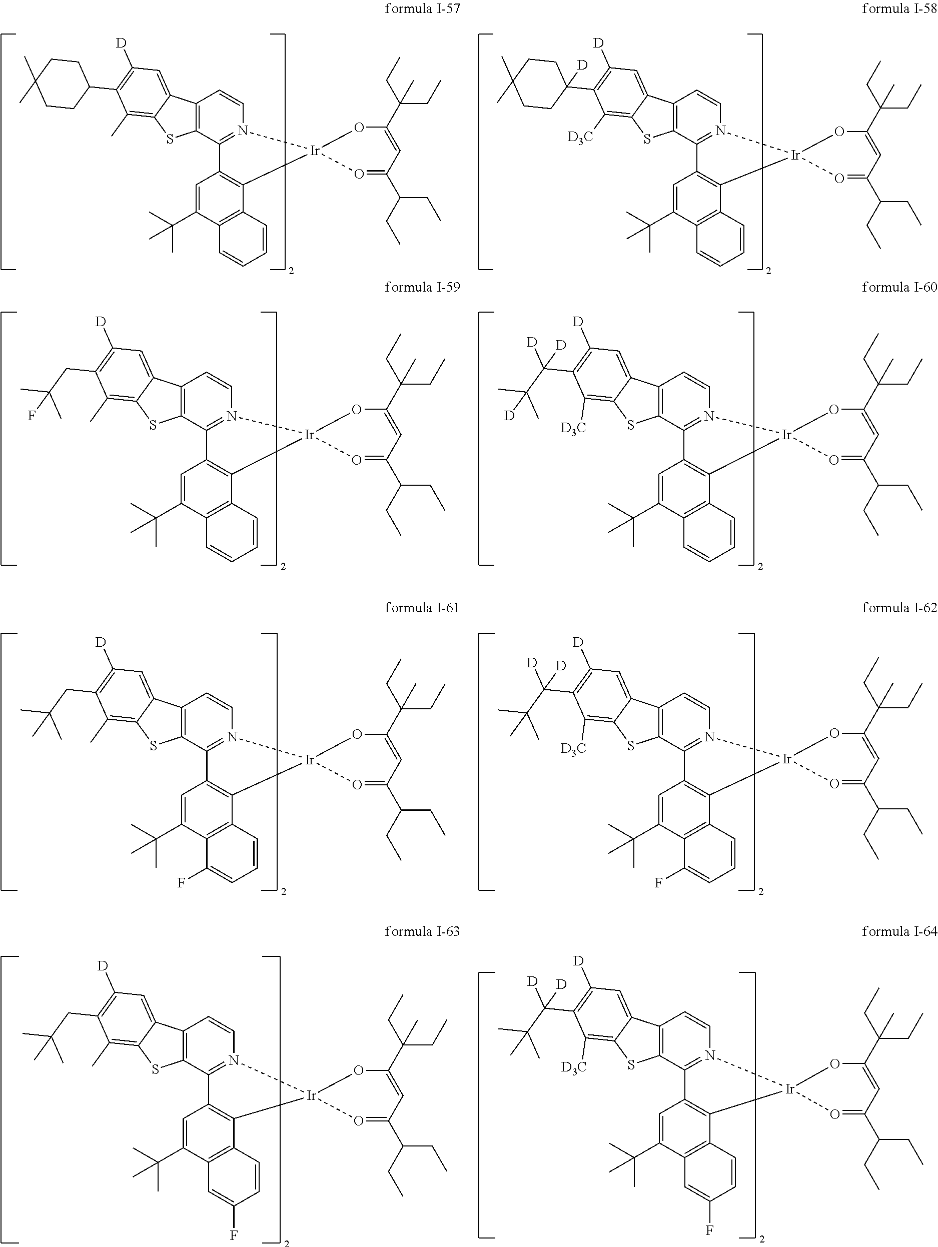

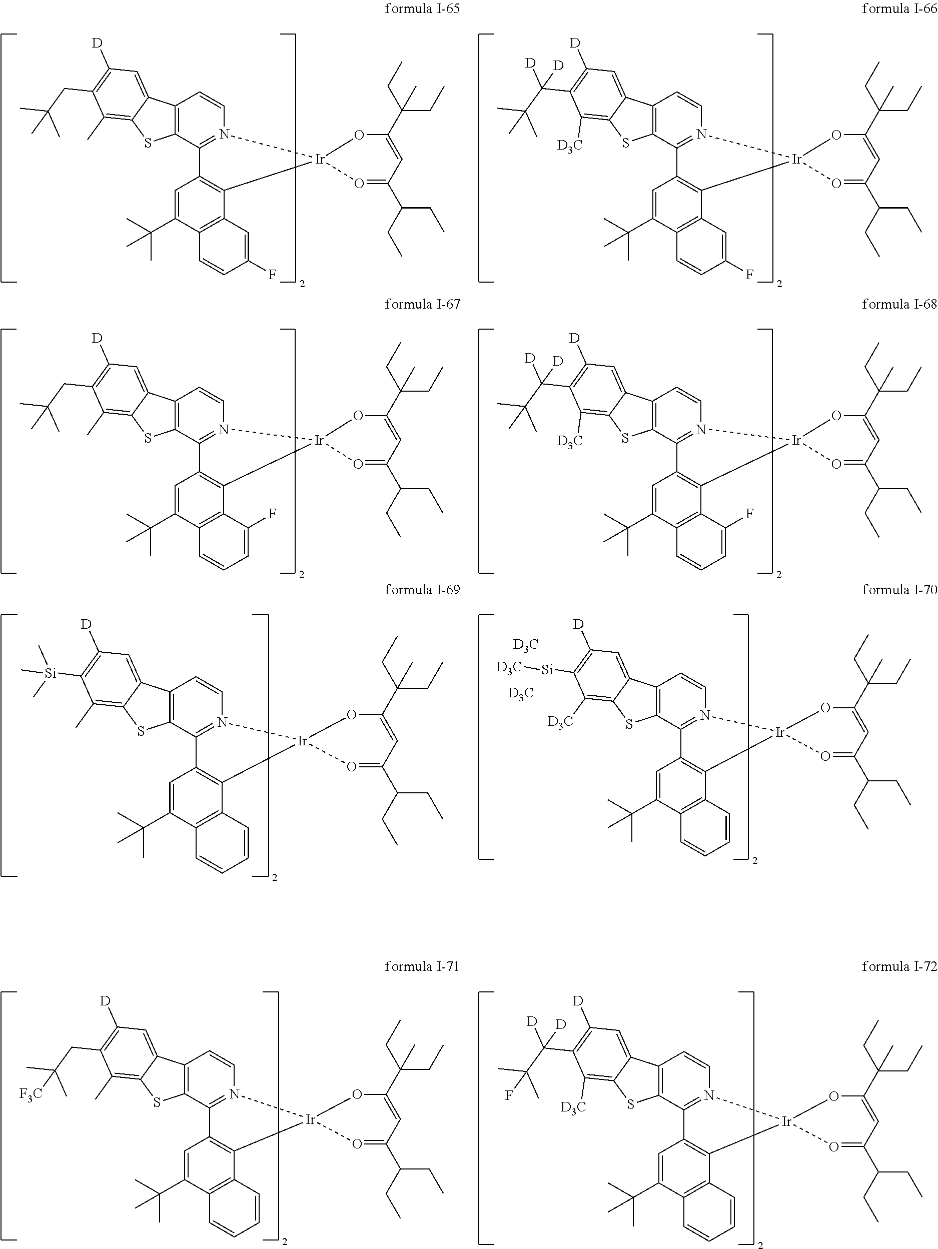

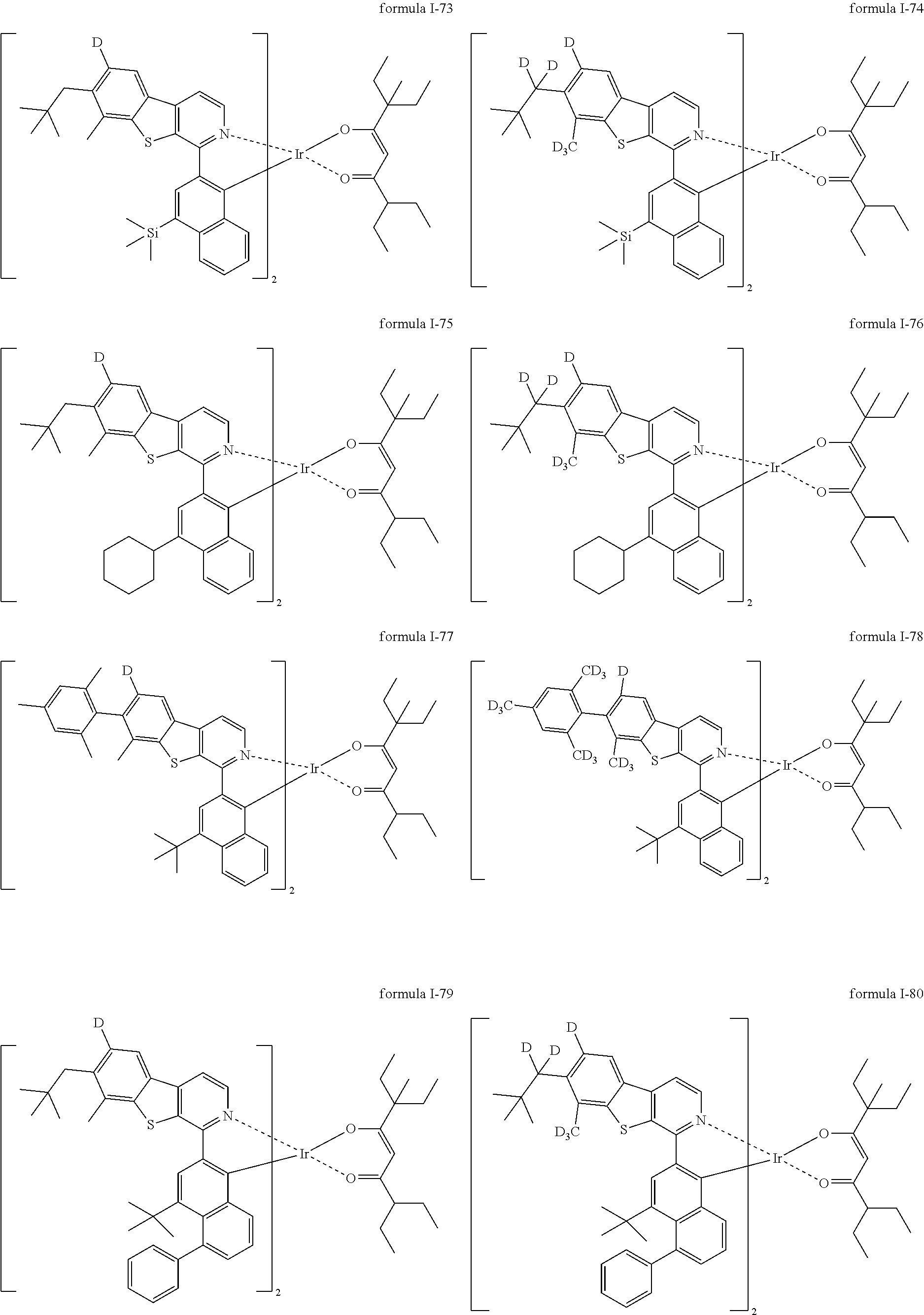

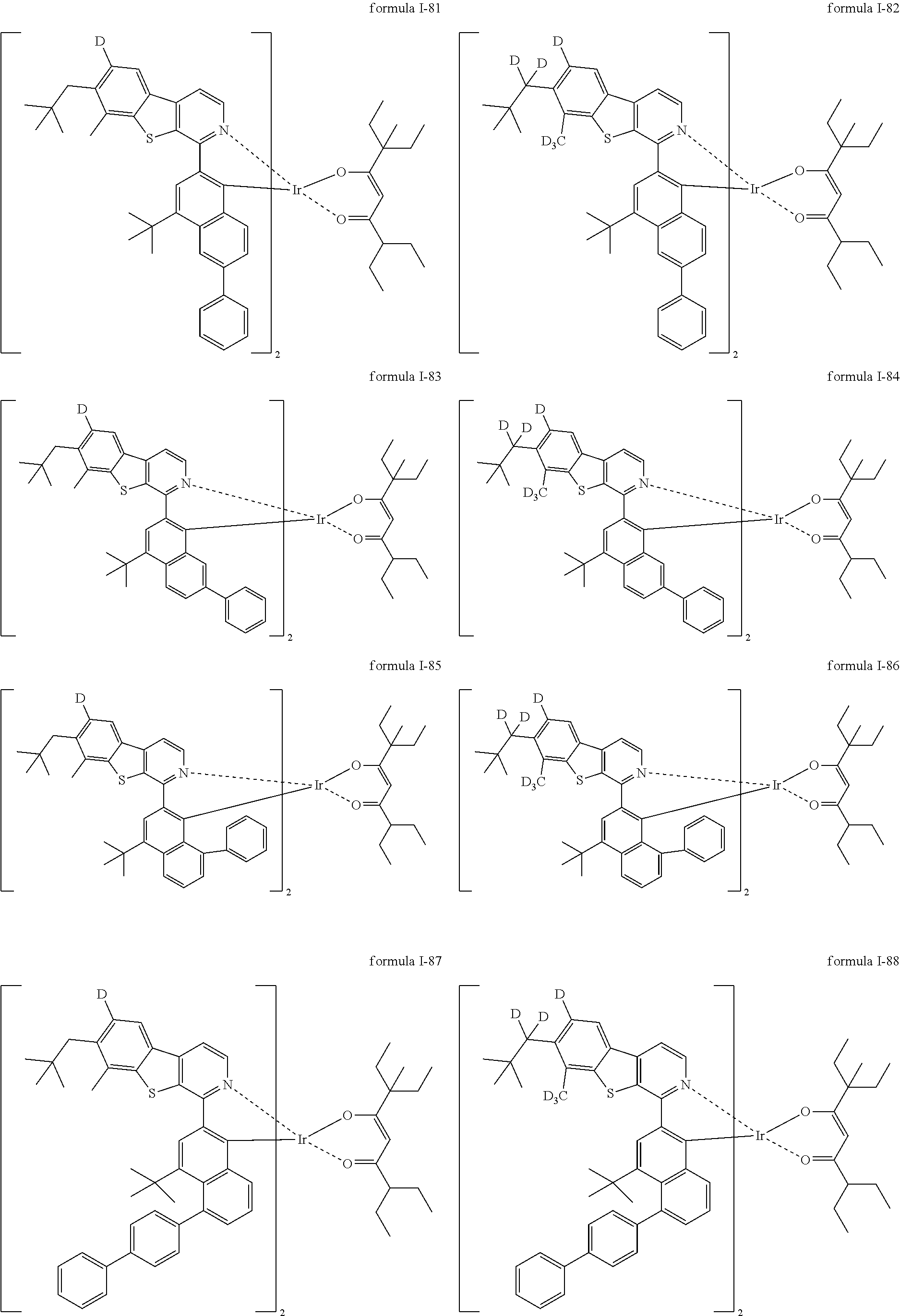

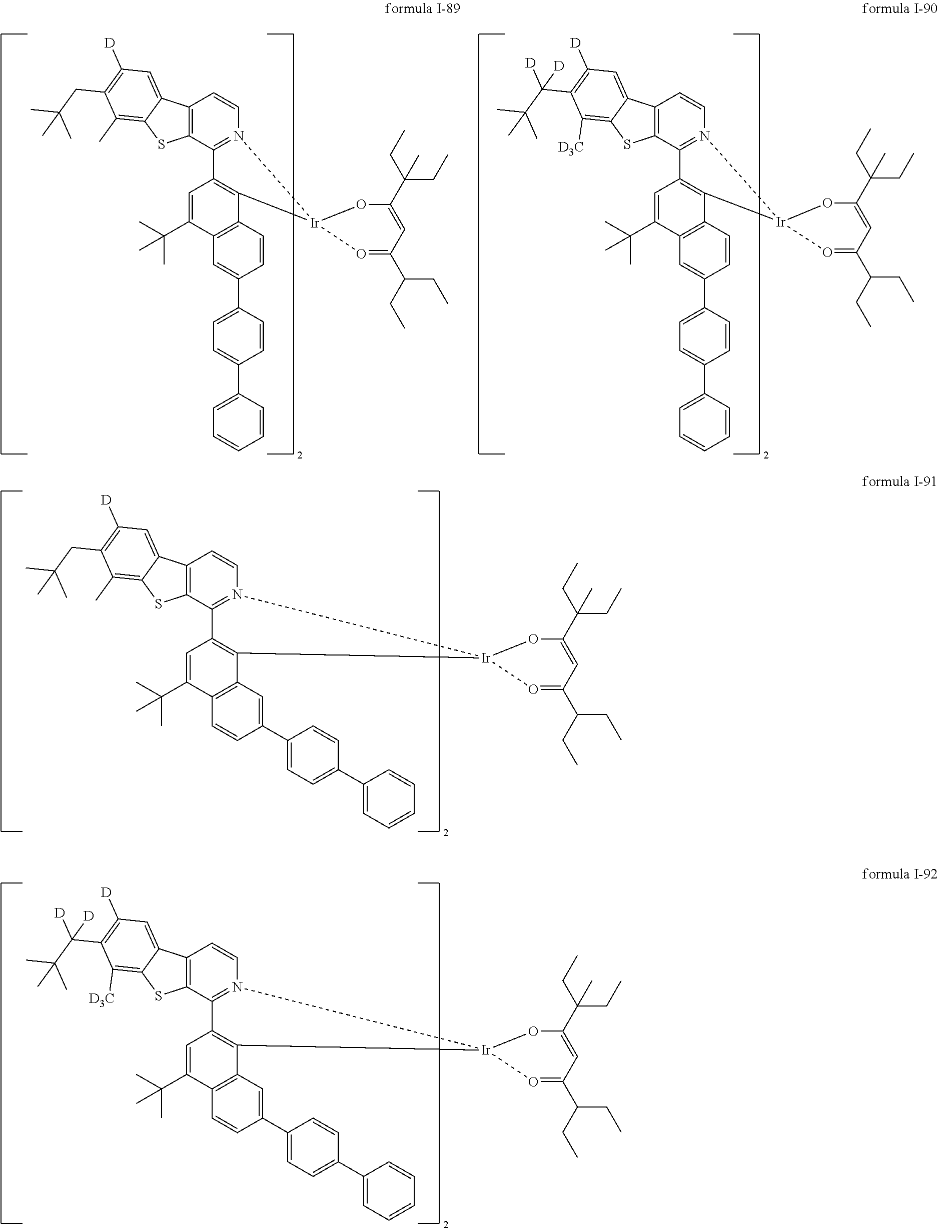

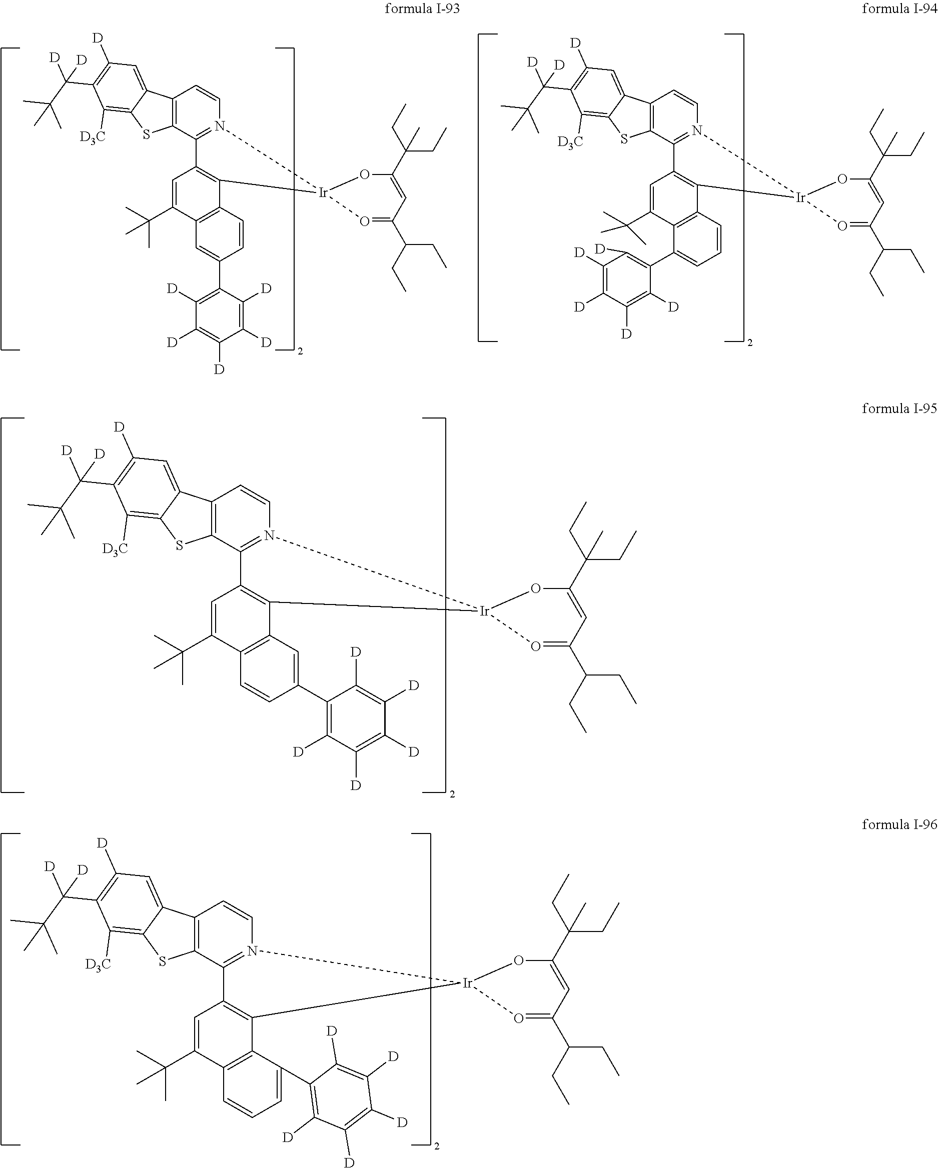

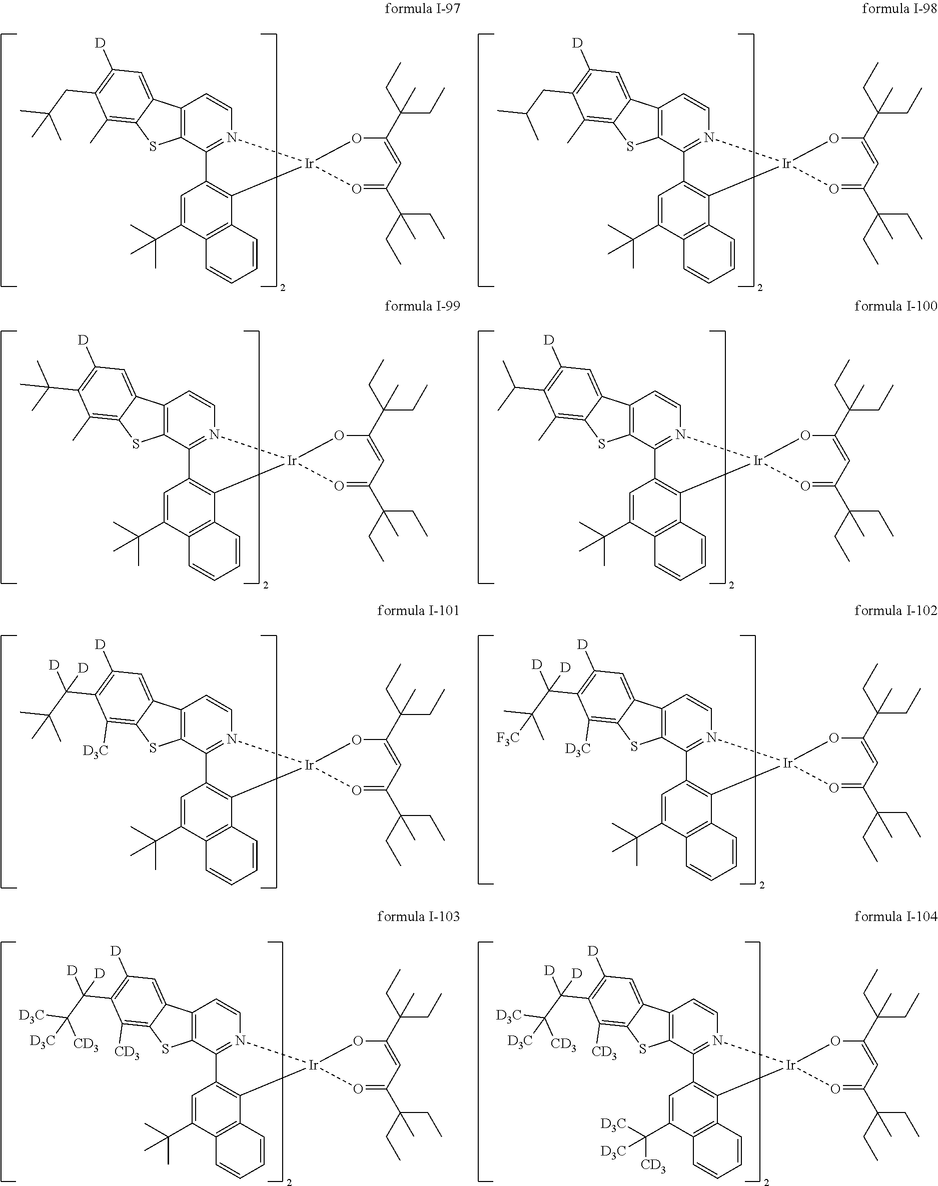

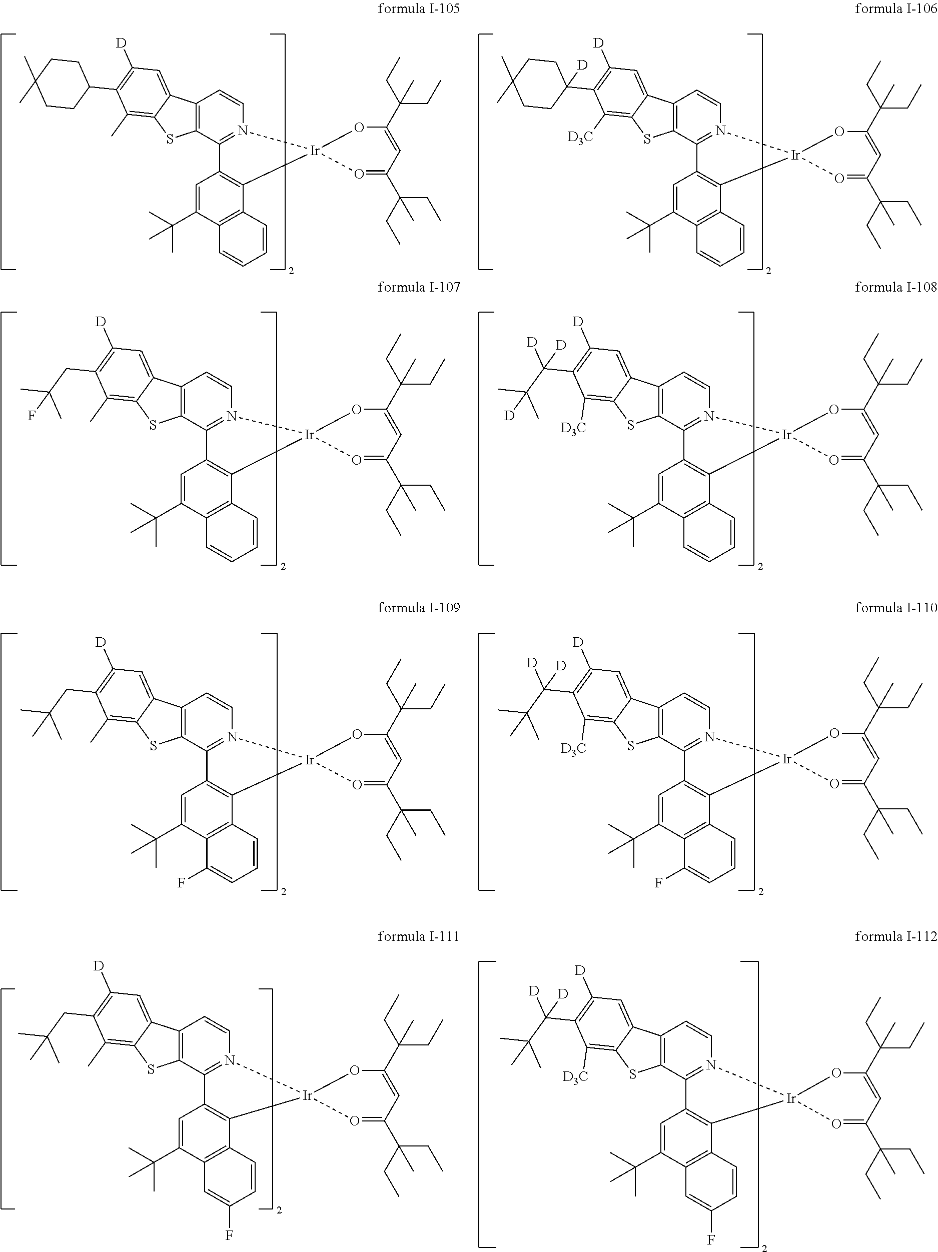

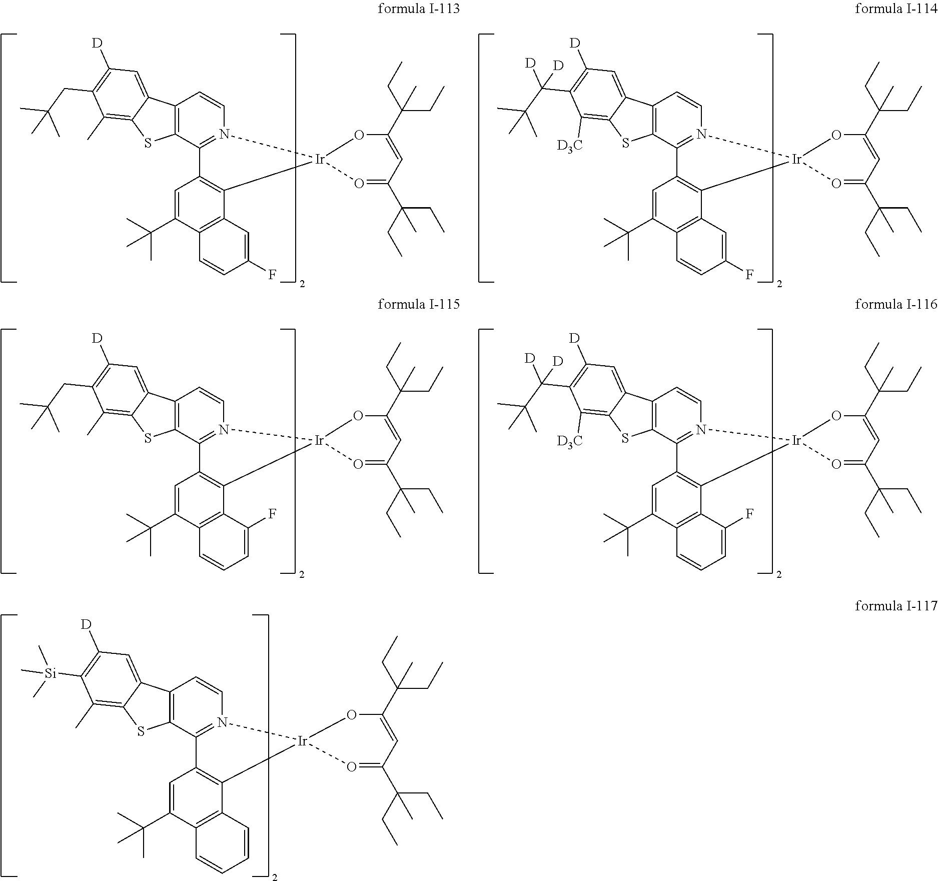

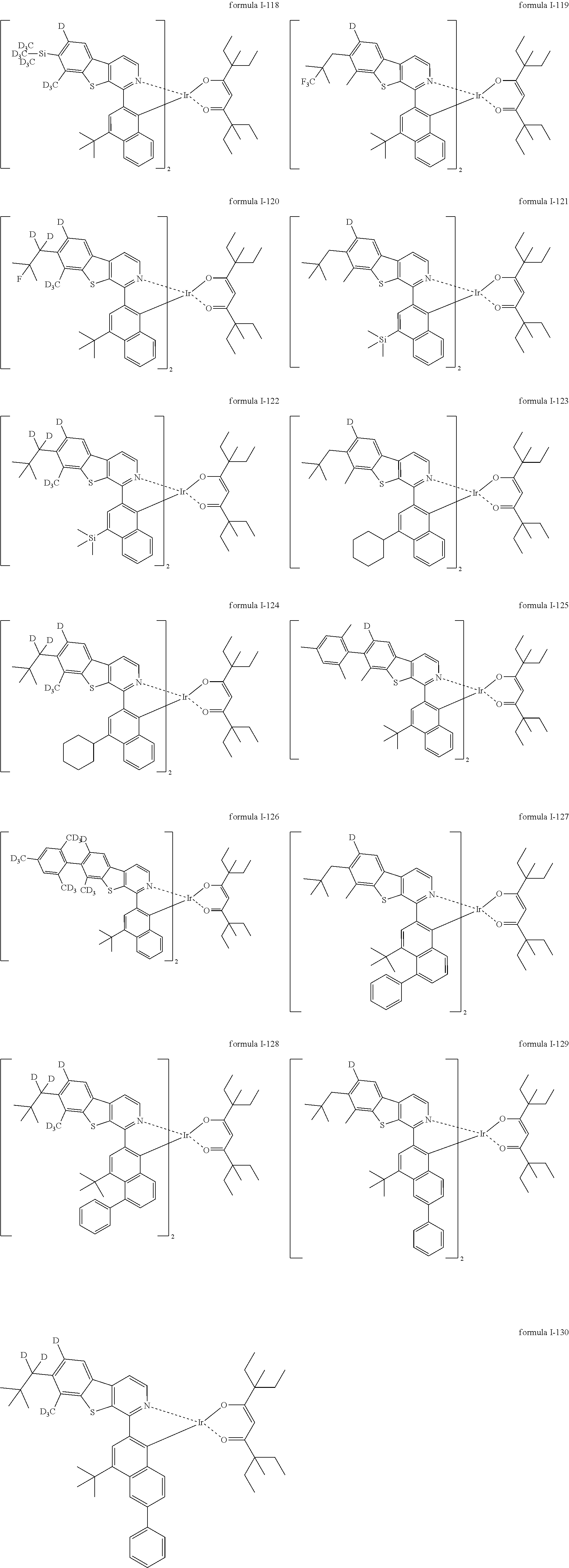

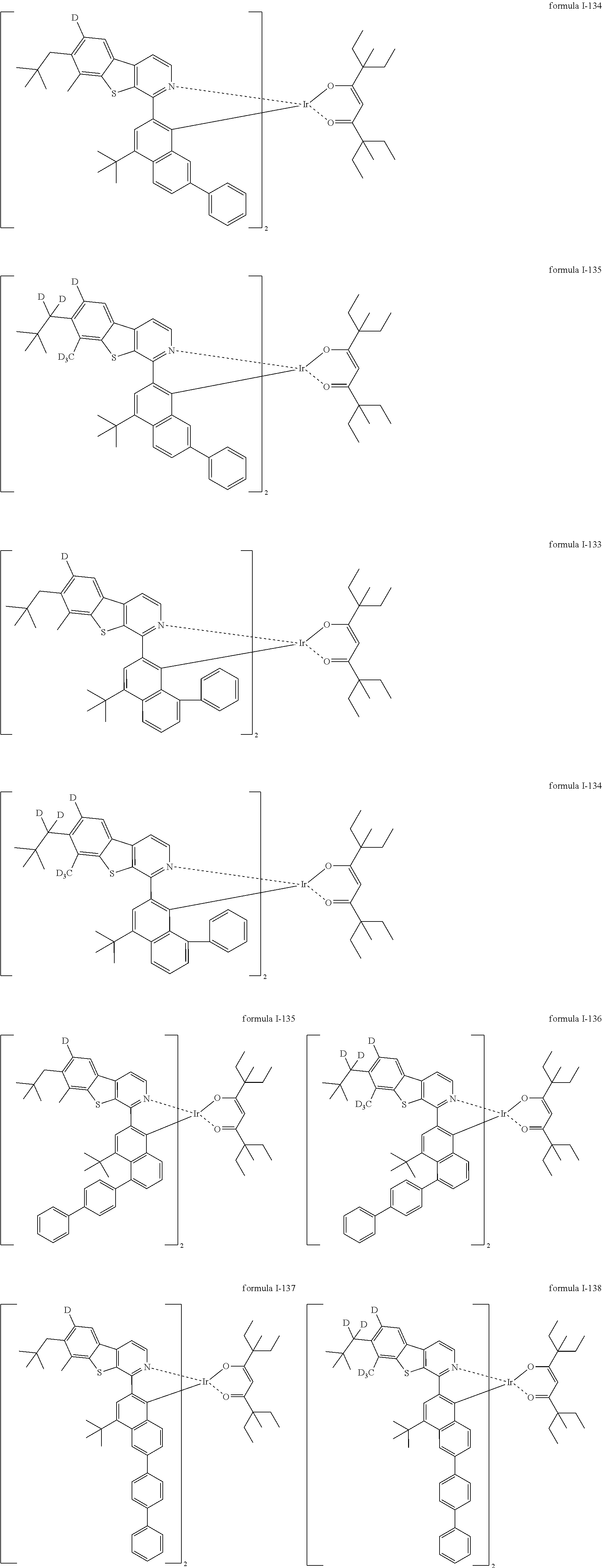

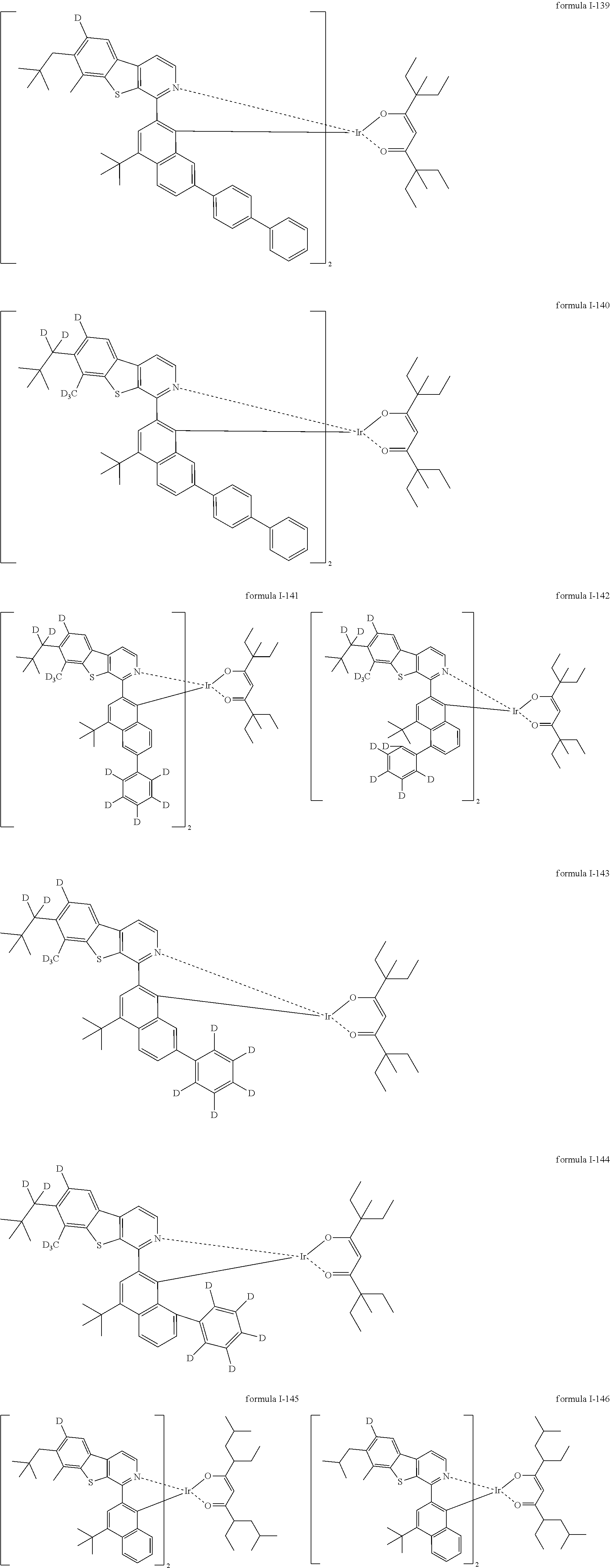

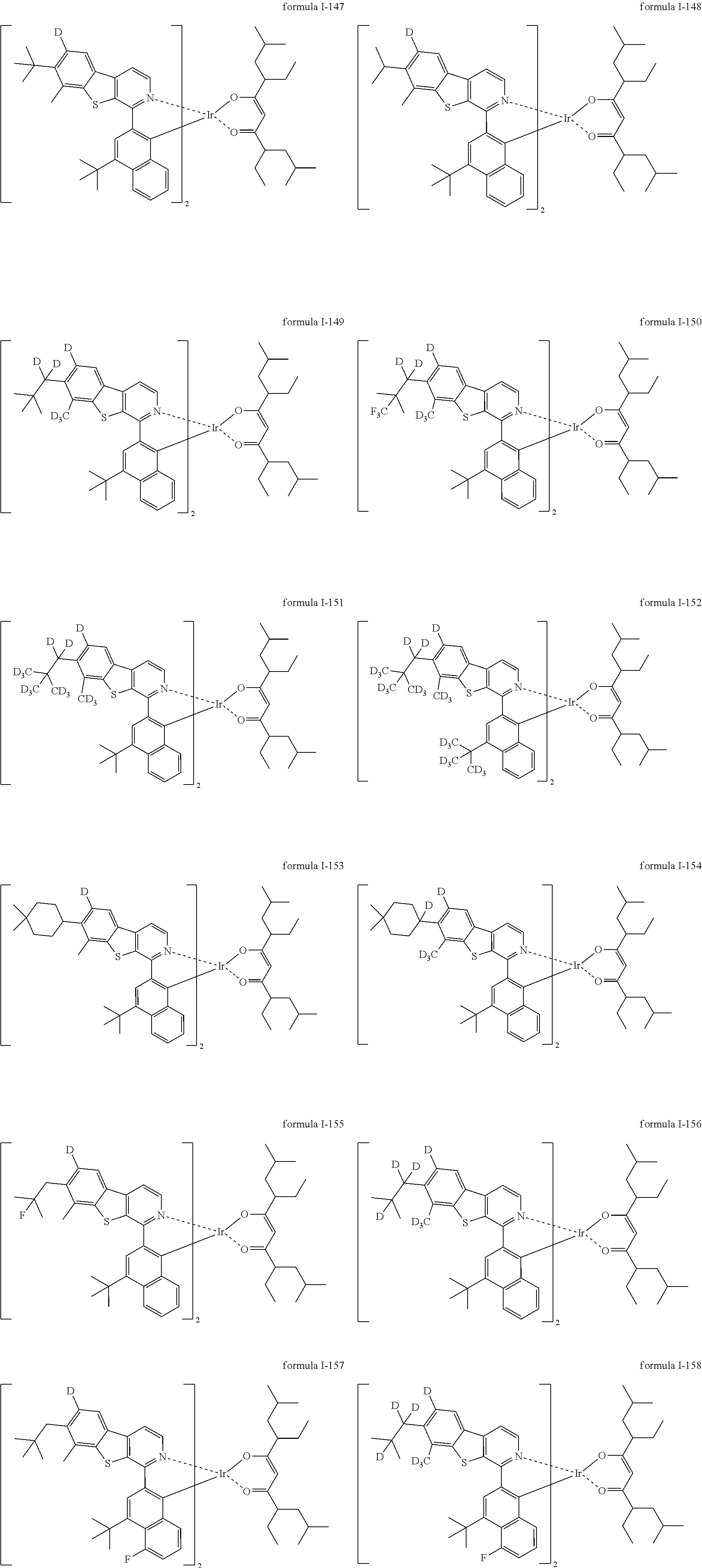

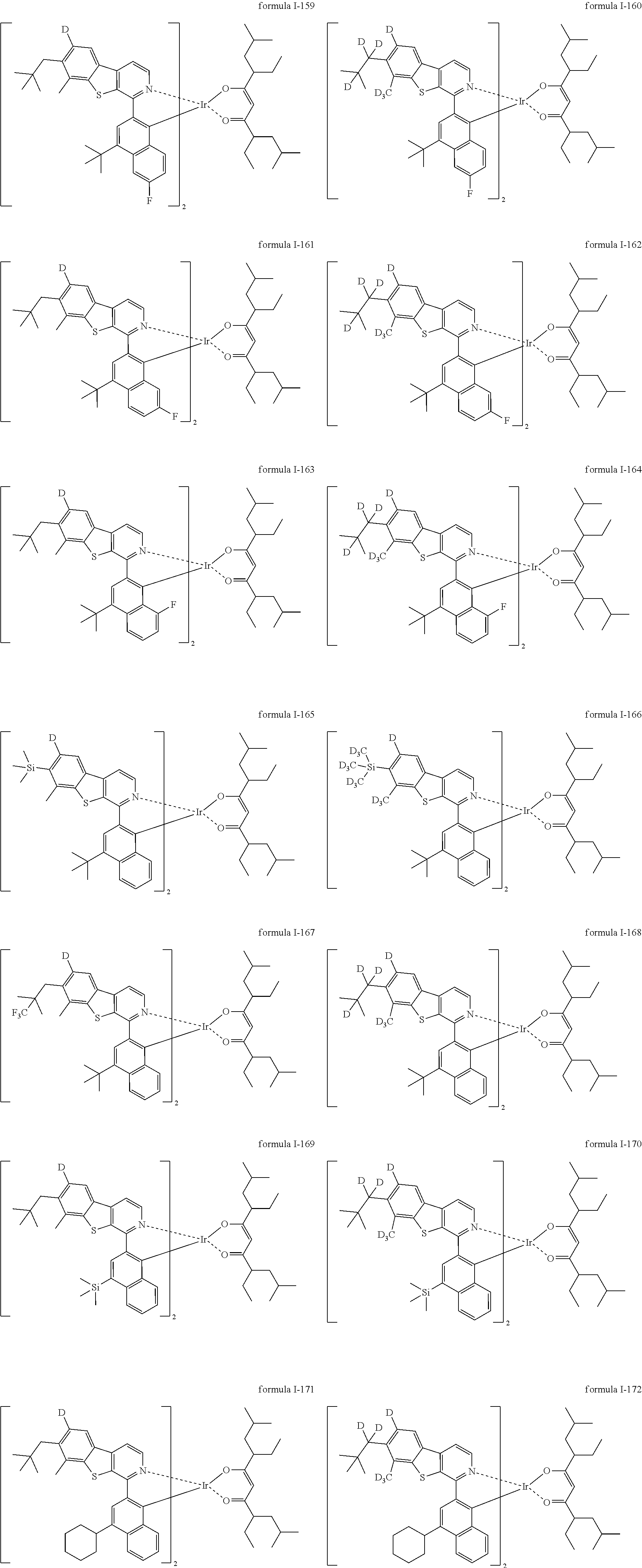

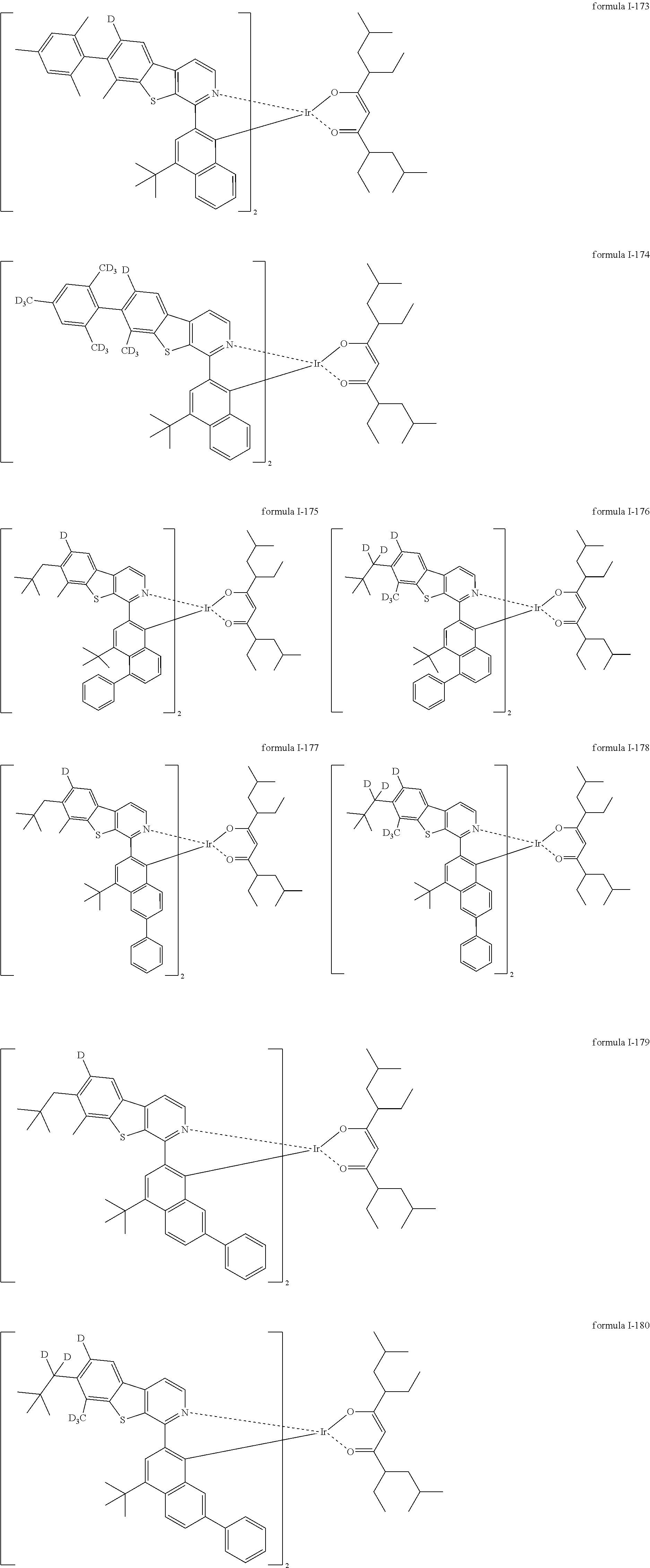

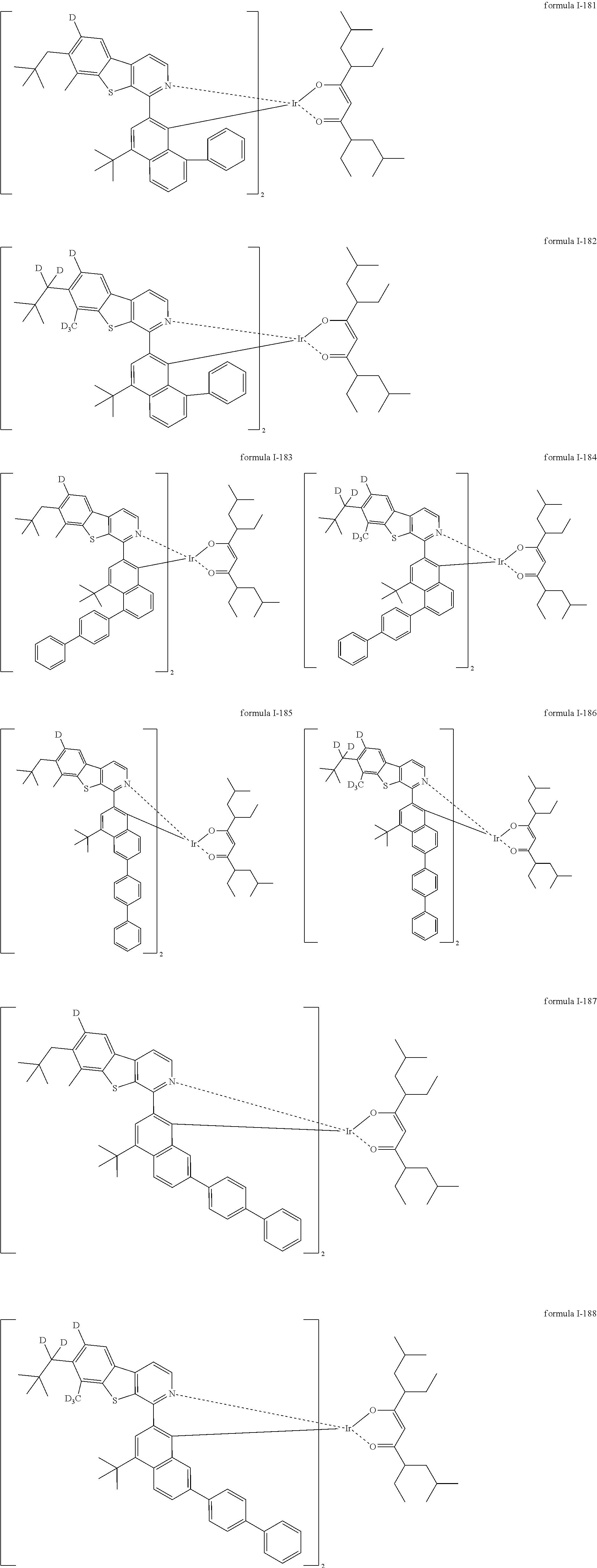

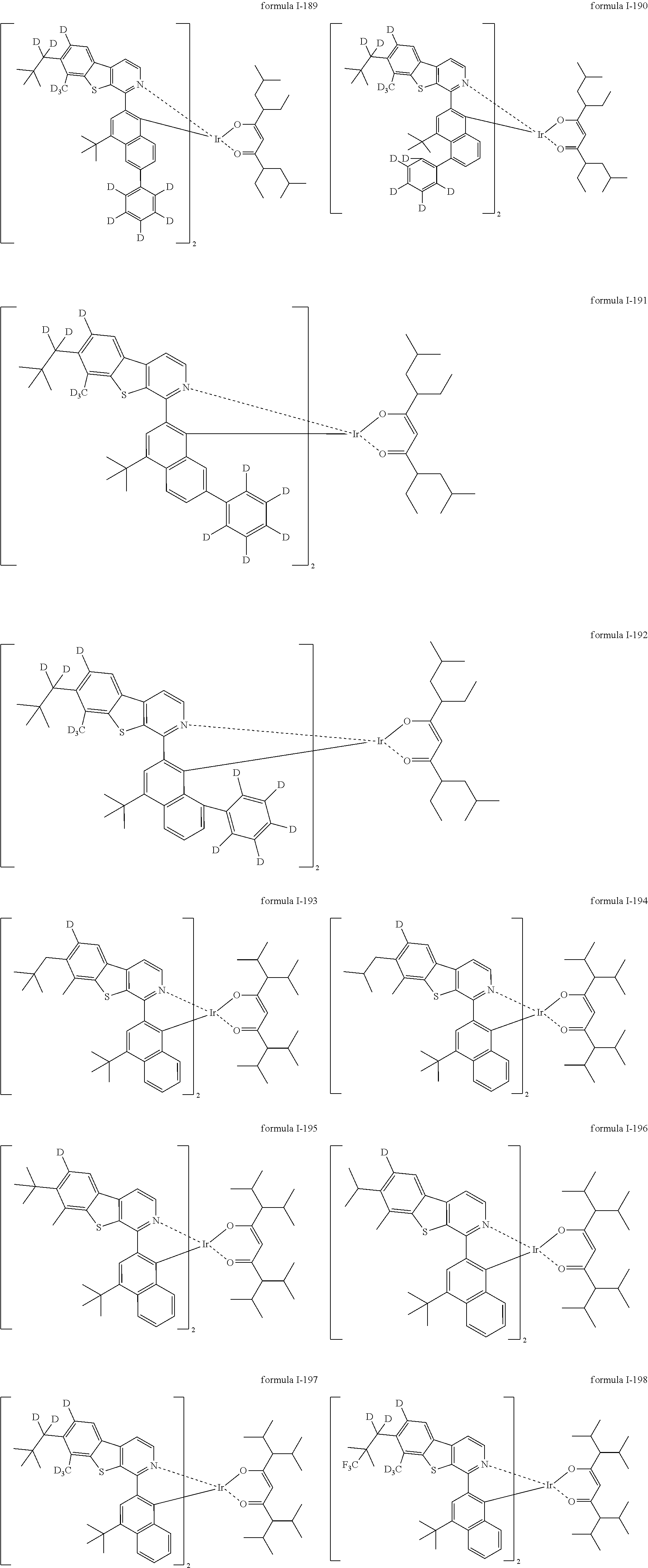

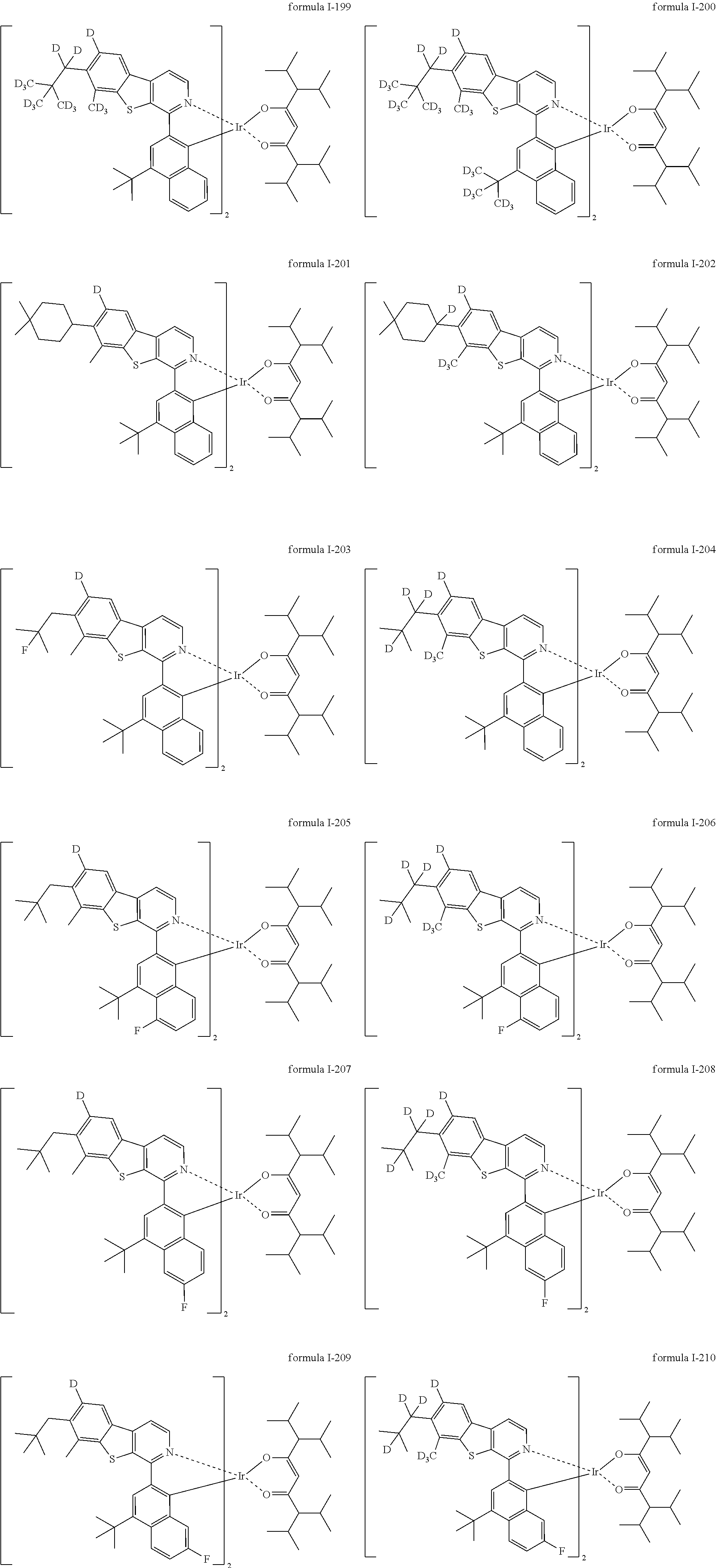

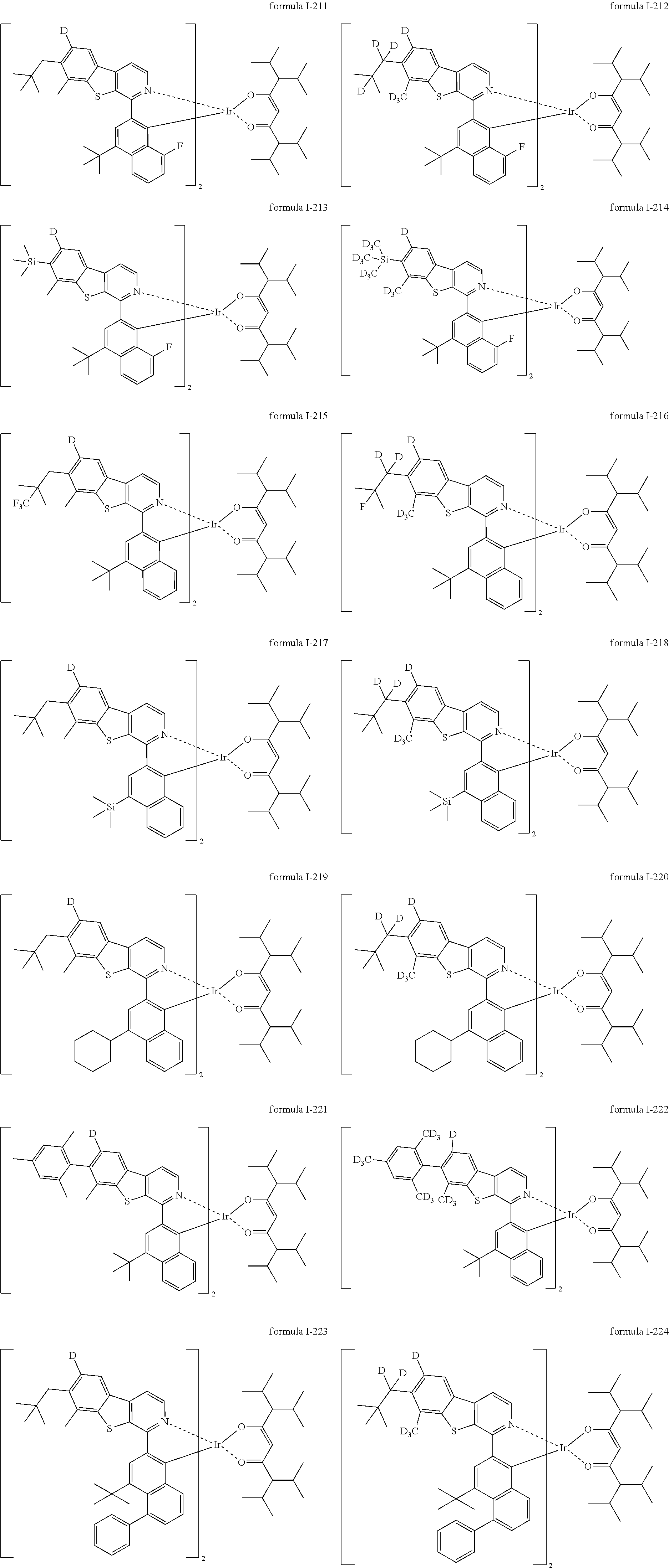

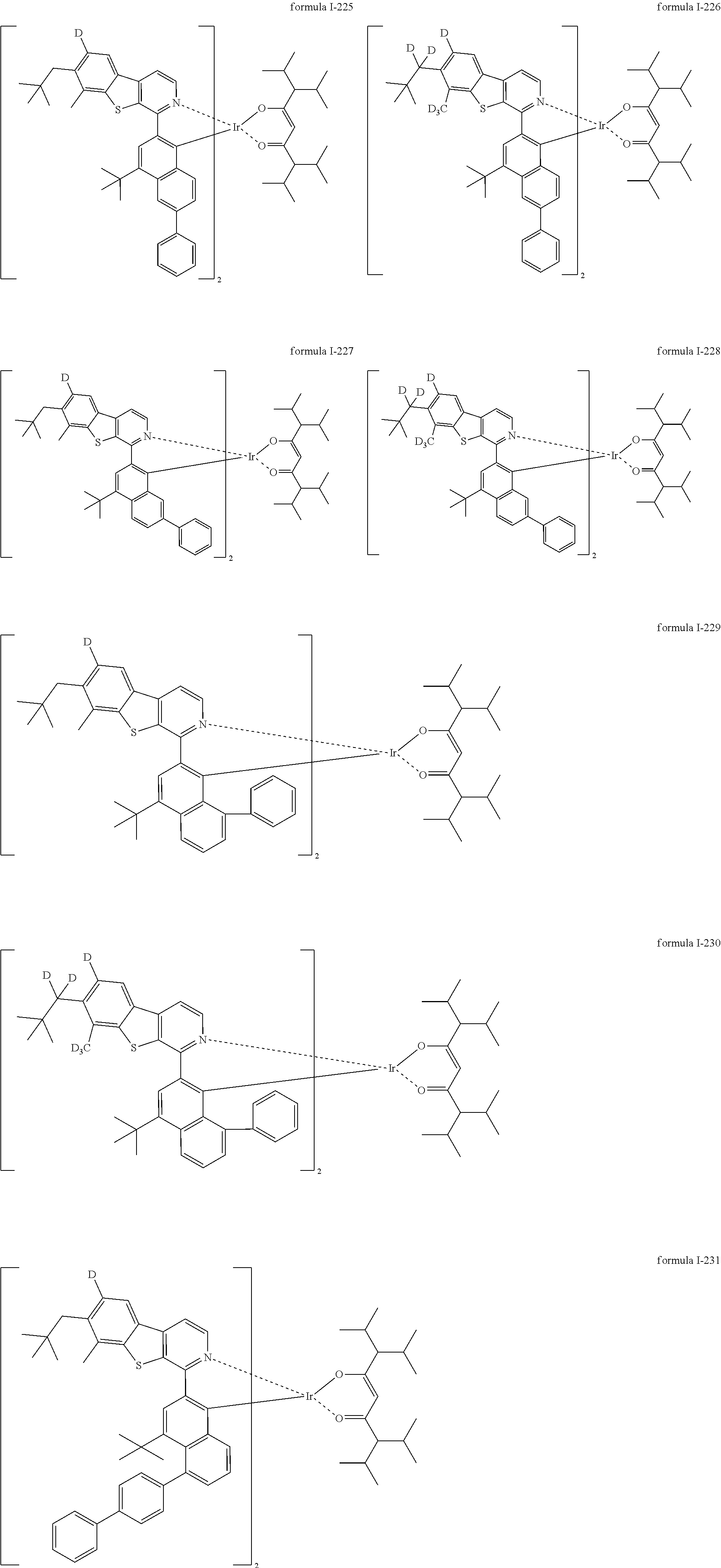

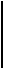

The present invention further provides a preparation method for an organic electroluminescent dopant material, and the preparation process of the organic electroluminescent dopant material of the compound of structure represented by formula I is as follows:

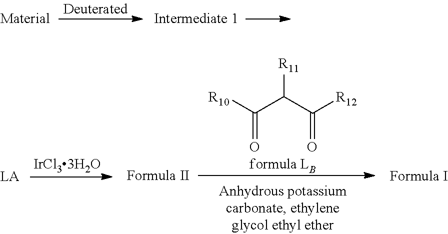

The definition in the above formula is consistent with the above, and will not be repeated here.

The present invention further provides an organic electroluminescent device comprising a first electrode, a second electrode, and an organic material layer located between the first electrode and the second electrode; the organic material layer may be further divided into a plurality of regions. For example, the organic material layer comprises a hole transport region, an emissive layer, and an electron transport region; the emissive layer comprises the organic electroluminescent dopant material.

According to an embodiment of the present invention, the emissive layer may comprise an emissive dye (i.e., dopant) emitting different wavelength spectra, and may also further comprise a host material (host). The emissive layer may be a monochromatic emissive layer that emits a single color such as red, green, or blue. The monochromatic emissive layers of different colors may be arranged in a plane according to a pixel pattern, or may be stacked together to form a color emissive layer. When the emissive layers of different colors are stacked together, they may be spaced apart from each other or may be connected to each other. The emissive layer may also be a single color emissive layer capable of simultaneously emitting different colors such as red and green.

According to an embodiment of the present invention, the organic electroluminescent dopant material may be different materials such as a phosphorescent electroluminescent material and a thermally activated delayed fluorescent material. In an OLED device, a single light-emitting technology may be used, or a combination of a plurality of different light-emitting technologies may be used. These different luminescent materials classified according to the technology may emit light of the same color, or may emit light of different colors. A phosphorescent electroluminescence technology may be used in the emissive layer.

According to an embodiment of the present invention, the organic electroluminescent device comprises an anode, a hole injection layer, a hole transport layer, an electron blocking layer, an emissive layer, an electron transport layer, an electron injection layer, and a cathode, which are sequentially disposed.

According to an embodiment of the present invention, a substrate may be used below the first electrode or above the second electrode. The substrate is a glass or polymer material with excellent mechanical strength, thermal stability, waterproofness, and transparency. In addition, a thin-film transistor (TFT) may be provided on the substrate for a display.

According to an embodiment of the present invention, the first electrode may be formed by sputtering or depositing a first electrode material on the substrate. When the first electrode is used as the anode, an oxide transparent conductive material such as indium tin oxide (ITO), indium zinc oxide (IZO), tin dioxide (SnO2), zinc oxide (ZnO), or any combination thereof may be used.

According to an embodiment of the present invention, the anode material may also be selected from materials other than the listed anode materials that facilitate hole injection and combinations thereof, including known materials suitable for use as anodes.

According to an embodiment of the present invention, when the first electrode is used as the cathode, a metal or alloy such as magnesium (Mg), silver (Ag), aluminum (Al), aluminum-lithium (Al—Li), calcium (Ca), magnesium-indium (Mg—In), magnesium-silver (Mg—Ag), or any combination thereof may be used.

In addition to the above-listed cathode materials, the cathode materials may also be materials and combinations thereof that facilitate electron injection, including known materials suitable for use as cathodes.

According to an embodiment of the present invention, the organic material layer may be formed on the electrode by vacuum thermal evaporation, spin coating, printing, or the like.

According to an embodiment of the present invention, the compound used as the organic material layer may be an organic small molecule, an organic large molecule, a polymer, and a combination thereof.

According to an embodiment of the present invention, the hole transport region is located between the anode and the emissive layer, and the hole transport region may be a hole transport layer (HTL) with a single-layer structure, including a single-layer hole transport layer containing only one compound and a single-layer hole transport layer containing a plurality of compounds.

According to an embodiment of the present invention, the hole transport region may also be a multi-layer structure including at least one layer of a hole injection layer (HIL), a hole transport layer (HTL), and an electron blocking layer (EBL).

According to an embodiment of the present invention, the material of the hole transport layer may be selected from phthalocyanine derivatives, such as CuPc and conductive polymers.

According to an embodiment of the present invention, the material of the hole transport layer may be selected from a polymer containing a conductive dopant.

For example, polyphenylenevinylene, polyaniline/dodecylbenzenesulfonic acid (Pani/DBSA), poly(3,4-ethylenedioxythiophene)/poly(4-styrenesulfonate) (PEDOT/PSS), polyaniline/camphorsulfonic acid (Pani/CSA), polyaniline/poly(4-styrenesulfonate) (Pani/PSS), aromatic amine derivatives such as compounds as shown from HT-1 to HT-34 below, or any combination thereof.

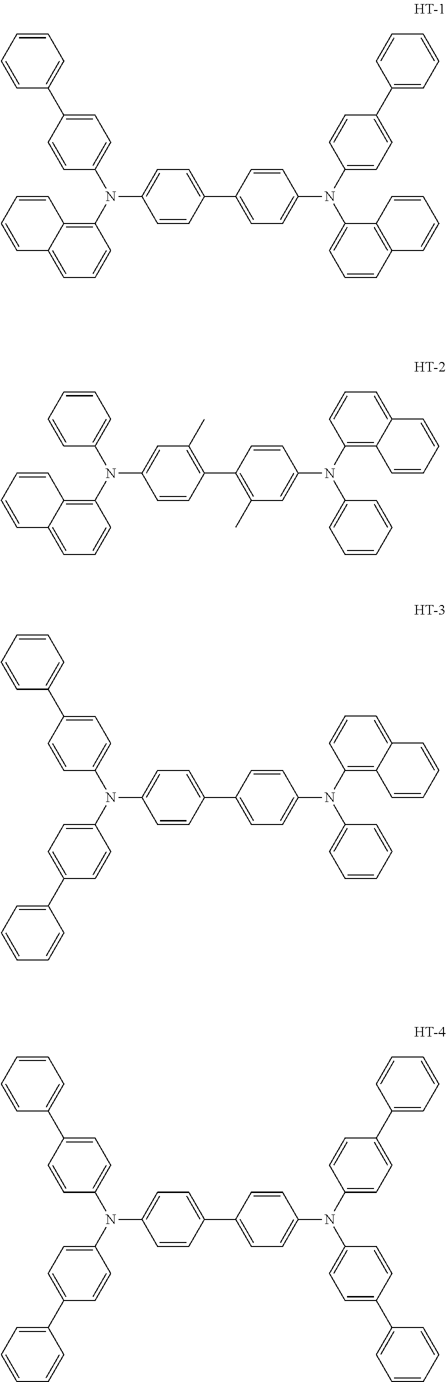 [SMILES: c1ccc(-c2ccc(N(c3ccc(-c4ccc(N(c5ccc(-c6ccccc6)cc5)c5cccc6ccccc56)cc4)cc3)c3cccc4ccccc34)cc2)cc1 ; Cc1cc(N(c2ccccc2)c2cccc3ccccc23)ccc1-c1ccc(N(c2ccccc2)c2cccc3ccccc23)cc1C ; c1ccc(-c2ccc(N(c3ccc(-c4ccccc4)cc3)c3ccc(-c4ccc(N(c5ccccc5)c5cccc6ccccc56)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

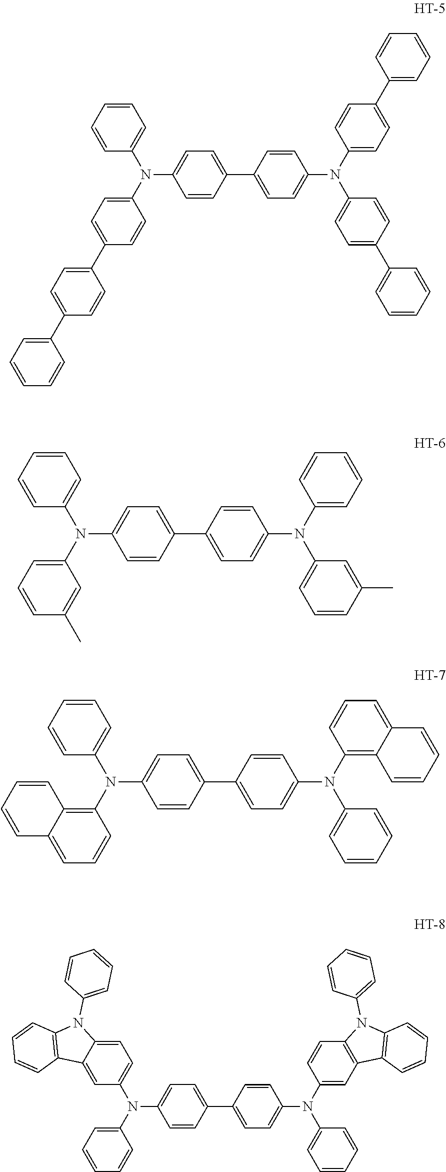 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; Cc1cccc(N(c2ccccc2)c2ccc(-c3ccc(N(c4ccccc4)c4cccc(C)c4)cc3)cc2)c1 ; c1ccc(N(c2ccc(-c3ccc(N(c4ccccc4)c4cccc5ccccc45)cc3)cc2)c2cccc3ccccc23)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

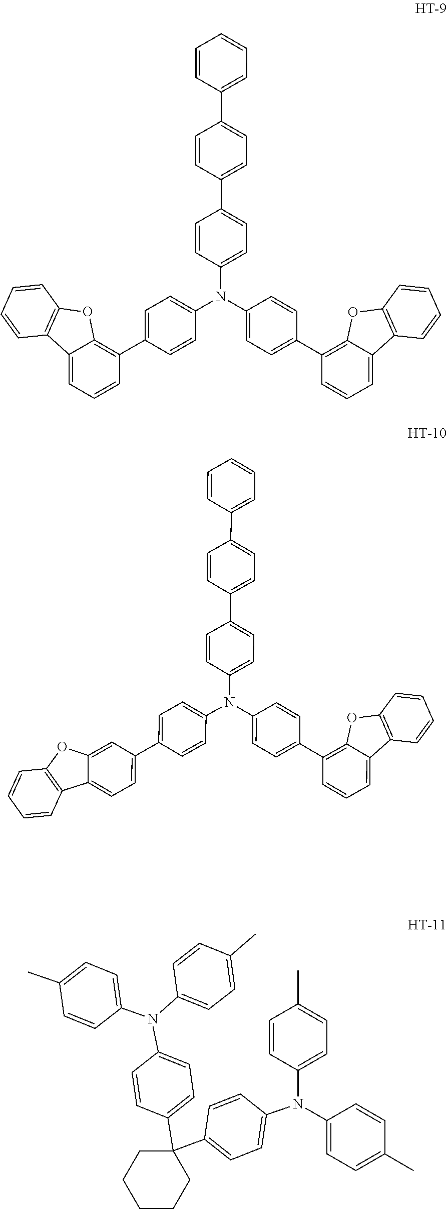

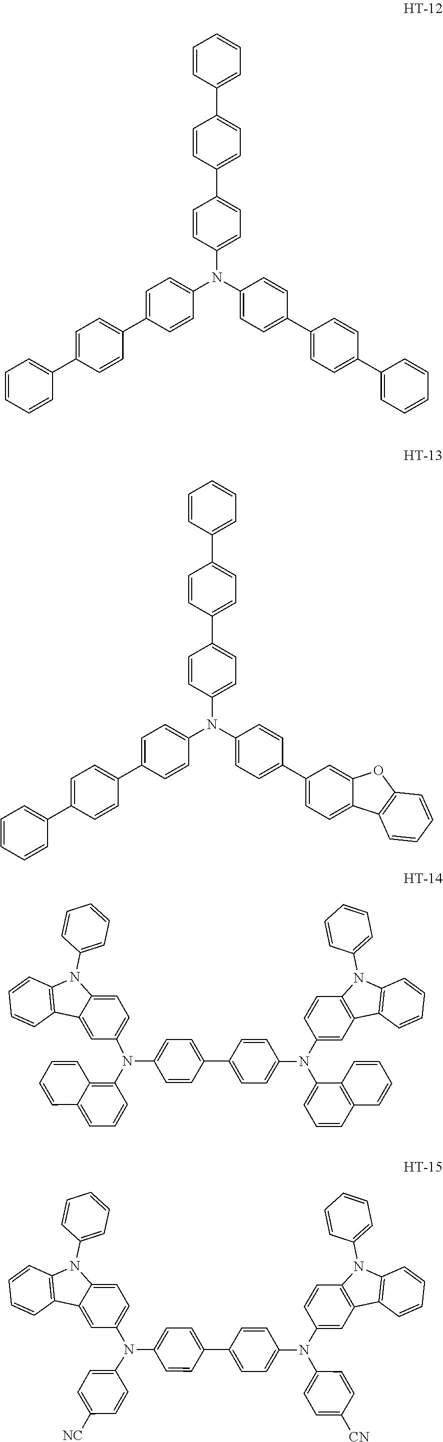 [SMILES: c1ccc(-c2ccc(-c3ccc(N(c4ccc(-c5ccc(-c6ccccc6)cc5)cc4)c4ccc(-c5ccc(-c6ccccc6)cc5)cc4)cc3)cc2)cc1 ; c1ccc(-c2ccc(-c3ccc(N(c4ccc(-c5ccc(-c6ccccc6)cc5)cc4)c4ccc(-c5ccc6c(c5)oc5ccccc56)cc4)cc3)cc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

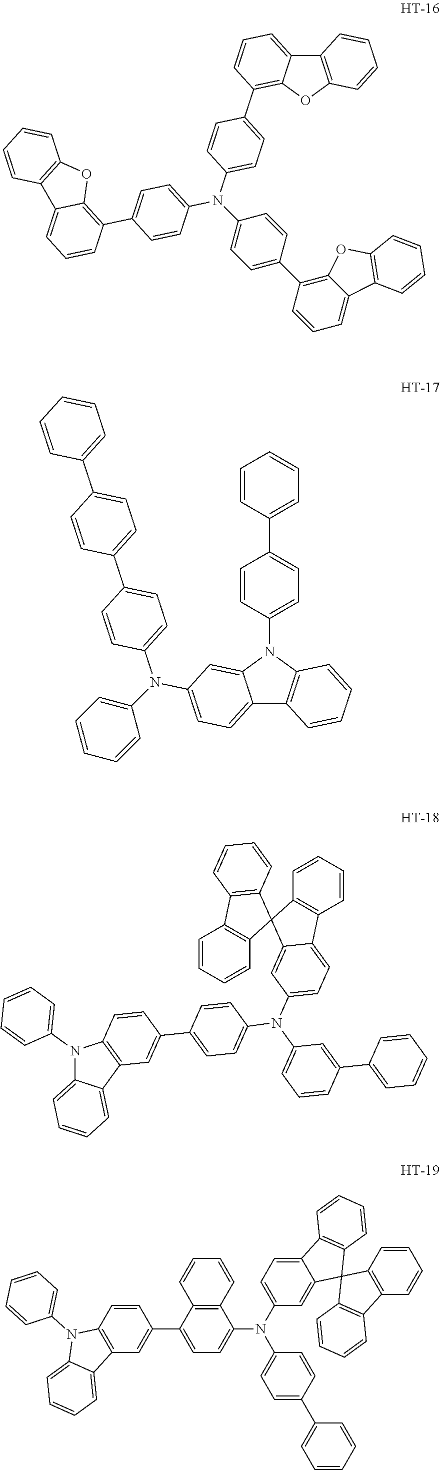 [SMILES: c1ccc2c(c1)oc1c(-c3ccc(N(c4ccc(-c5cccc6c5oc5ccccc56)cc4)c4ccc(-c5cccc6c5oc5ccccc56)cc4)cc3)cccc12 ; c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2cccc(N(c3ccc(-c4ccc5c(c4)c4ccccc4n5-c4ccccc4)cc3)c3ccc4c(c3)C3(c5ccccc5-c5ccccc53)c3ccccc3-4)c2)cc1 ; c1ccc(-c2ccc(N(c3ccc4c(c3)C3(c5ccccc5-c5ccccc53)c3ccccc3-4)c3ccc(-c4ccc5c(c4)c4ccccc4n5-c4ccccc4)c4ccccc34)cc2)cc1]

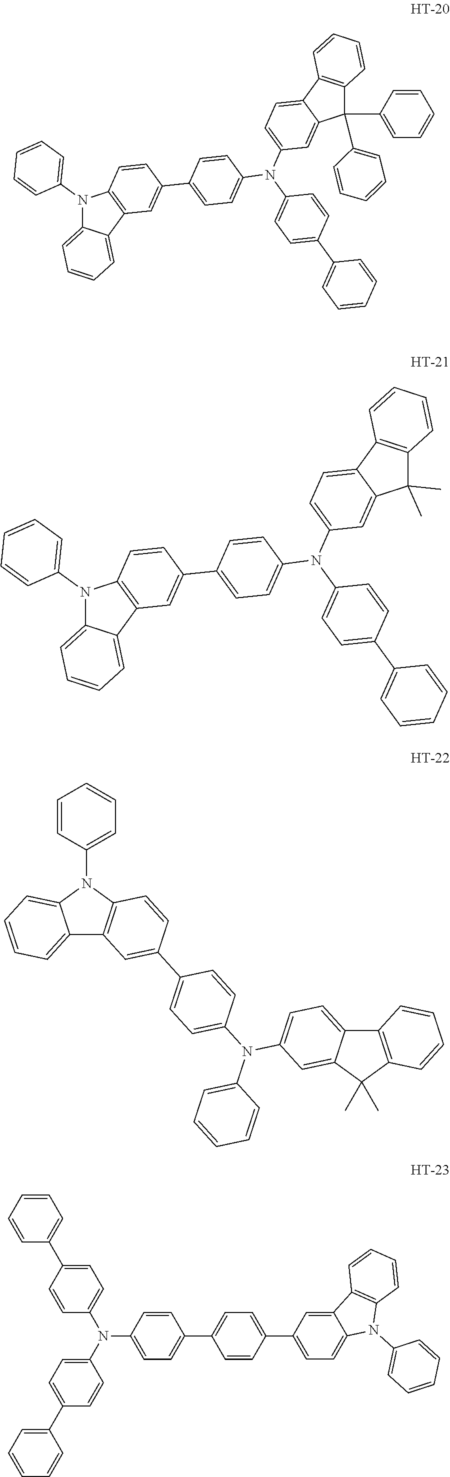 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccccc4)cc3)cc21 ; c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1]

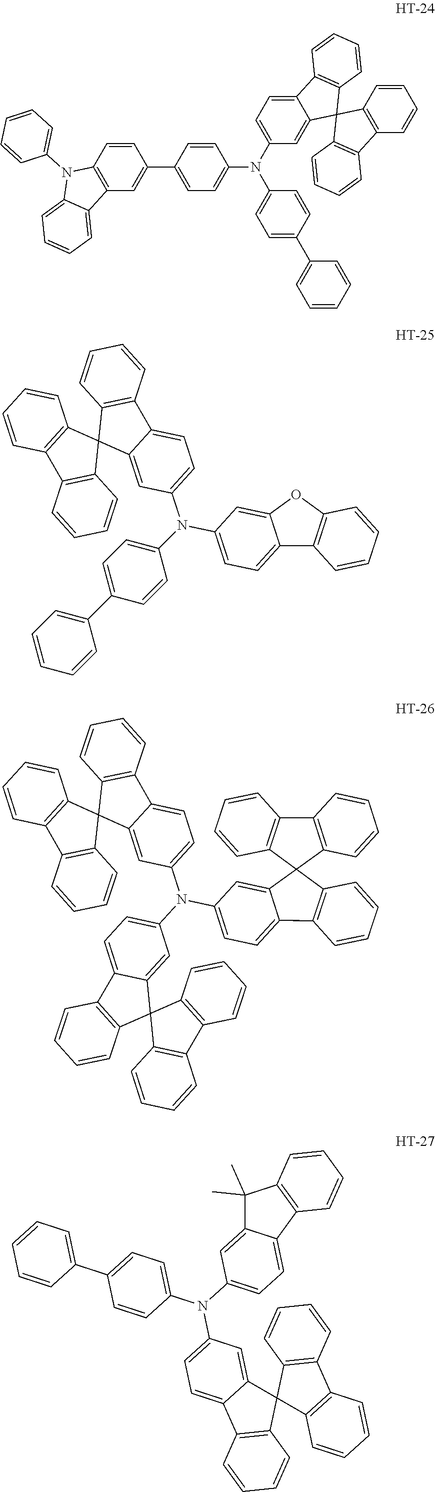 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; c1ccc(-c2ccc(N(c3ccc4c(c3)C3(c5ccccc5-c5ccccc53)c3ccccc3-4)c3ccc4c(c3)oc3ccccc34)cc2)cc1 ; c1ccc2c(c1)-c1ccccc1C21c2ccccc2-c2ccc(N(c3ccc4c(c3)C3(c5ccccc5-c5ccccc53)c3ccccc3-4)c3ccc4c(c3)C3(c5ccccc5-c5ccccc53)c3ccccc3-4)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21]

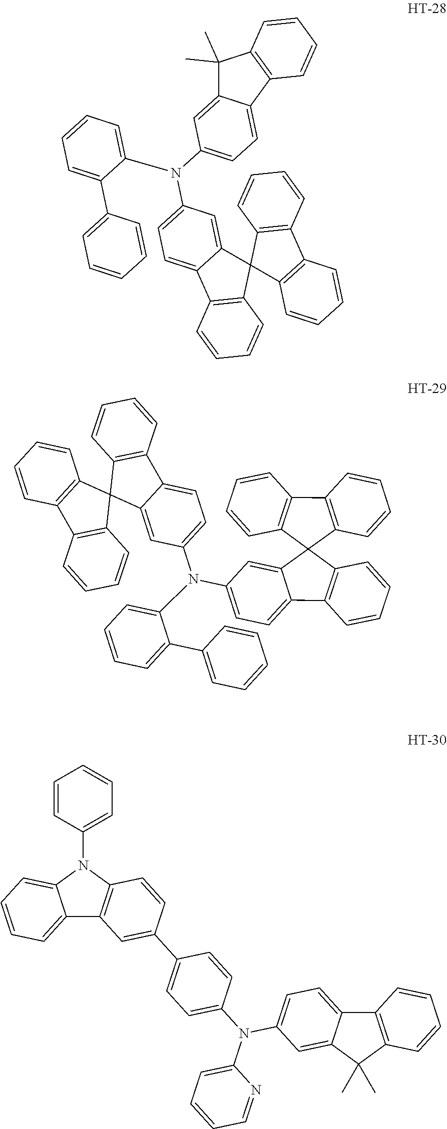 [SMILES: CC1(C)c2ccccc2-c2ccc(N(c3ccc4c(c3)C3(c5ccccc5-c5ccccc53)c3ccccc3-4)c3ccccc3-c3ccccc3)cc21 ; c1ccc(-c2ccccc2N(c2ccc3c(c2)C2(c4ccccc4-c4ccccc42)c2ccccc2-3)c2ccc3c(c2)C2(c4ccccc4-c4ccccc42)c2ccccc2-3)cc1 ; CC1(C)c2ccccc2-c2ccc(N(c3ccc(-c4ccc5c(c4)c4ccccc4n5-c4ccccc4)cc3)c3ccccn3)cc21]

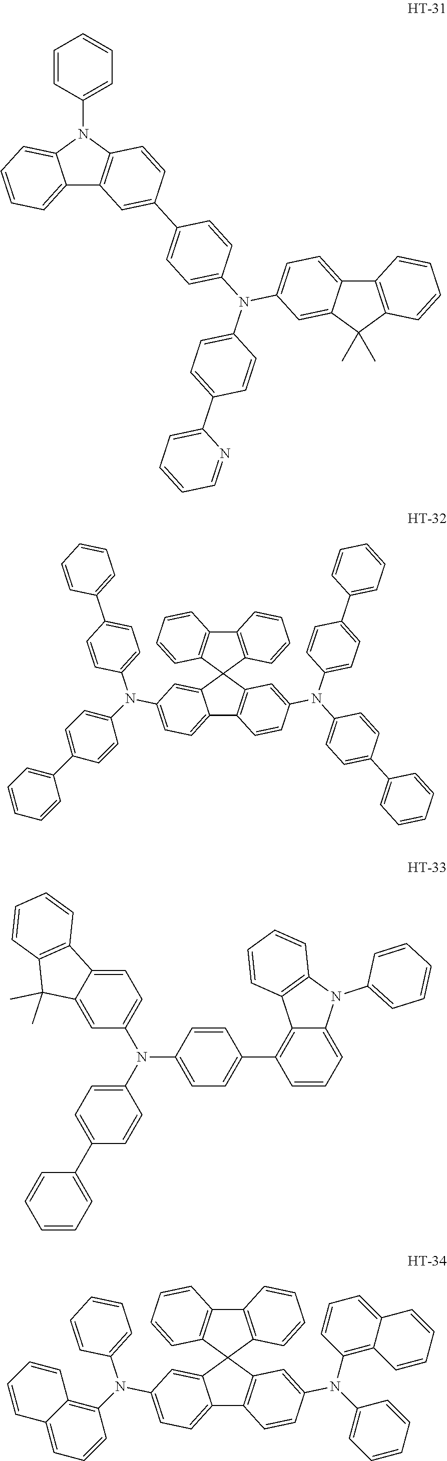 [SMILES: CC1(C)c2ccccc2-c2ccc(N(c3ccc(-c4ccc5c(c4)c4ccccc4n5-c4ccccc4)cc3)c3ccc(-c4ccccn4)cc3)cc21 ; c1ccc(-c2ccc(N(c3ccc(-c4ccccc4)cc3)c3ccc4c(c3)C3(c5ccccc5-c5ccccc53)c3cc(N(c5ccc(-c6ccccc6)cc5)c5ccc(-c6ccccc6)cc5)ccc3-4)cc2)cc1 ; CC1(C)c2ccccc2-c2ccc(N(c3ccc(-c4ccccc4)cc3)c3ccc(-c4cccc5c4c4ccccc4n5-c4ccccc4)cc3)cc21 ; c1ccc(N(c2ccc3c(c2)C2(c4ccccc4-c4ccccc42)c2cc(N(c4ccccc4)c4cccc5ccccc45)ccc2-3)c2cccc3ccccc23)cc1]

However, it is not limited to the above materials.

According to an embodiment of the present invention, the hole injection layer is located between the anode and the hole transport layer.

According to an embodiment of the present invention, the hole injection layer may be a single-compound material or a combination of a plurality of compounds.

For example, the hole injection layer may be obtained from one or more compounds of HT-1 to HT-34 described above, or from one or more compounds of HI-1 to HI-3 described below, or from doping one or more compounds of HI-1 to HI-3 described below with one or more compounds of HT-1 to HT-34:

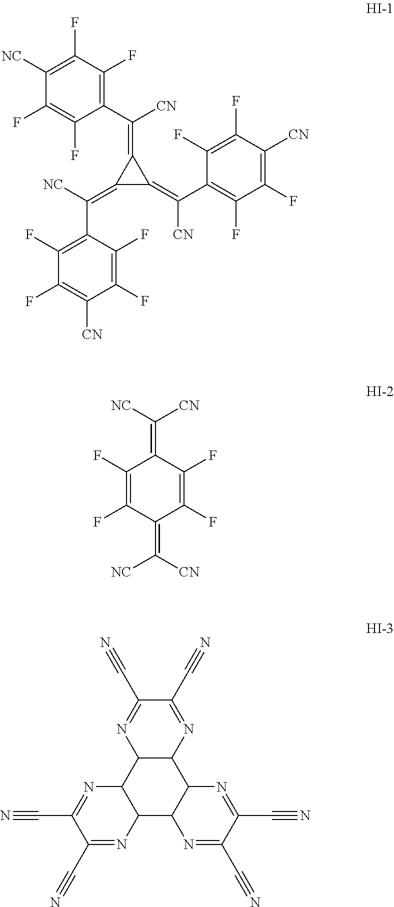 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC(C#N)=c1c(F)c(F)c(=C(C#N)C#N)c(F)c1F ; N#CC1=NC2C3N=C(C#N)C(C#N)=NC3C3N=C(C#N)C(C#N)=NC3C2N=C1C#N]

However, it is not limited to the above materials.

The OLED organic material layer may further include an electron transport region between the emissive layer and the cathode. The electron transport region may be an electron transport layer (ETL) with a single-layer structure, including a single-layer electron transport layer containing only one compound and a single-layer electron transport layer containing a plurality of compounds. The electron transport region may also be a multi-layer structure including at least one layer of an electron injection layer (EIL), an electron transport layer (ETL), and a hole blocking layer (HBL).

In an aspect of the present invention, the material of the electron transport layer may be selected from, but not limited to, one or a combination of two or more of ET-1 to ET-57 listed below.

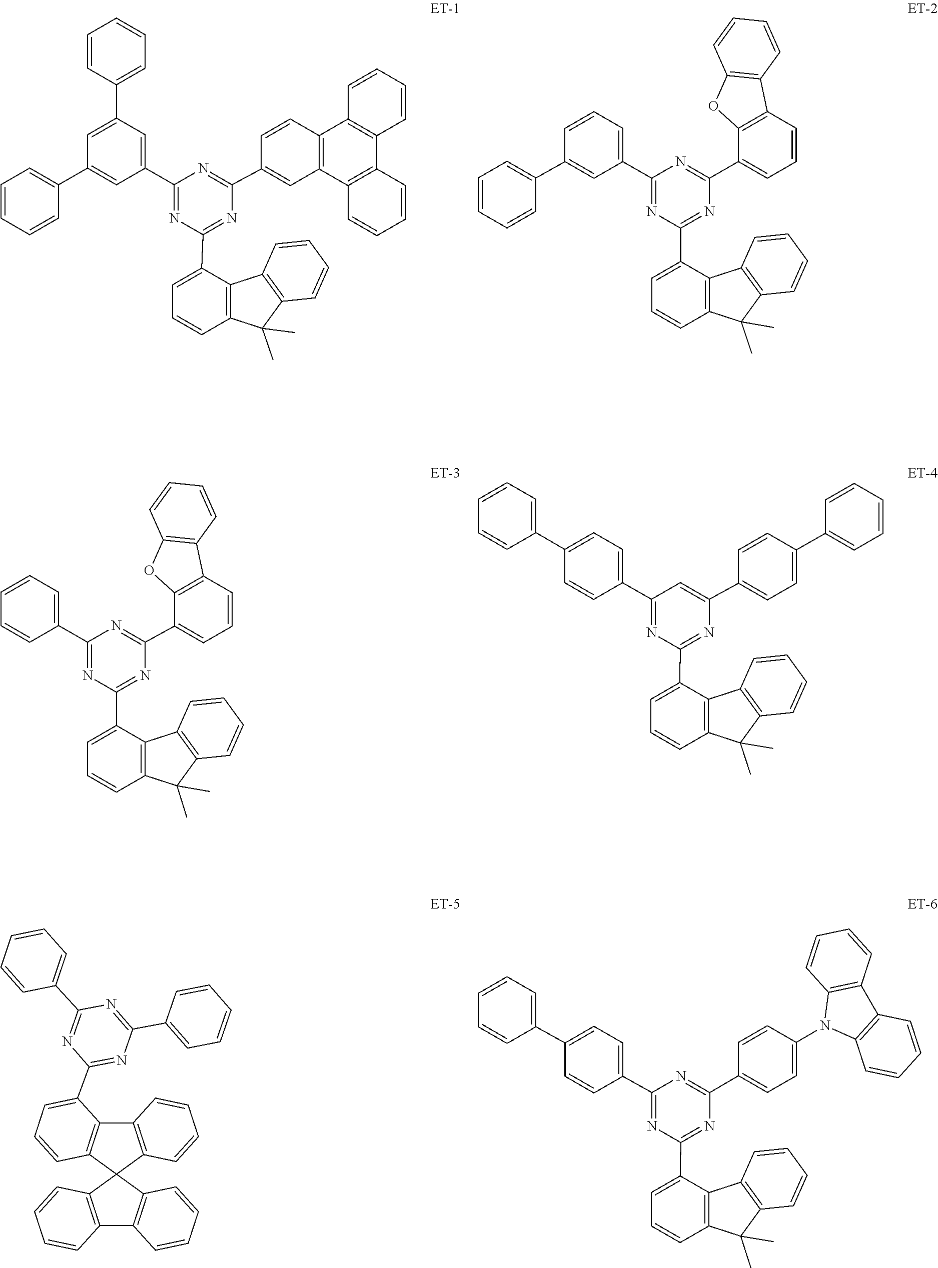 [SMILES: CC1(C)c2ccccc2-c2c(-c3nc(-c4cc(-c5ccccc5)cc(-c5ccccc5)c4)nc(-c4ccc5c6ccccc6c6ccccc6c5c4)n3)cccc21 ; CC1(C)c2ccccc2-c2c(-c3nc(-c4cccc(-c5ccccc5)c4)nc(-c4cccc5c4oc4ccccc45)n3)cccc21 ; CC1(C)c2ccccc2-c2c(-c3nc(-c4ccccc4)nc(-c4cccc5c4oc4ccccc45)n3)cccc21 ; CC1(C)c2ccccc2-c2c(-c3nc(-c4ccc(-c5ccccc5)cc4)cc(-c4ccc(-c5ccccc5)cc4)n3)cccc21 ; c1ccc(-c2nc(-c3ccccc3)nc(-c3cccc4c3-c3ccccc3C43c4ccccc4-c4ccccc43)n2)cc1 ; CC1(C)c2ccccc2-c2c(-c3nc(-c4ccc(-c5ccccc5)cc4)nc(-c4ccc(-n5c6ccccc6c6ccccc65)cc4)n3)cccc21]

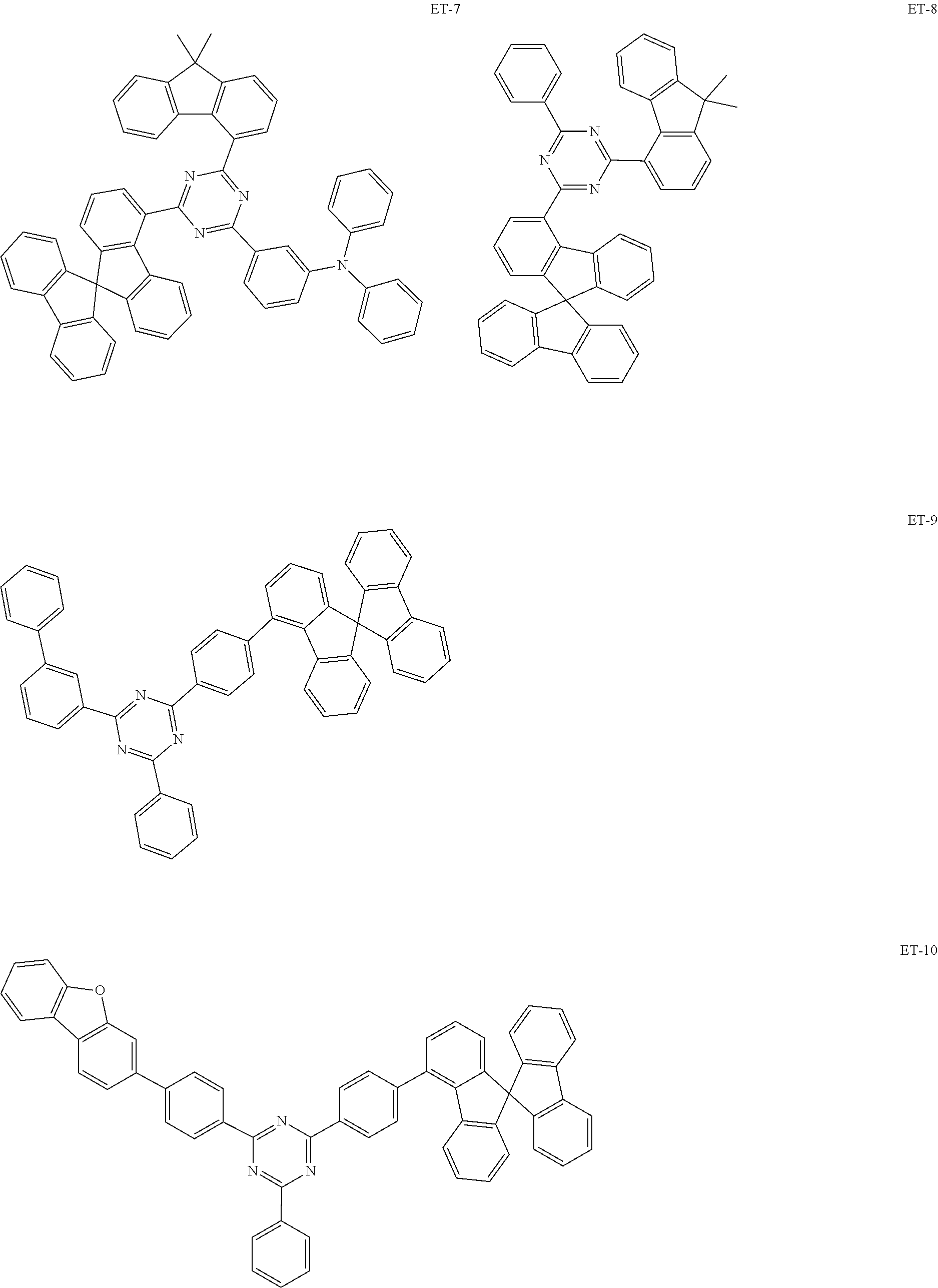 [SMILES: CC1(C)c2ccccc2-c2c(-c3nc(-c4cccc(N(c5ccccc5)c5ccccc5)c4)nc(-c4cccc5c4-c4ccccc4C54c5ccccc5-c5ccccc54)n3)cccc21 ; CC1(C)c2ccccc2-c2c(-c3nc(-c4ccccc4)nc(-c4cccc5c4-c4ccccc4C54c5ccccc5-c5ccccc54)n3)cccc21 ; c1ccc(-c2cccc(-c3nc(-c4ccccc4)nc(-c4ccc(-c5cccc6c5-c5ccccc5C65c6ccccc6-c6ccccc65)cc4)n3)c2)cc1 ; c1ccc(-c2nc(-c3ccc(-c4ccc5c(c4)oc4ccccc45)cc3)nc(-c3ccc(-c4cccc5c4-c4ccccc4C54c5ccccc5-c5ccccc54)cc3)n2)cc1]

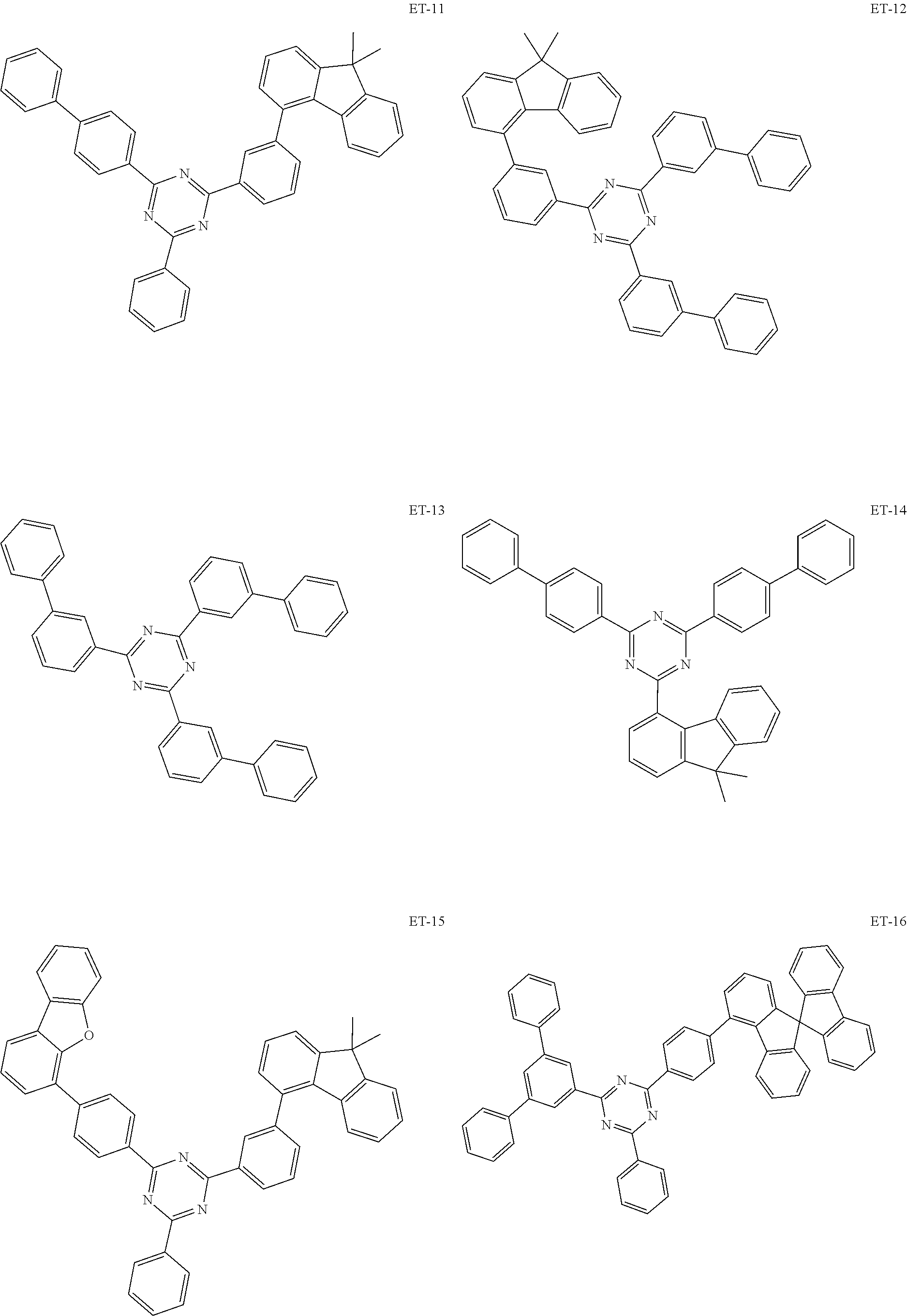

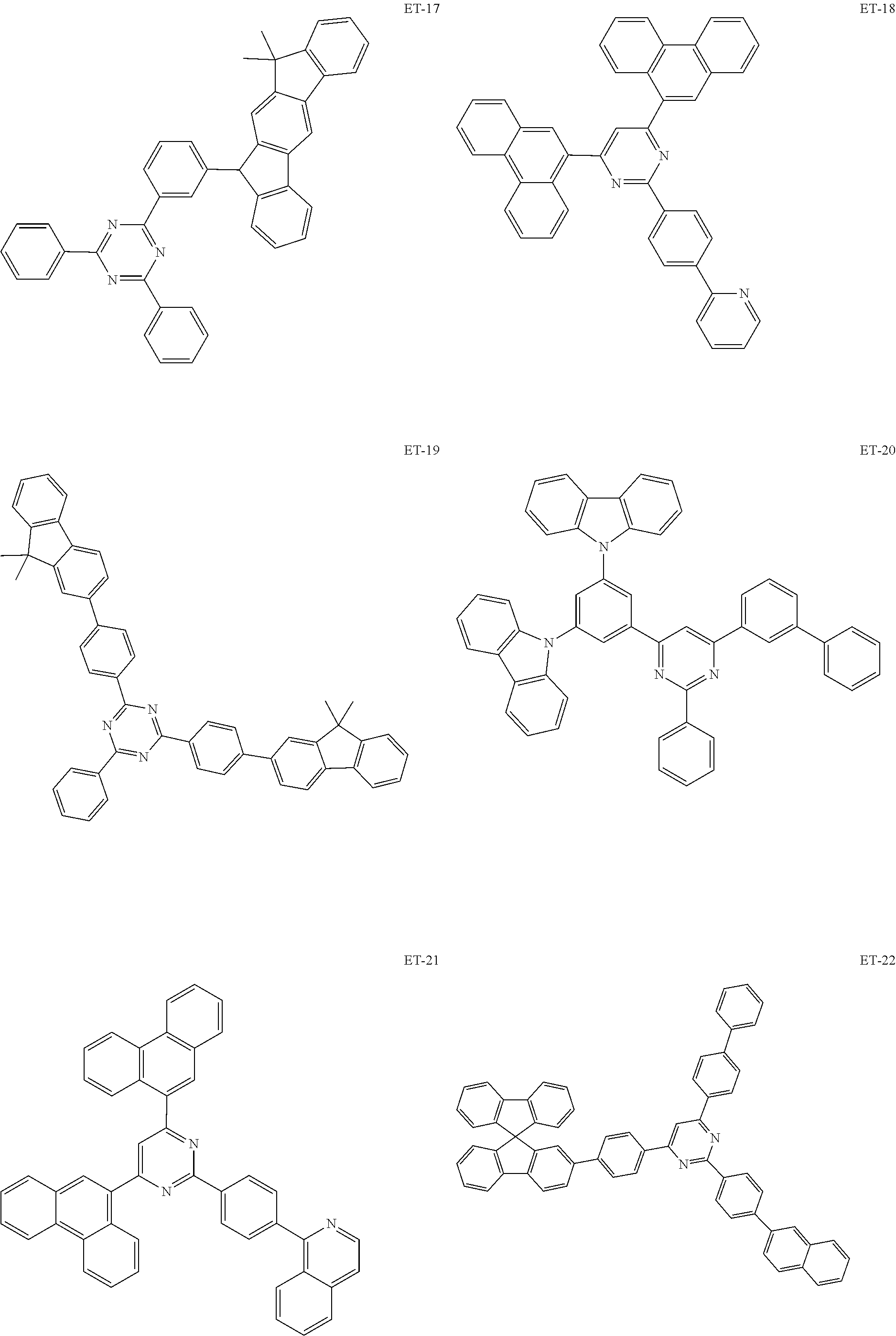

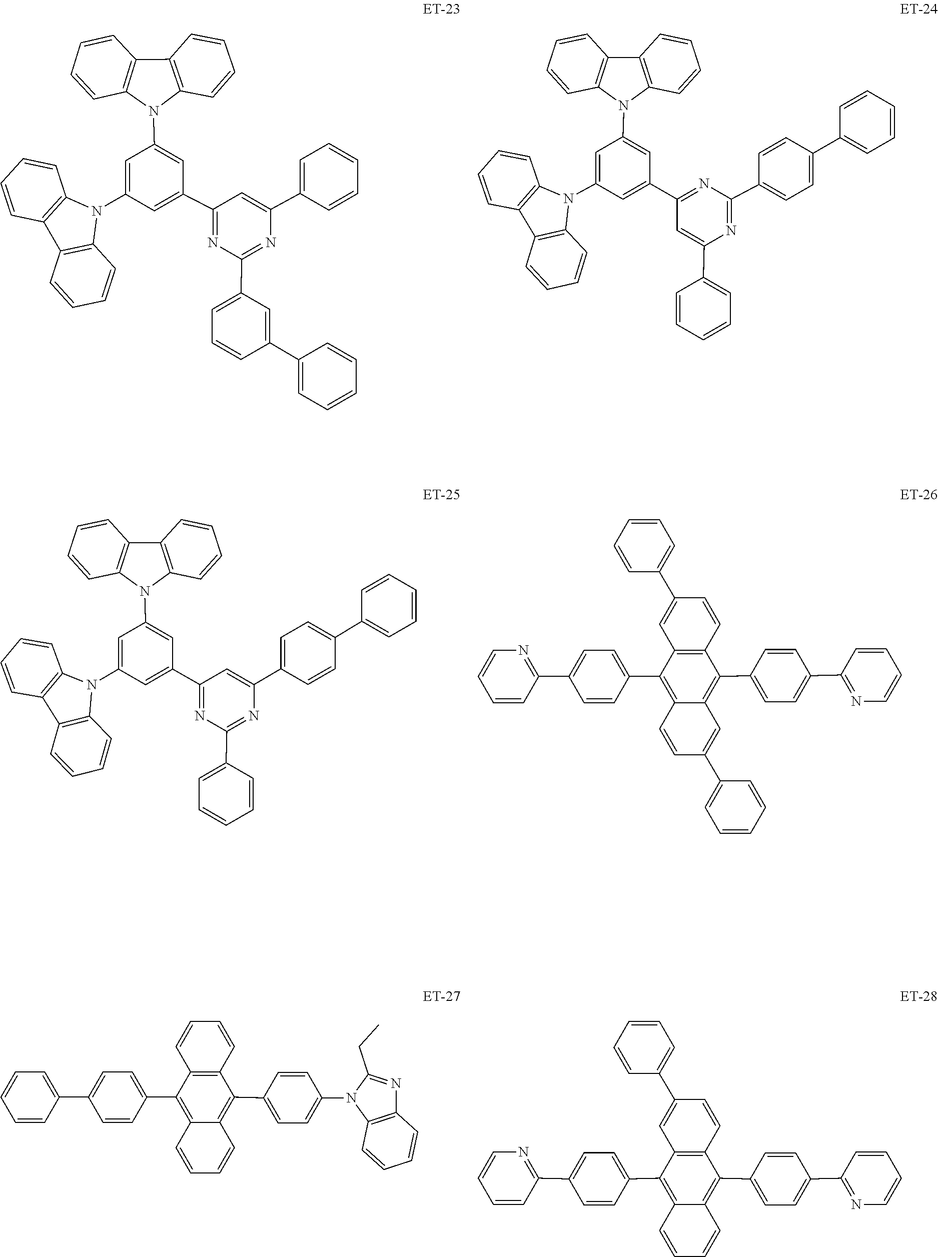

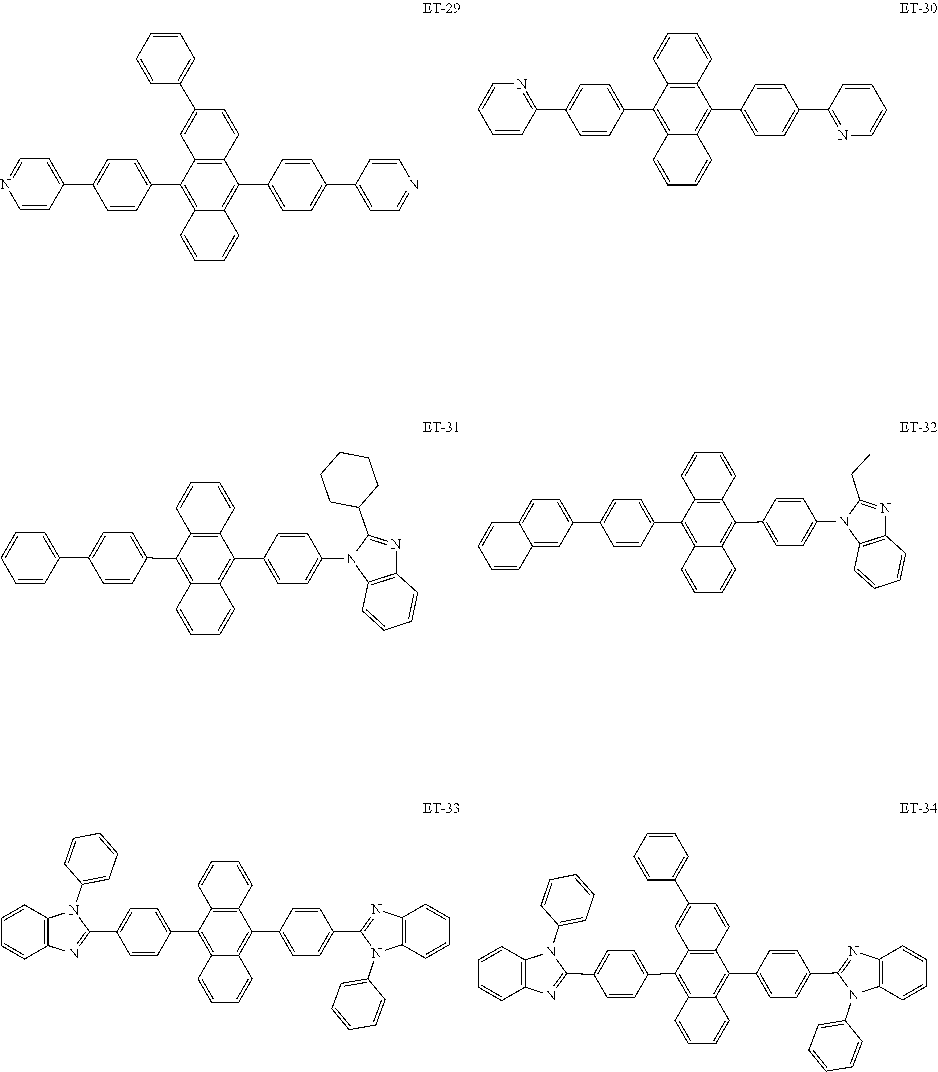

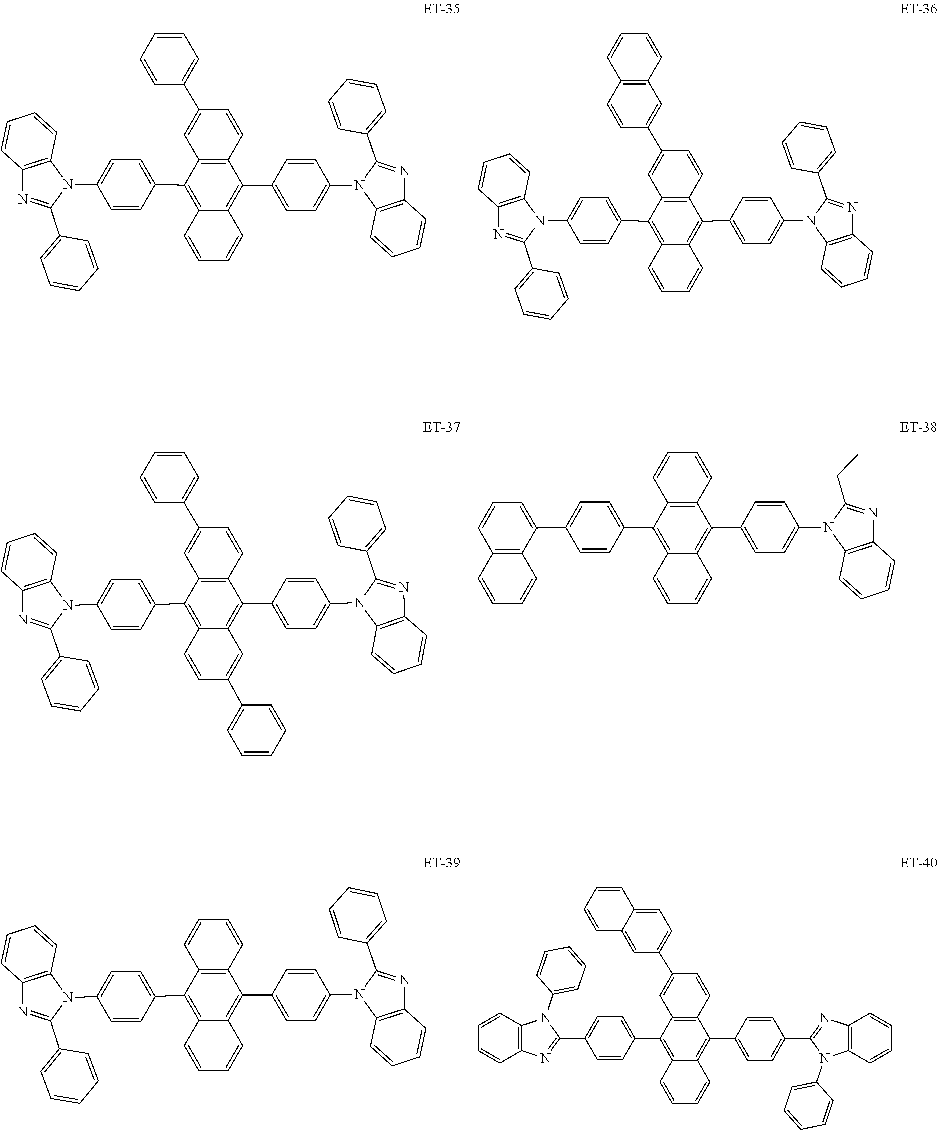

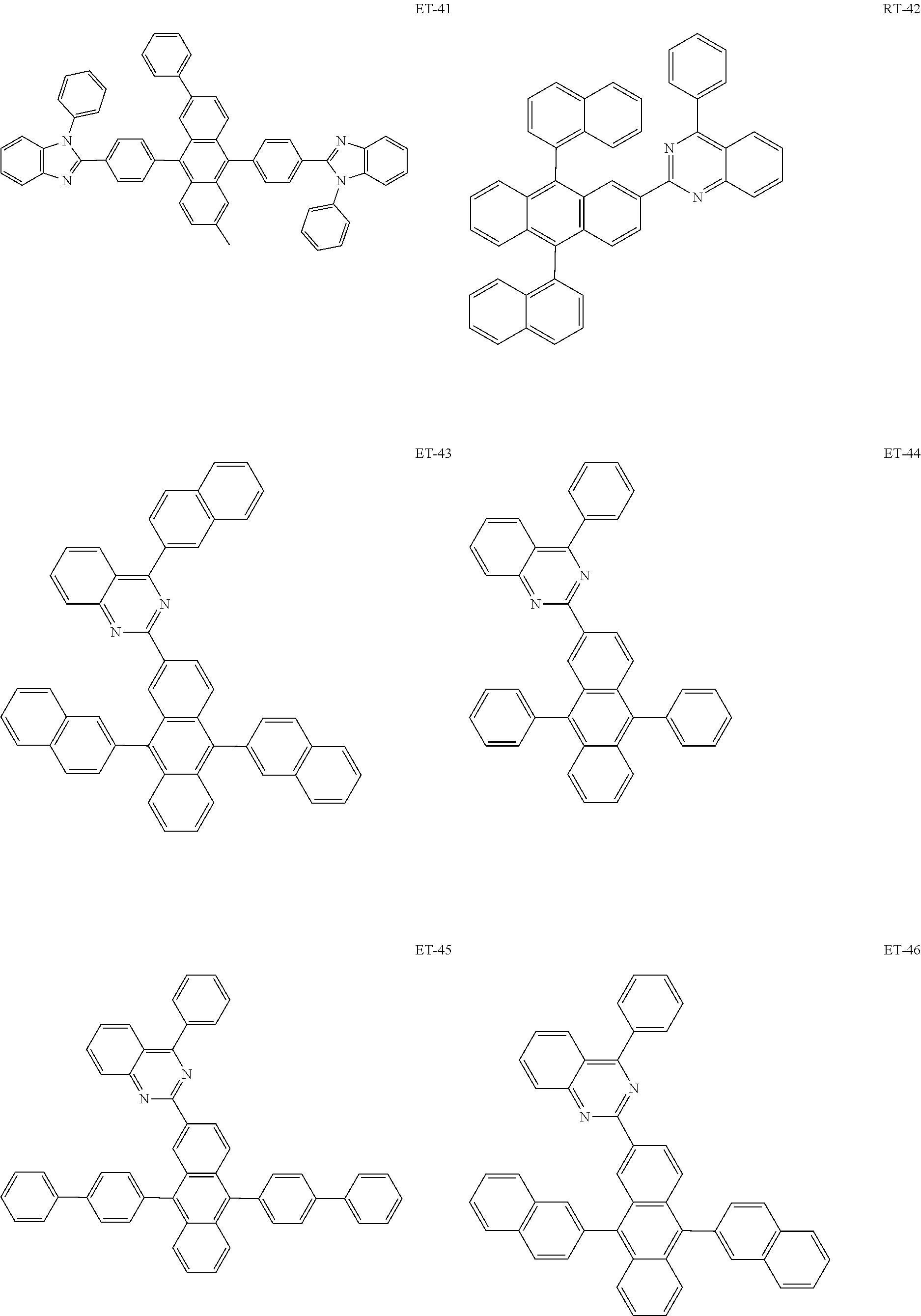

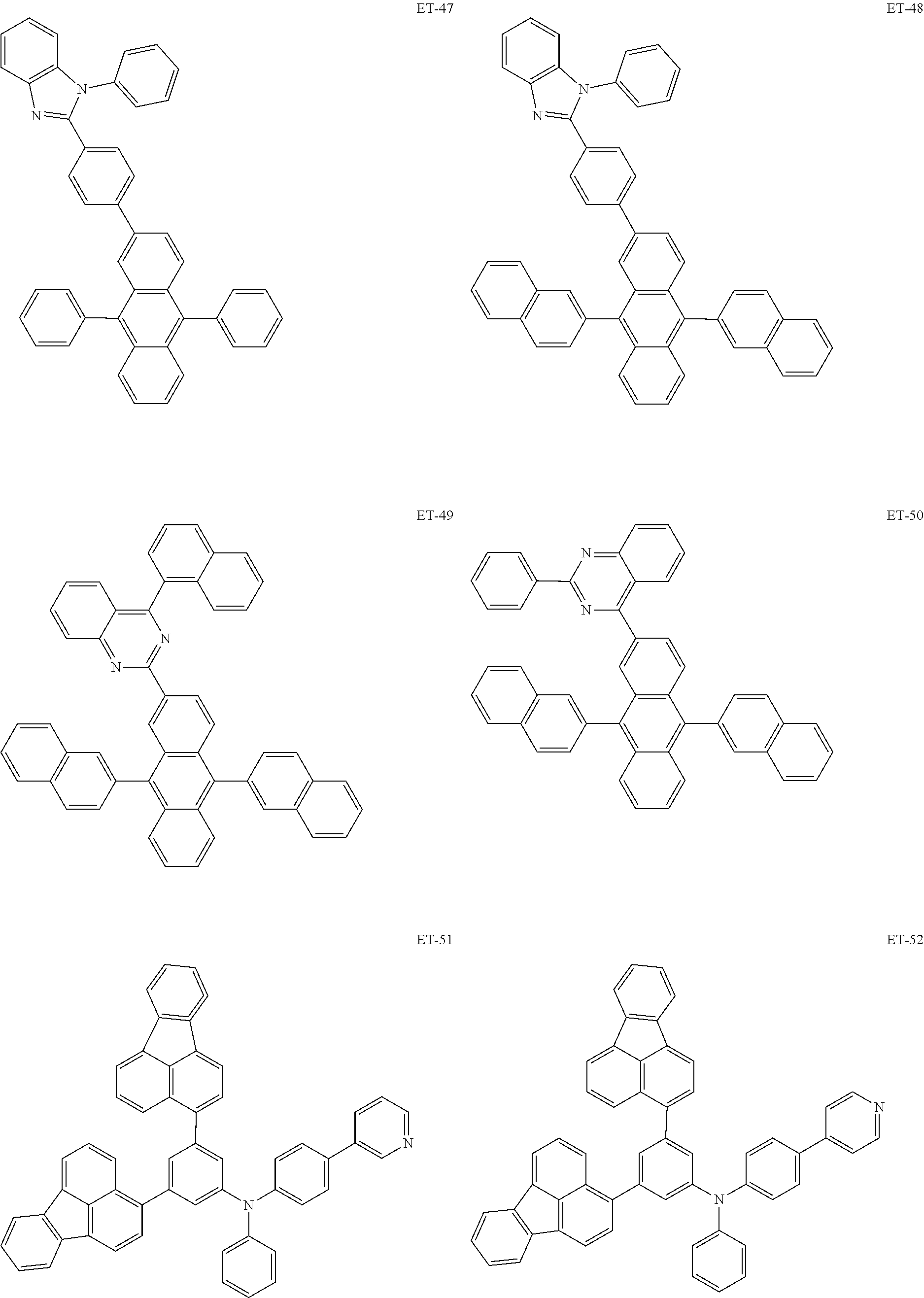

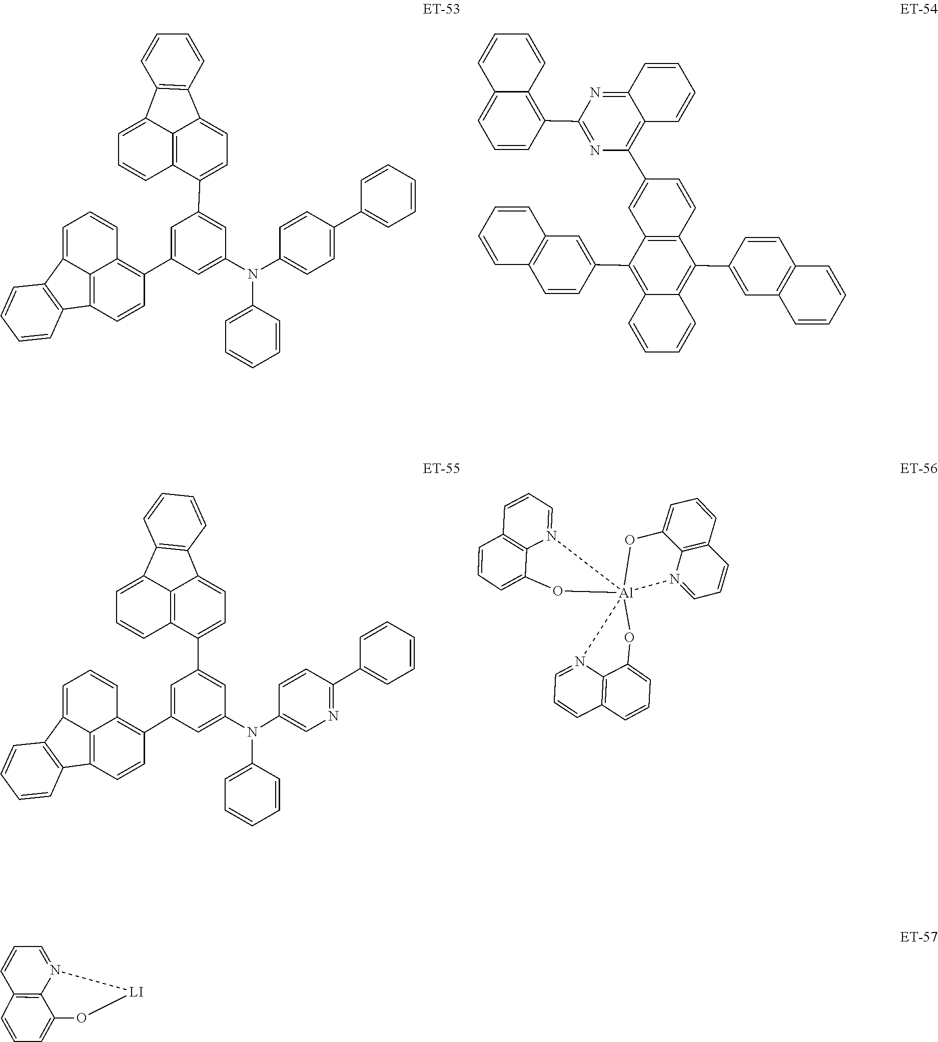

However, it is not limited to the above materials.

According to an embodiment of the present invention, the organic electroluminescent device further comprises an electron injection layer located between the electron transport layer and the cathode.

According to an embodiment of the present invention, the material of the electron injection layer is selected from one or more of LiF, NaCl, CsF, Li₂O, Cs₂CO₃, BaO, Na, Li, and Ca.

The present application has the following beneficial effects:

1) The present invention provides an organic electroluminescent dopant material and a light-emitting device. By introducing a deuterium atom group at a specific position on a thiophene ring and adjusting the molecular spacing and bond energy of the obtained compound, a dopant material having a specific atomic structure is obtained. After the obtained dopant material having a specific atomic structure is applied to the organic electroluminescent device, the driving voltage can be significantly reduced, and the luminous efficiency of the device is improved.

2) The organic electroluminescent material prepared by the present invention is used in an emissive layer of an organic electroluminescent device. Since the light-emitting material is a structure composed of a specific dopant material and a host material, and is designed in combination with other layer materials, the effects of effectively reducing the turn-on and turn-off voltages of the organic electroluminescent device and improving the efficiency of the device can be achieved.

### BRIEF DESCRIPTION OF THE DRAWING

FIG. 1 shows a nuclear magnetic resonance hydrogen spectrum of a compound of formula LAF-1 according to an example of the present invention.

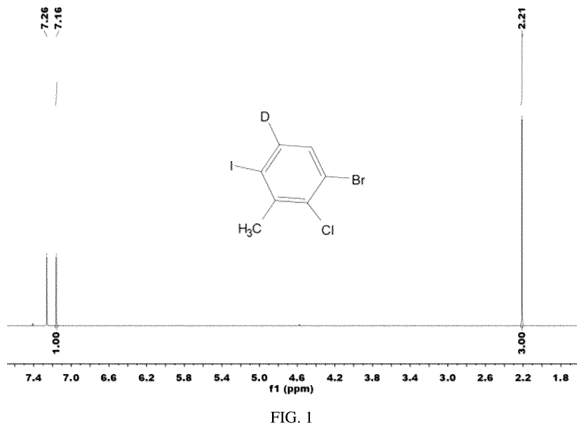

### DETAILED DESCRIPTION

The technical solutions will be described clearly and completely below with reference to the synthesis examples and examples of the present invention, and it is apparent that the described examples are only a part of the examples of the present invention, but not all of them. Based on the examples of the present invention, all examples obtained by those of ordinary skills in the art without creative work shall fall within the protection scope of the present invention.

### Synthesis Example 1

This synthesis example provides an organometallic compound I-1, and the specific synthesis steps are as follows:

1)

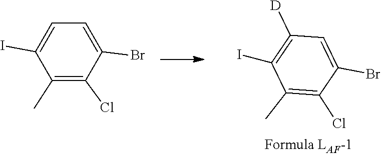

Under nitrogen the compounds 1-bromo-2-chloro-4-iodo-3-methylbenzene (CAS: 1000573-57-8) (1700 mmol), deuterated benzene (170000 mmol), and trifluoromethanesulfonic acid (5100 mmol) were weighed out and added into a reaction system. The mixture was refluxed for 18 h under nitrogen atmosphere. After the reaction was complete, the mixture was quenched by the addition of heavy water, extracted with ethyl acetate, washed three times with saturated brine, concentrated under reduced pressure, and subjected to column chromatography (200-300 mesh, 6000 g) with a developing solvent of DCM:PE=1:10. The receiving liquid was rotated until no liquid flowed out to obtain a compound of formula LAF-1 (461.19 g, 82% yield).

The intermediate compound of formula LAF-1 was subjected to the following analytical tests:

HPLC purity: greater than 99.5%; mass spectrum: measured value 330.92.

2)

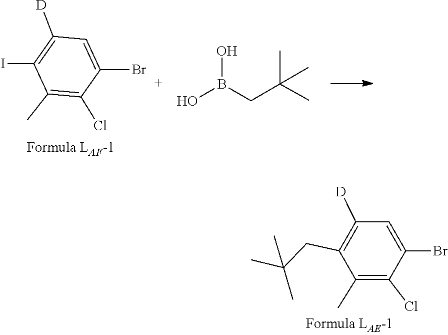

Under nitrogen atmosphere, the compound represented by formula LAF-1 (1350 mmol), neopentyl boronic acid (CAS: 701261-35-0) (1350 mmol), and anhydrous potassium carbonate (4050 mmol) were weighed out and added into a reaction system, and 3600 mL of toluene, 1800 mL of absolute ethanol, and 1800 mL of purified water were added. Pd(PPh₃)₄ (27 mmol) was added under nitrogen atmosphere, and the mixture was refluxed at 100° C. for 22 h under nitrogen atmosphere.

After the reaction was complete, the mixture was subjected to liquid separation, extracted with ethyl acetate, washed three times with saturated brine, and concentrated under reduced pressure. 600 mL of dichloromethane was added for dissolution, and the solution was subjected to column chromatography (200-300 mesh, 2900 g) with a developing solvent of DCM:PE=1:5. The receiving liquid was rotated until no liquid flowed out to obtain a compound of formula LAE-1 (129.95 g, yield: 35%). The intermediate compound of formula LAE-1 was subjected to the following analytical tests:

HPLC purity: greater than 99.5%; mass spectrum: measured value 275.18.

3)

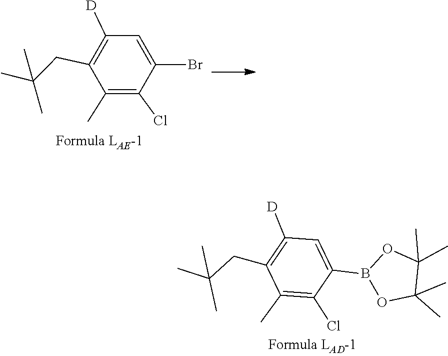 [SMILES: [2H]c1cc(Br)c(Cl)c(C)c1CC(C)(C)C ; [2H]c1cc(B2OC(C)(C)C(C)(C)O2)c(Cl)c(C)c1CC(C)(C)C]

Under nitrogen atmosphere, the compound of formula LAE-1 (470 mmol), bis(pinacolato)diboron (470 mmol), X-Phos (94 mmol), palladium acetate (9.4 mmol), potassium acetate (1410 mmol), and dioxane (2850 mL) were sequentially added to a reaction system. The system was purged with N₂ for three times and heated and stirred overnight at 100° C. under N₂ atmosphere. After the reaction was complete, the mixture was filtered through celite and anhydrous magnesium sulfate, and washed twice with ethyl acetate. The organic phase was collected and concentrated under reduced pressure to obtain a crude product, i.e., an intermediate compound represented by formula L_{AD}-1, which was directly used in the next step.

4)

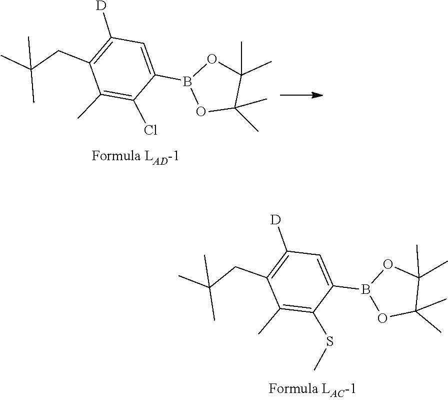

Under nitrogen atmosphere, the compound of formula L_{AD}-1 (470 mmol), cuprous bromide (470 mmol), and anhydrous sodium methanethiolate (1410 mmol) were sequentially added to DMF (1850 mL), and subsequently water (185 mL) was added. The system was purged with N₂ for three times and heated and stirred at 140° C. for 41 h under N₂ atmosphere. After the reaction was complete, the mixture was cooled to room temperature, and the reaction solution was poured into 3 volumes of water to precipitate a solid and filtered. The solid was dissolved with DCM, and the filtrate was passed through a silica gel funnel, rinsed with DCM, and concentrated to dryness by rotary evaporation to obtain a crude product, i.e., an intermediate compound represented by formula LAC-1, which was directly used in the next step.

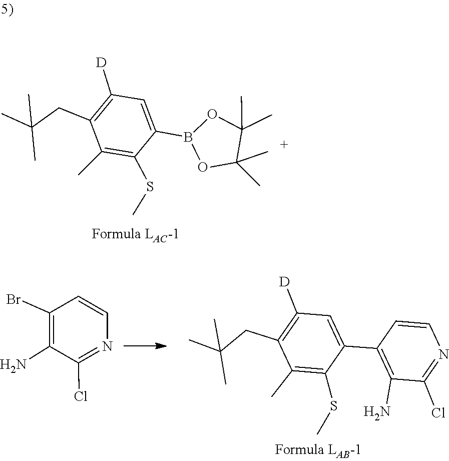

Under nitrogen atmosphere, the compound of formula LAC-1 (470 mmol), 2-chloro-3-amino-4-bromopyridine (CAS: 1354021-09-2) (470 mmol), and anhydrous potassium carbonate (1410 mmol) were weighed out and added into a reaction system. 3100 mL of toluene, 1550 mL of absolute ethanol, and 1550 mL of purified water were added. Pd(PPh₃)₄ (9.4 mmol) was added under nitrogen atmosphere, and the mixture was refluxed at 100° C. for 23 h under nitrogen atmosphere. After the reaction was complete, the mixture was subjected to liquid separation, extracted with ethyl acetate, washed three times with saturated brine, and concentrated under reduced pressure. 750 mL of dichloromethane was added for dissolution, and the solution was subjected to column chromatography (200-300 mesh, 2350 g) with a developing solvent of DCM:PE=1:2. The receiving liquid was rotated until no liquid flowed out to obtain a compound of formula L_{AB}-1 (67.89 g, yield: 43%). The intermediate compound of formula L_{AB}-1 was subjected to the following analytical tests:

HPLC purity: greater than 99.5%; mass spectrum: measured value 335.96.

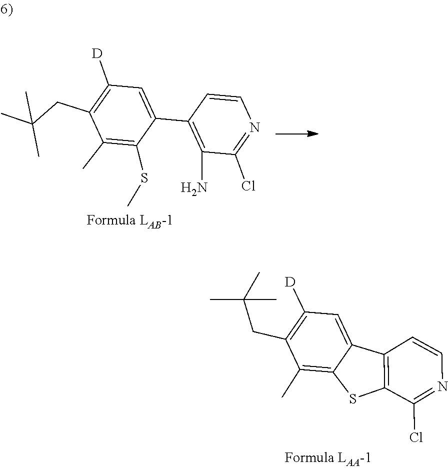 [SMILES: [2H]c1cc(-c2ccnc(Cl)c2N)c(SC)c(C)c1CC(C)(C)C ; [2H]c1cc2c(sc3c(Cl)nccc32)c(C)c1CC(C)(C)C]

Under nitrogen atmosphere, the compound of formula L_{AB}-1 (200 mmol) was weighed out and completely dissolved with THF (810 mL) in a reaction system. After the internal temperature was increased to 55-57° C., the heating was stopped, copper acetate (200 mmol) was added, and then a solution of tert-butyl nitrite (240 mmol) in THF (105 mL) was carefully added dropwise to the above system. The system exhibited heat release and gas evolution. After the dropwise addition was complete, the temperature was maintained for 1.5 h before the reaction was complete. The reaction solution was directly concentrated to dryness under reduced pressure, and then DCM (1300 mL) was added to carry out refluxing for clear dissolution. The solution was passed through a silica gel column, and the column liquid was collected and concentrated under reduced pressure until a solid precipitated after a volume of about 90 mL remained. The mixture was cooled to a temperature lower than 20° C., filtered, drained, and dried to obtain a compound of formula L_{AA}-1 (25.00 g, yield: 41%). The intermediate compound of formula L_{AA}-1 was subjected to the following analytical tests:

HPLC purity: greater than 99.5%;

mass spectrum: measured value 304.94.

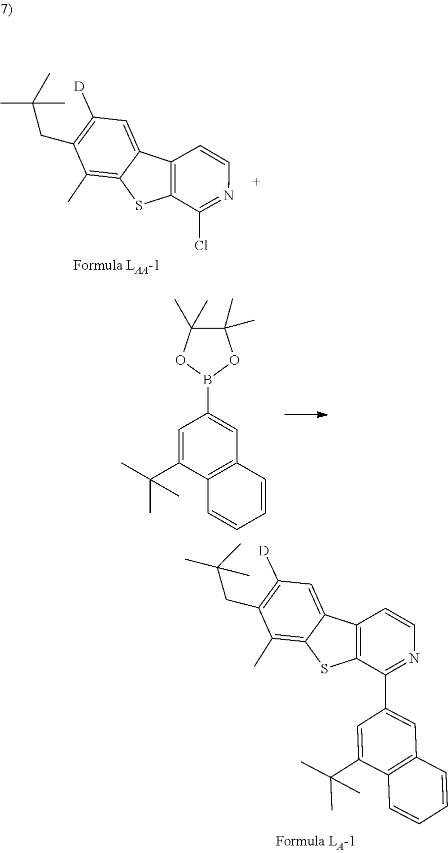

Under nitrogen atmosphere, the compound of formula L_{AA}-1 (80 mmol), [4-(tert-butyl)naphthalene]-2-boronic acid pinacol ester (CAS: 2217657-10-6) (96 mmol), and anhydrous potassium carbonate (240 mmol) were weighed out and added into a reaction system. 1200 mL of toluene, 600 mL of absolute ethanol, and 600 mL of purified water were added. Pd(PPh₃)₄ (1.6 mmol) was added under nitrogen atmosphere, and the mixture was refluxed at 100° C. for 23 h under nitrogen atmosphere. After the reaction was complete, the mixture was subjected to liquid separation, extracted with ethyl acetate, washed three times with saturated brine, and concentrated under reduced pressure. 185 mL of dichloromethane was added for dissolution, and the solution was subjected to column chromatography (200-300 mesh, 700 g) with a developing solvent of DCM:PE=1:4. The receiving liquid was rotated until no liquid flowed out to obtain a compound of formula L_{A}-1 (22.79 g, yield: 63%). The intermediate compound of formula L_{A}-1 was subjected to the following analytical tests:

HPLC purity: greater than 99.5%;

mass spectrum: measured value 452.38.

Elemental analysis: calculated C, 82.25; H, 7.57; N, 3.09; S, 7.08. The measured values were C, 82.26; H, 7.56; N, 3.08; S, 7.09.

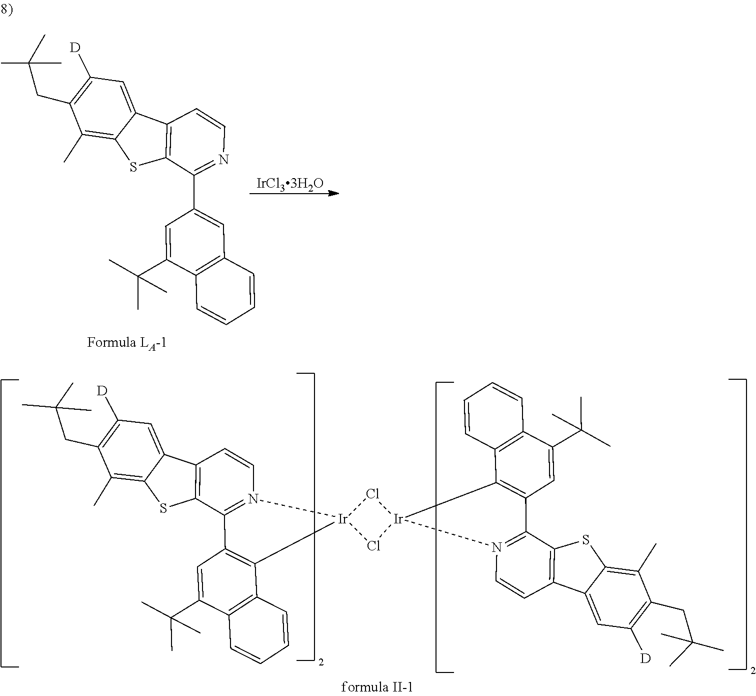

Under nitrogen atmosphere, the ligand of formula L_{A}-1 (52.8 mmol) and IrCl₃·3H₂O (22 mmol) were weighed out and added into a reaction system, and a mixed solution of 480 mL of ethylene glycol ethyl ether and 160 mL of purified water was added. The mixture was refluxed for 30 h under nitrogen protection, and then cooled to room temperature, and a precipitate was precipitated. The precipitate was filtered under vacuum, washed with water, absolute ethanol, and petroleum ether in sequence, and dried to obtain a bridging ligand II-1 as a dark red powder (15.67 g, yield: 63%).

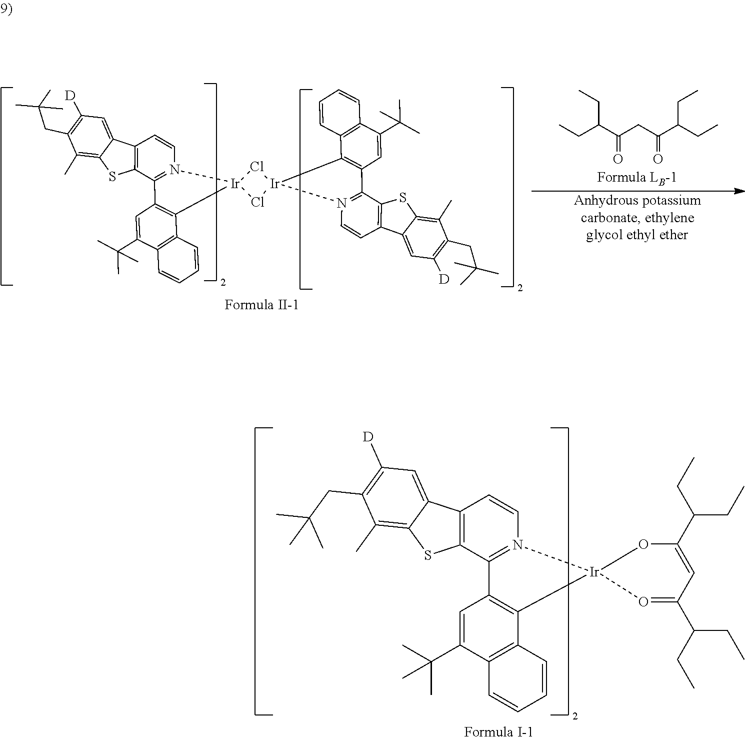

The bridging ligand II-1 (5.5 mmol) was weighed out, anhydrous potassium carbonate (55 mmol) was added, and 230 mL of ethylene glycol ethyl ether was added into the system. The system was purged with nitrogen three times, and the compound of formula L_{B}-1 (CAS: 872802-98-7) (16.5 mmol) was added under nitrogen atmosphere. The mixture was refluxed for 28 h under nitrogen atmosphere, cooled, filtered under vacuum, washed with alcohol, and dried. Dichloromethane was used as a solvent, and neutral alumina was used for column chromatography. The filtrate was concentrated to precipitate a solid, and finally the organic phosphorus luminescent material shown by I-1 (4.17 g, yield: 29%) was obtained.

The obtained organometallic compound having a structure represented by formula I-1 was subjected to analytical tests:

HPLC purity: greater than 99.5%;

mass spectrum: measured value 1306.72.

Elemental analysis: calculated C, 68.93; H, 6.86; N, 2.14; O, 2.45; S, 4.91. The measured values were C, 68.91; H, 6.88; N, 2.15; O, 2.46; S, 4.90;

¹H NMR (400 MHz, Chloroform-d) δ 8.87 (d, 2H), 8.34 (dd, 2H), 8.01-7.94 (m, 2H), 7.81 (d, 2H), 7.70 (d, 2H), 7.54 (s, 2H), 7.45 (td, 2H), 7.37 (td, 2H), 5.65 (dd, 1H), 2.76 (pd, 1H), 2.62 (s, 4H), 2.48 (pd, 1H), 2.31 (s, 6H), 1.63-1.51 (m, 4H), 1.50-1.44 (m, 4H), 1.43 (d, 18H), 1.00 (d, 18H), 0.89 (t, 12H).

### Synthesis Example 2

This synthesis example provides an organometallic compound I-193, i.e., the compound numbered I-193, and the specific synthesis steps are as follows:

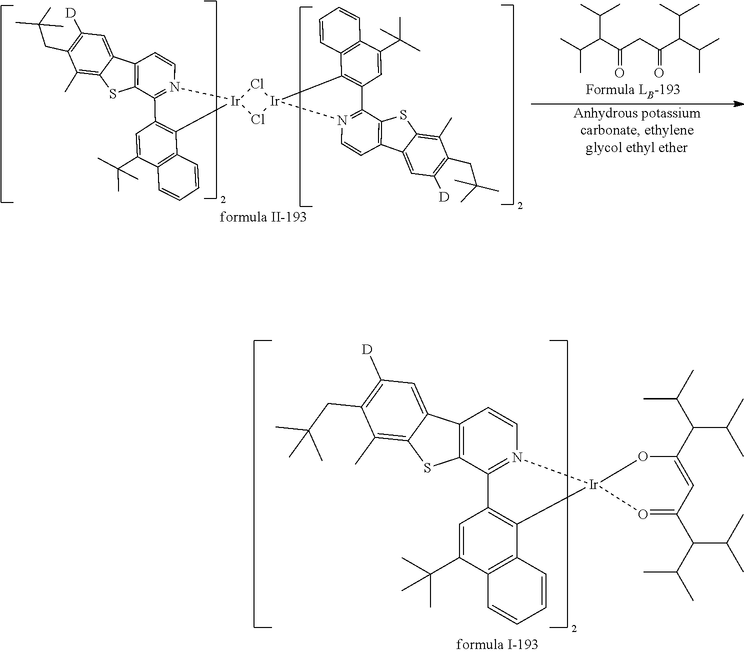

The synthesis method of formula II-193 is as shown in Synthesis Example 1, and details are not described again.

The bridging ligand II-193 (5.5 mmol) was weighed out, anhydrous potassium carbonate (55 mmol) was added, and 240 mL of ethylene glycol ethyl ether was added into the system. The system was purged with nitrogen three times, and the compound of formula L_{B}-193 (CAS: 1821143-86-5) (22.0 mmol) was added under nitrogen atmosphere. The mixture was refluxed for 28 h under nitrogen atmosphere, cooled, filtered under vacuum, washed with alcohol, and dried. Dichloromethane was used as a solvent, and neutral alumina was used for column chromatography. The filtrate was concentrated to precipitate a solid, and finally the organometallic compound shown by I-193 (3.79 g, yield: 27%) was obtained. The organometallic compound I-193 was subjected to the following analytical tests:

HPLC purity: greater than 99.5%;

mass spectrum: measured value 1362.75.

Elemental analysis: calculated C, 69.62; H, 7.17; N, 2.06; O, 2.35; S, 4.70. The measured values were C, 69.63; H, 7.16; N, 2.07; O, 2.34; S, 4.71;

¹H NMR (400 MHz, Chloroform-d) δ 8.87 (d, 2H), 8.34 (dd, 2H), 8.01-7.94 (m, 2H), 7.81 (d, 2H), 7.70 (d, 2H), 7.54 (s, 2H), 7.45 (td, 2H), 7.37 (td, 2H), 5.61 (dd, 1H), 2.66 (td, 1H), 2.62 (s, 4H), 2.31 (s, 6H), 2.14 (ddd, 1H), 2.00 (dq, 2H), 1.85 (dq, 2H), 1.45-1.40 (m, 18H), 1.04-0.97 (m, 18H), 0.96-0.87 (m, 24H).

The present invention further provides an organic electroluminescent device comprising the organic electroluminescent dopant material of the present invention, more specifically, an organic electroluminescent dopant material comprising a compound having the structure shown in chemical formula I.

For the purpose of further describing the present invention, more specific examples are set forth below.

### Device Example 1

Devices and apparatuses in all examples were made by high vacuum (<10⁻⁷ Torr) thermal evaporation. The anode electrode was 1200 angstroms of indium tin oxide (ITO), and the cathode consisted of 10 angstroms of Liq (lithium 8-hydroxyquinolinate) followed by 1000 angstroms of Al. The device was encapsulated with a glass lid sealed with epoxy resin in a nitrogen glove box (H₂O and O₂<1 ppm) immediately after fabrication, and the moisture scavenger was incorporated inside the packaging.

The organic stack of the device example is, in order: ITO surface, 100 angstroms of HT-16 as a hole injection layer (HIL); 400 angstroms of HT-16 as a hole transport layer (HTL); 50 angstroms of EBM as an electron blocking layer (EBL); 400 angstroms of an emissive layer (EML) containing RH-01 as a red host and 3% of the emitter compound of formula I-1; 350 angstroms of Liq (lithium 8-hydroxyquinolinate) doped with 35% of ET-16 as an electron transport layer (ETL). Table 2 shows the thicknesses and materials of the device layers.

TABLE 2
Device layer materials and thicknesses

| Layer | Material | Thickness (angstrom) |
|---|---|---|
| Anode | ITO | 1200 |
| HIL | HT-16 | 100 |
| HTL | HT-16 | 400 |
| EBL | EBM | 50 |
| EML | RH-01: red emitter 3% | 400 |
| ETL | Lip:ET-16 35% | 350 |
| EIL | Liq | 10 |
| Cathode | Al | 1000 |

The structure is as follows:

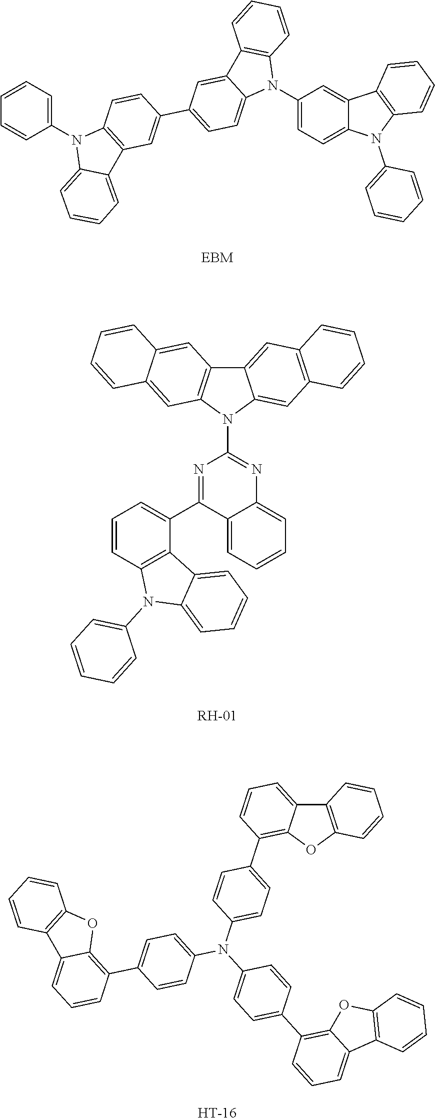

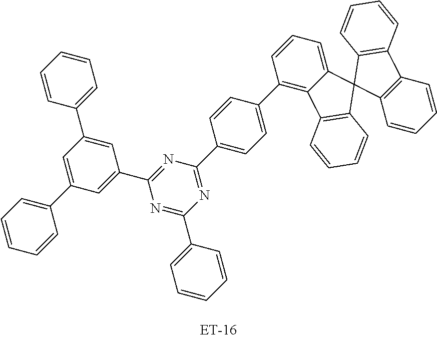 [SMILES: c1ccc(-c2cc(-c3ccccc3)cc(-c3nc(-c4ccccc4)nc(-c4ccc(-c5cccc6c5-c5ccccc5C65c6ccccc6-c6ccccc65)cc4)n3)c2)cc1]

### Device Example 2-12

The preparation method is the same as that of Example 1 above, except that the dopant material I-1 was replaced with I-5, I-65, I-119, I-142, I-169, I-193, I-197, I-213, I-245, I-281, and I-293.

### Device Comparative Example 1-4

The method is the same as the method for preparing the organic electroluminescent device in Example 1 above, except that the compound represented by formula I-1, the dopant material in Example 1, was replaced with compounds having the structures in Comparative Example 1 to Comparative Example 4.

The compounds obtained in Comparative Examples 1˜4 are as follows:

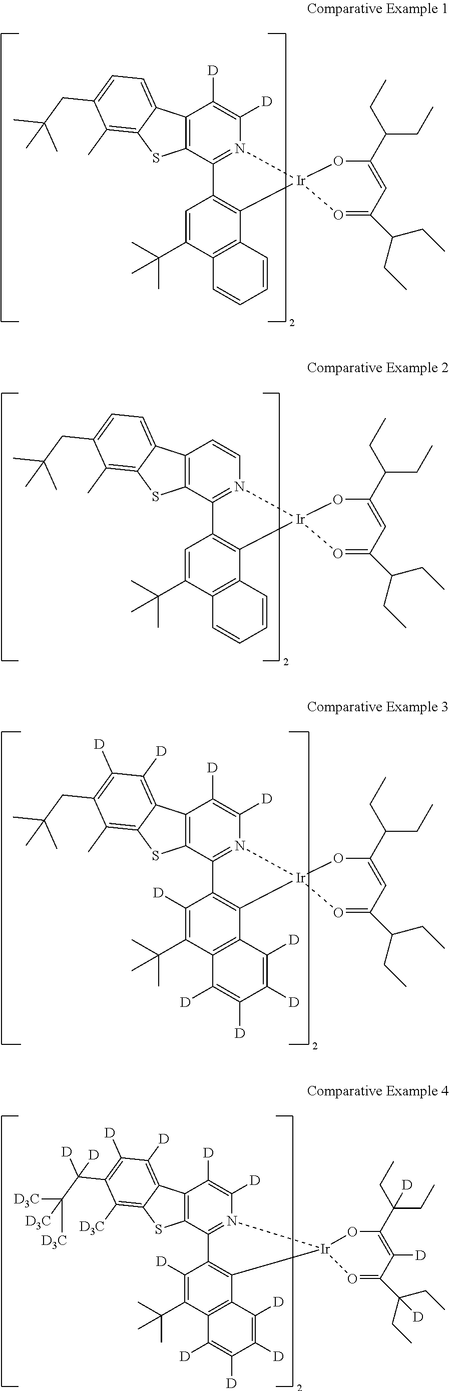

The organic electroluminescent devices obtained from the above device examples and device comparative examples were characterized in terms of driving voltage, luminous efficiency, and lifetime at 6000 (nits) luminance, and the test results are shown in Table 3 below:

TABLE 3

| | Test data for device example and comparative example | | | | |
|---|---|---|---|---|---|
| Test Condition | | | Driving | Luminous | Lifetime |
| Luminance | | | voltage | efficiency | T95 |
| (cd/cm²) | Device example | Compound | (V) | (cd/A) | (h) |
| 6000 | Device | Comparative | 3.92 | 59.9 | 728 |
| | Comparative | Example 1 | | | |
| | Example 1 | | | | |
| 6000 | Device | Comparative | 4.03 | 60.3 | 834 |
| | Comparative | Example 2 | | | |
| | Example 2 | | | | |
| 6000 | Device | Comparative | 3.94 | 59.1 | 986 |
| | Comparative | Example 3 | | | |
| | Example 3 | | | | |
| 6000 | Device | Comparative | 4.15 | 57.8 | 1057 |
| | Comparative | Example 4 | | | |
| | Example 4 | | | | |
| 6000 | Device Example 1 | I-1 | 3.46 | 64.1 | 964 |
| 6000 | Device Example 2 | I-5 | 3.40 | 68.4 | 1047 |
| 6000 | Device Example 3 | I-65 | 3.45 | 63.2 | 935 |
| 6000 | Device Example 4 | I-119 | 3.47 | 64.1 | 977 |
| 6000 | Device Example 5 | I-142 | 3.41 | 66.8 | 1081 |
| 6000 | Device Example 6 | I-169 | 3.47 | 62.9 | 955 |
| 6000 | Device Example 7 | I-193 | 3.45 | 63.2 | 964 |
| 6000 | Device Example 8 | I-197 | 3.43 | 66.4 | 995 |
| 6000 | Device Example 9 | I-213 | 3.46 | 64.0 | 929 |
| 6000 | Device Example 10 | I-245 | 3.39 | 67.3 | 975 |
| 6000 | Device Example 11 | I-281 | 3.45 | 63.5 | 923 |
| 6000 | Device Example 12 | I-293 | 3.41 | 65.7 | 976 |

As can be seen from Table 3, the organic electroluminescent dopant material compound prepared by the present invention is used as an emissive layer applied to a dopant material applied to an organic electroluminescent device. Compared with the organic electroluminescent device prepared by the comparative example, since the specific ligand compound is selected in the present invention, by introducing a deuterium atom group on the thiophene ring, the intermolecular spatial configuration and intermolecular spacing and bond energy are changed, the molecular orientation is set, and the device structure of the present invention is matched. Although the lifetime is not significantly improved compared with that of the comparative example, it can be clearly seen that the OLED device prepared by the present invention has the advantages of high efficiency, low driving voltage and the like.

The above examples only enumerate the effect data of the devices made by a part of the structural formulas, which is a representative sampling test. From the experimental data, the overall data is not much different, and may represent the effect of other structures not enumerated.

It will be apparent to those skilled in the art that many modifications and variations are possible in the present invention without departing from the spirit and scope of the present invention. Thus, it is intended that the present invention covers the modifications and variations of the present invention provided within the scope of the appended claims and their equivalents.

The above description of the disclosed examples enables those skilled in the art to implement or use the present invention. Various modifications to these examples will be apparent to those skilled in the art, and the general principles defined herein may be implemented in other examples without departing from the spirit or scope of the present invention. Therefore, the present invention is not limited to the examples shown herein, but conforms to the widest scope consistent with the principles and novel features disclosed herein.

1. An organic electroluminescent dopant material, comprising a compound M(L_{A})₂(L_{B}), wherein M is a metal; L_{A} and L_{B} are both ligands, and L_{A} and L_{B} are compounds having the following general structural formulas: 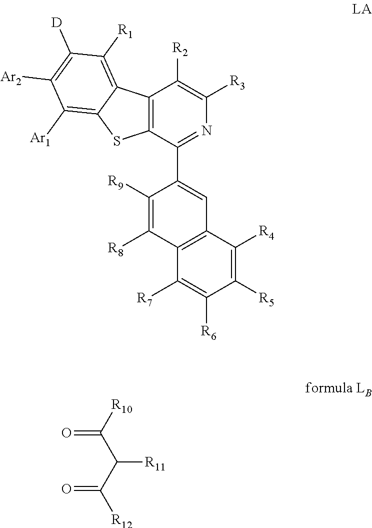
Ar₁ and Ar₂ are independently selected from any one of —F, —CN, —CH₃, —CD₃, —CT₃, —CF₃, —CH₂F, —CHF₂, —Ge(Me)₃, —Si(Me)₃, substituted or unsubstituted C₂-C₆ alkyl, substituted or unsubstituted C₃-C₂₀ cycloalkyl, substituted or unsubstituted C₆-C₁₀ aryl, and substituted or unsubstituted 4- to 8-membered aromatic heterocyclyl;
R₁, R₂, R₃, R₄, R₅, R₆, R₇, R₈, and R₉ are independently selected from any one of —H, —F, —CN, —CH₃, —CD₃, —CT₃, —CF₃, —CH₂F, —CHF₂, —Ge(Me)₃, —Si(Me)₃, substituted or unsubstituted C₂-C₆ alkyl, substituted or unsubstituted C₃-C₂₀ cycloalkyl, substituted or unsubstituted C₆-C₁₀ aryl, and substituted or unsubstituted 4- to 8-membered aromatic heterocyclyl;
R₁₀, R₁₁, and R₁₂ are independently selected from any one of —H, -D, -T, —F, —CN, —CH₃, —CD₃, —CT₃, —CF₃, —CH₂F, —CHF₂, —Ge(Me)₃, —Si(Me)₃, substituted or unsubstituted C₂-C₆ alkyl, substituted or unsubstituted C₃-C₂₀ cycloalkyl, substituted or unsubstituted C₆-C₁₀ aryl, and substituted or unsubstituted 4- to 8-membered aromatic heterocyclyl;
the “substitution” means being capable of being substituted with —H, -D, -T, —F, —CN, —CH₃, —CD₃, —CT₃, —CF₃, —CH₂F, —CHF₂, —Ge(Me)₃, —Si(Me)₃, ethyl, n-propyl, isopropyl, n-butyl, isobutyl, tert-butyl, cyclopropyl, cyclobutyl, cyclopentyl, cyclohexyl, thiocyclopentane, phenyl, biphenyl, terphenyl, naphthyl, fluorenyl, phenanthryl, anthracyl, indenyl, triphenylenyl, fluoranthenyl, furyl, thienyl, imidazolyl, pyrazolyl, thiazolyl, pyridinyl, pyrazinyl, pyrimidinyl, benzofuryl, benzothienyl, isobenzofuryl, dibenzofuryl, dibenzothienyl, benzimidazolyl, benzothiazolyl, benzisothiazolyl, benzothiadiazolyl, quinolyl, isoquinolyl, quinazolinyl, quinoxalinyl, and carbazolyl groups.

2. The organic electroluminescent dopant material according to claim 1, wherein M is metal Ir.

3. The organic electroluminescent dopant material according to claim 1, wherein Ar₁ and Ar₂ are independently selected from any one of —F, —CN, —CF₃, —CH₂F, —CHF₂, methyl, ethyl, n-propyl, isopropyl, n-butyl, isobutyl, tert-butyl, cyclopropyl, cyclobutyl, cyclopentyl, cyclohexyl, terphenyl, fluorenyl, phenanthryl, triphenylenyl, furyl, benzofuryl, benzothienyl, dibenzofuryl, dibenzothienyl, and the following substituents: 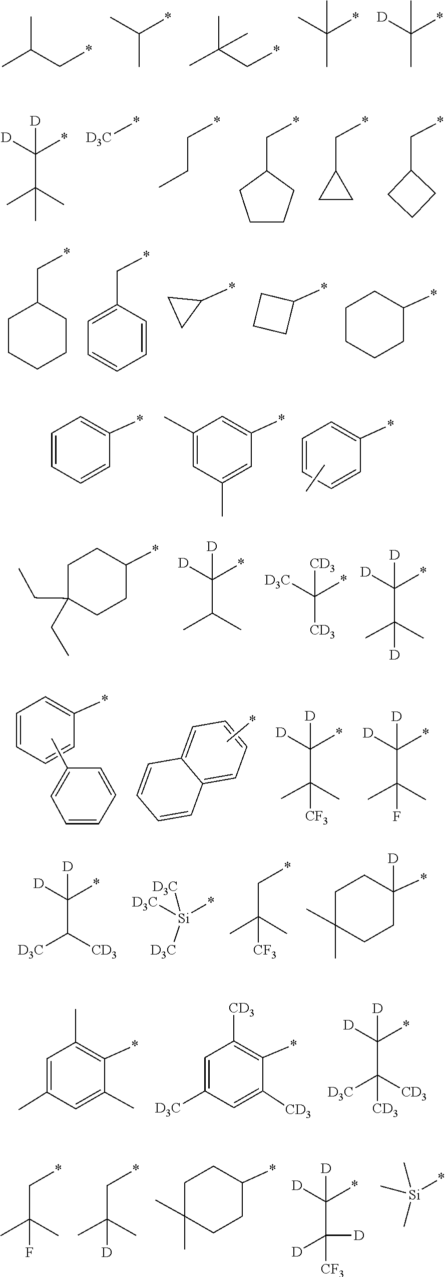
wherein * represents a connection position.

4. The organic electroluminescent dopant material according to claim 1, wherein R₁-R₉ are independently selected from one or more of the following groups: —H, —F, —CN, —CH₃, —CD₃, —CT₃, —CF₃, —CH₂F, —CHF₂, —Ge(Me)₃, —Si(Me)₃, ethyl, n-propyl, isopropyl, n-butyl, isobutyl, tert-butyl, cyclopropyl, cyclobutyl, cyclopentyl, cyclohexyl, thiocyclopentane, phenyl, biphenyl, terphenyl, naphthyl, fluorenyl, phenanthryl, anthracyl, indenyl, triphenylenyl, fluoranthenyl, furyl, thienyl, imidazolyl, pyrazolyl, thiazolyl, pyridinyl, pyrazinyl, pyrimidinyl, benzofuryl, benzothienyl, isobenzofuryl, dibenzofuryl, dibenzothienyl, benzimidazolyl, benzothiazolyl, benzisothiazolyl, benzothiadiazolyl, quinolyl, isoquinolyl, quinazolinyl, quinoxalinyl, and carbazolyl.

5. The organic electroluminescent dopant material according to claim 1, wherein R₁₀, R₁₁, and R₁₂ are independently selected from —H, -D, -T, —F, —CN, —CH₃, —CD₃, —CT₃, —CF₃, —CH₂F, —CHF₂, —Ge(Me)₃, —Si(Me)₃, methyl, ethyl, n-propyl, isopropyl, n-butyl, isobutyl, tert-butyl, cyclopropyl, cyclobutyl, cyclopentyl, cyclohexyl, tetrahydrofuran, pyrrolidine, thiocyclopentane, tetrahydropyran, phenyl, biphenyl, terphenyl, naphthyl, fluorenyl, phenanthryl, anthracyl, indenyl, triphenylenyl, pyrenyl, tetracenyl, perylenyl, chrysenyl, fused tetraphenyl, fluoranthenyl, furyl, thienyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridinyl, pyrazinyl, pyrimidinyl, pyridazinyl, benzofuryl, benzothienyl, isobenzofuryl, dibenzofuryl, dibenzothienyl, benzimidazolyl, benzothiazolyl, benzoisothiazolyl, benzisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenanthridinyl, and benzodioxolyl.

6. The organic electroluminescent dopant material according to claim 1,
wherein the organic electroluminescent dopant material is selected from any one of the following structures:

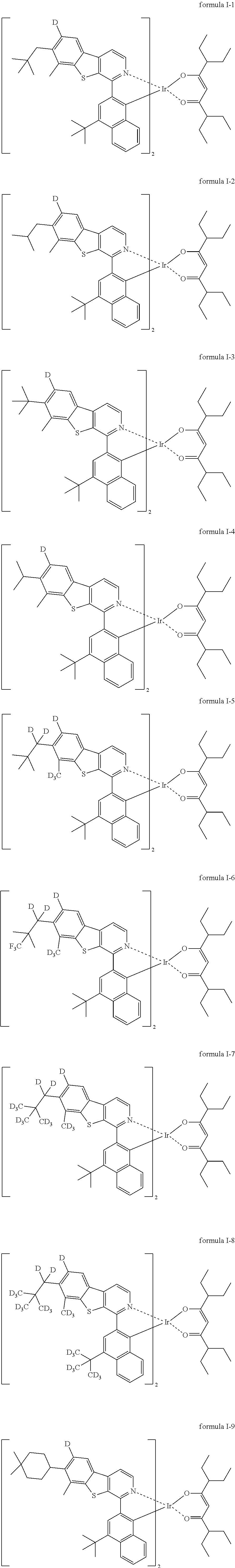

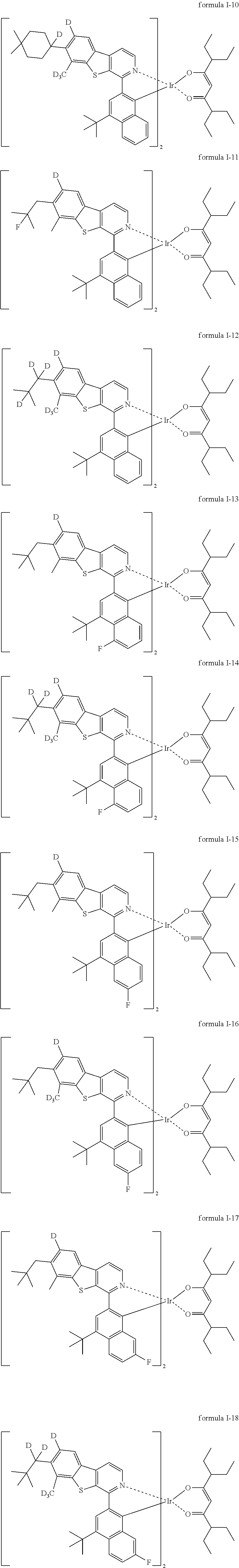

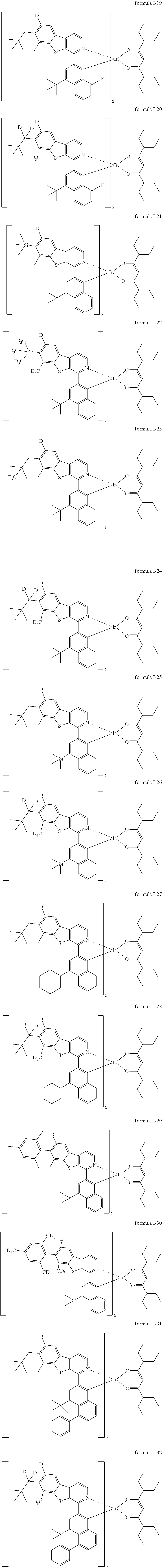

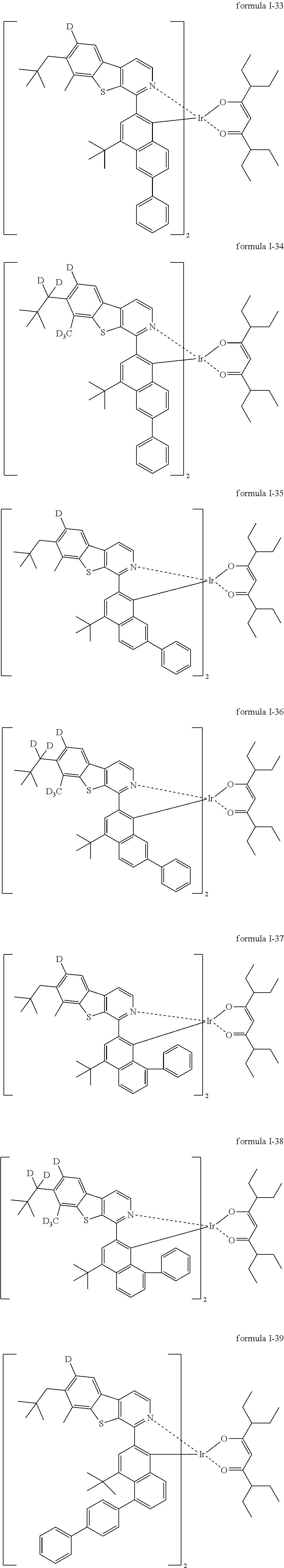

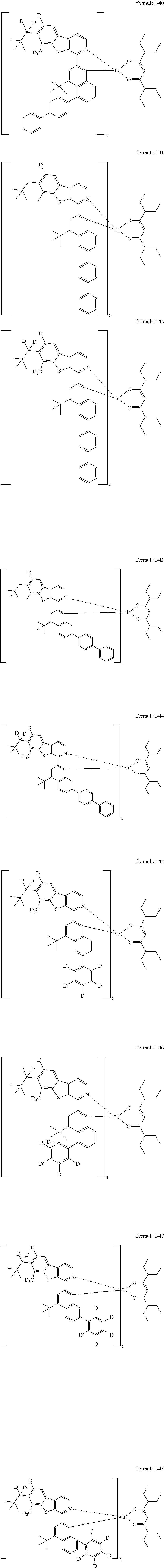

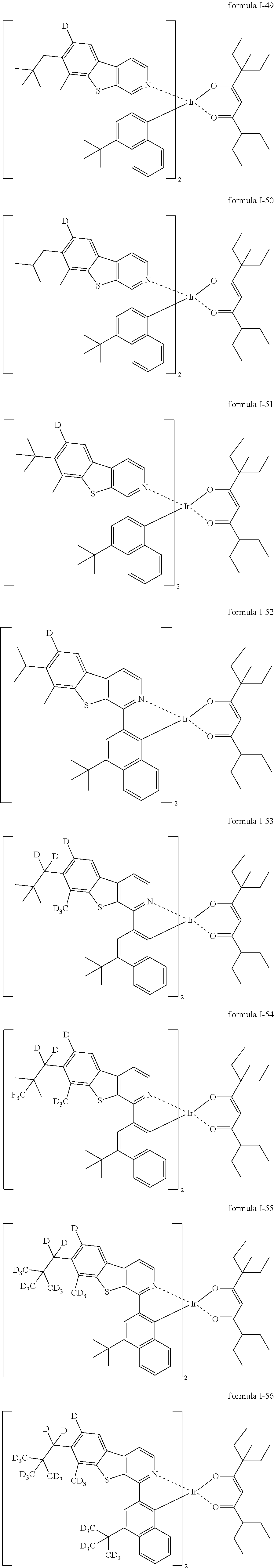

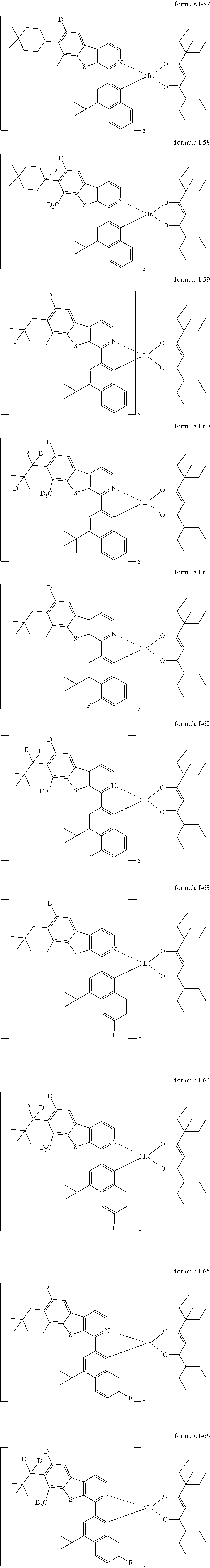

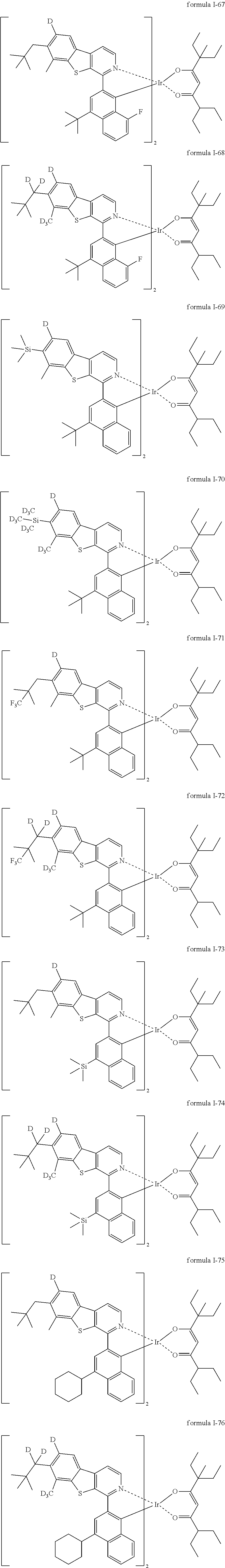

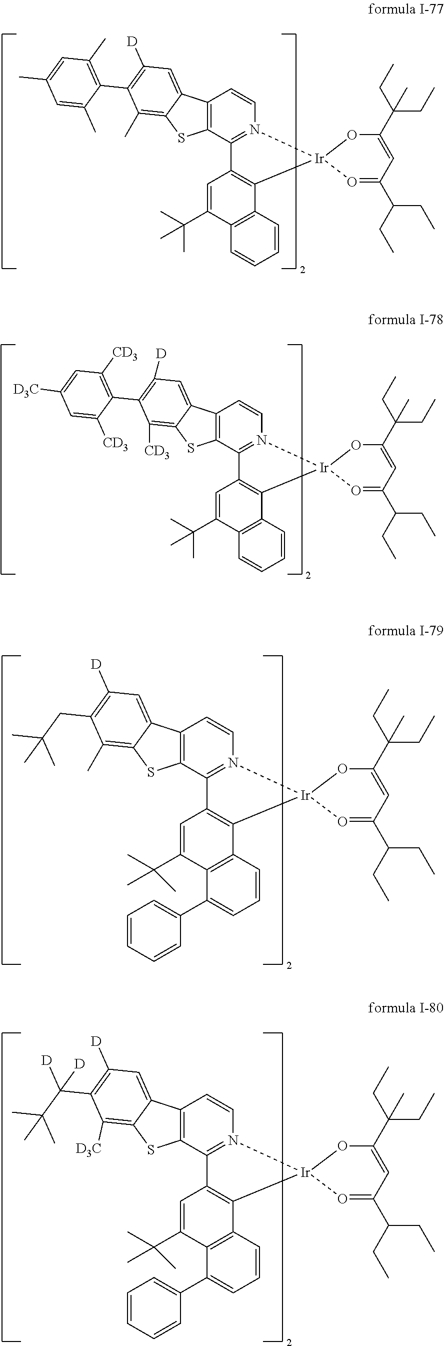

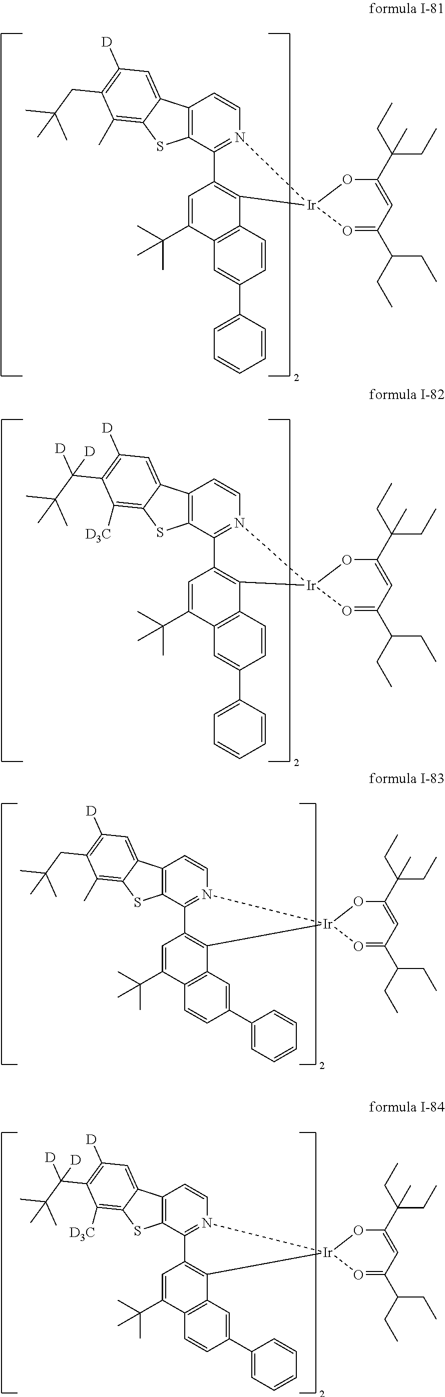

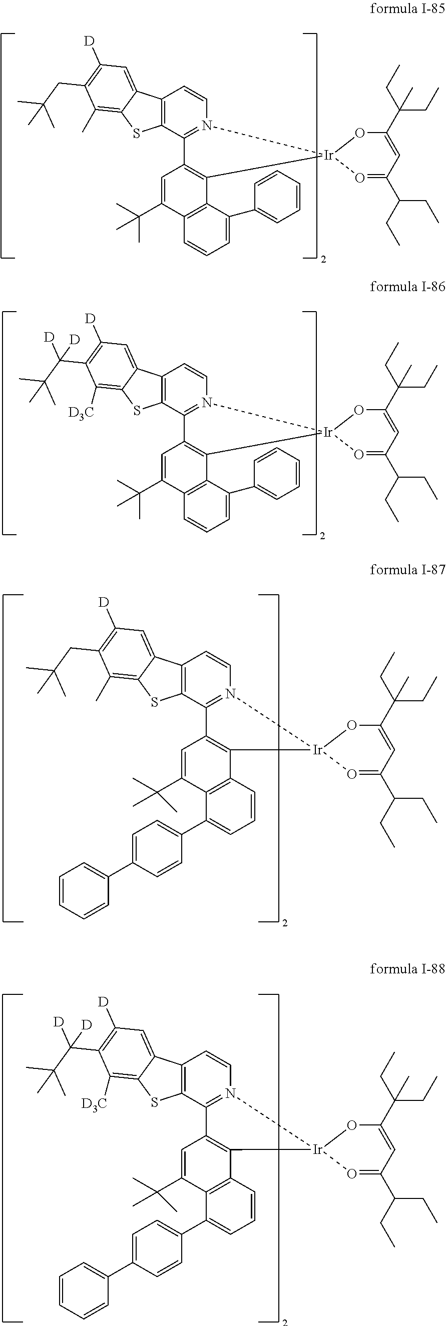

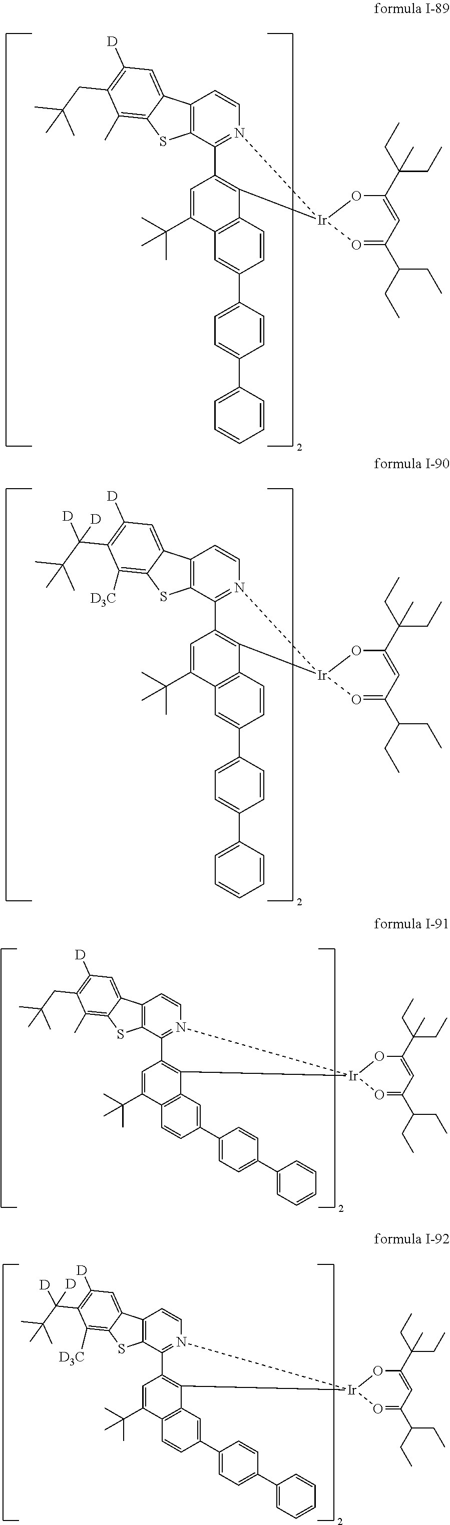

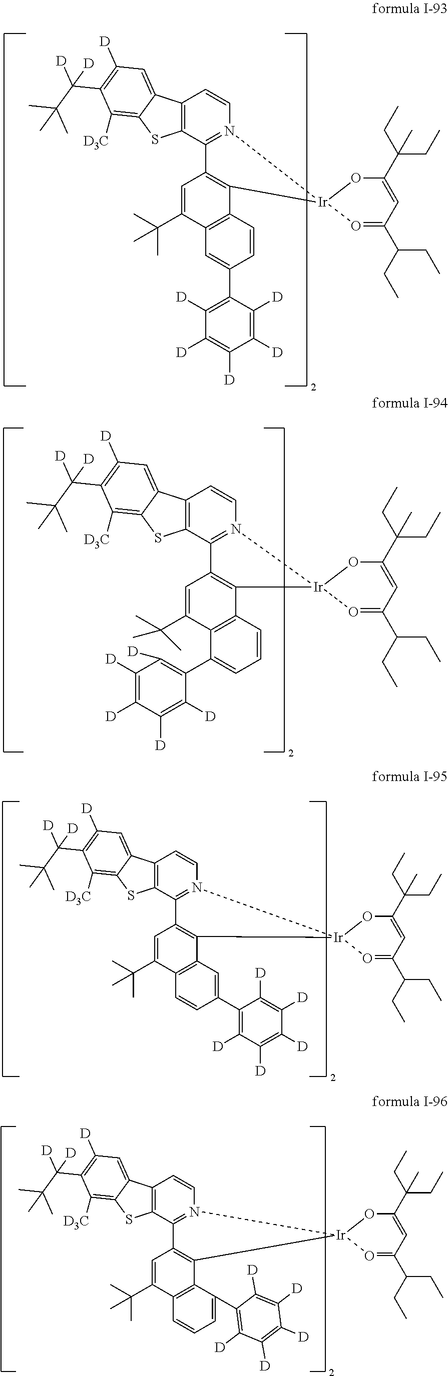

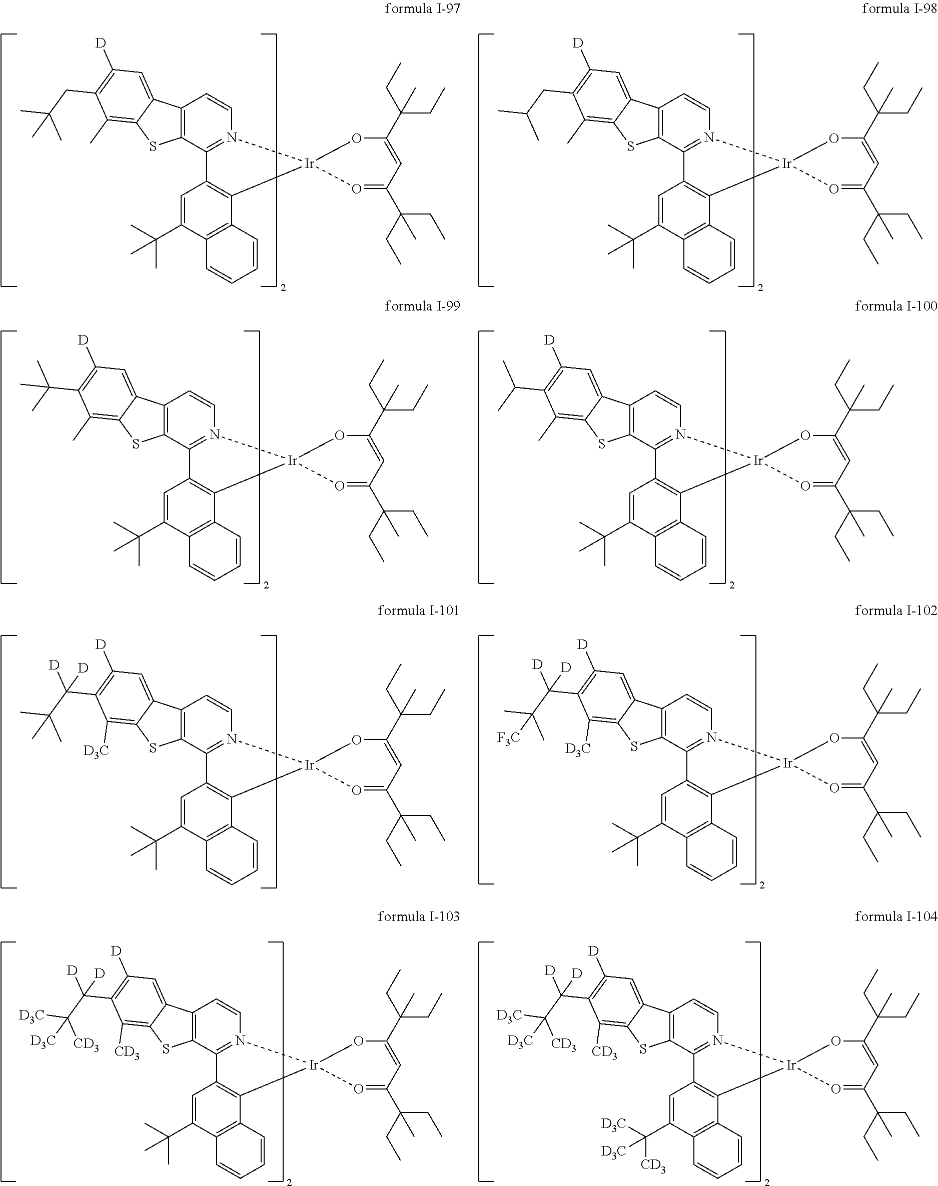

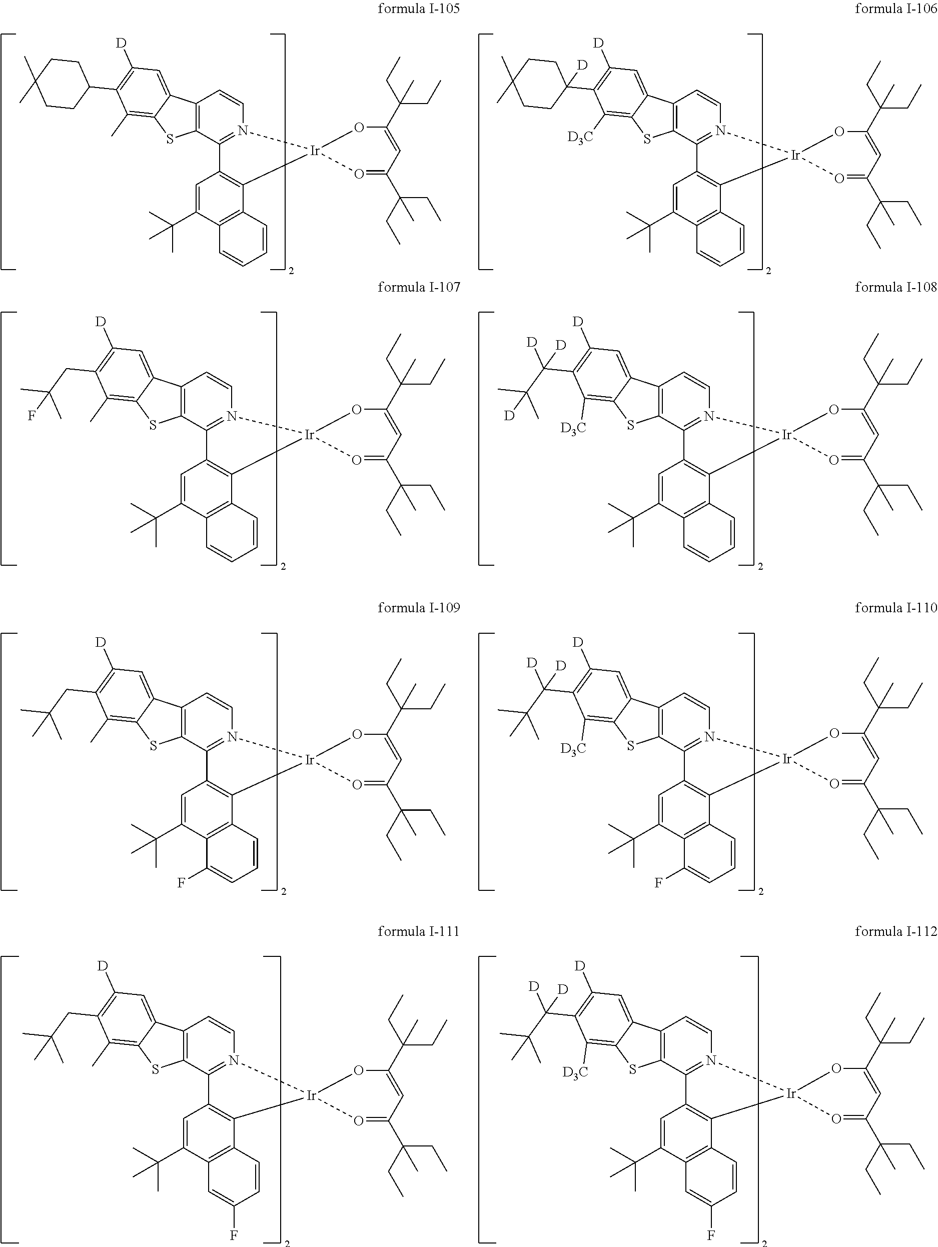

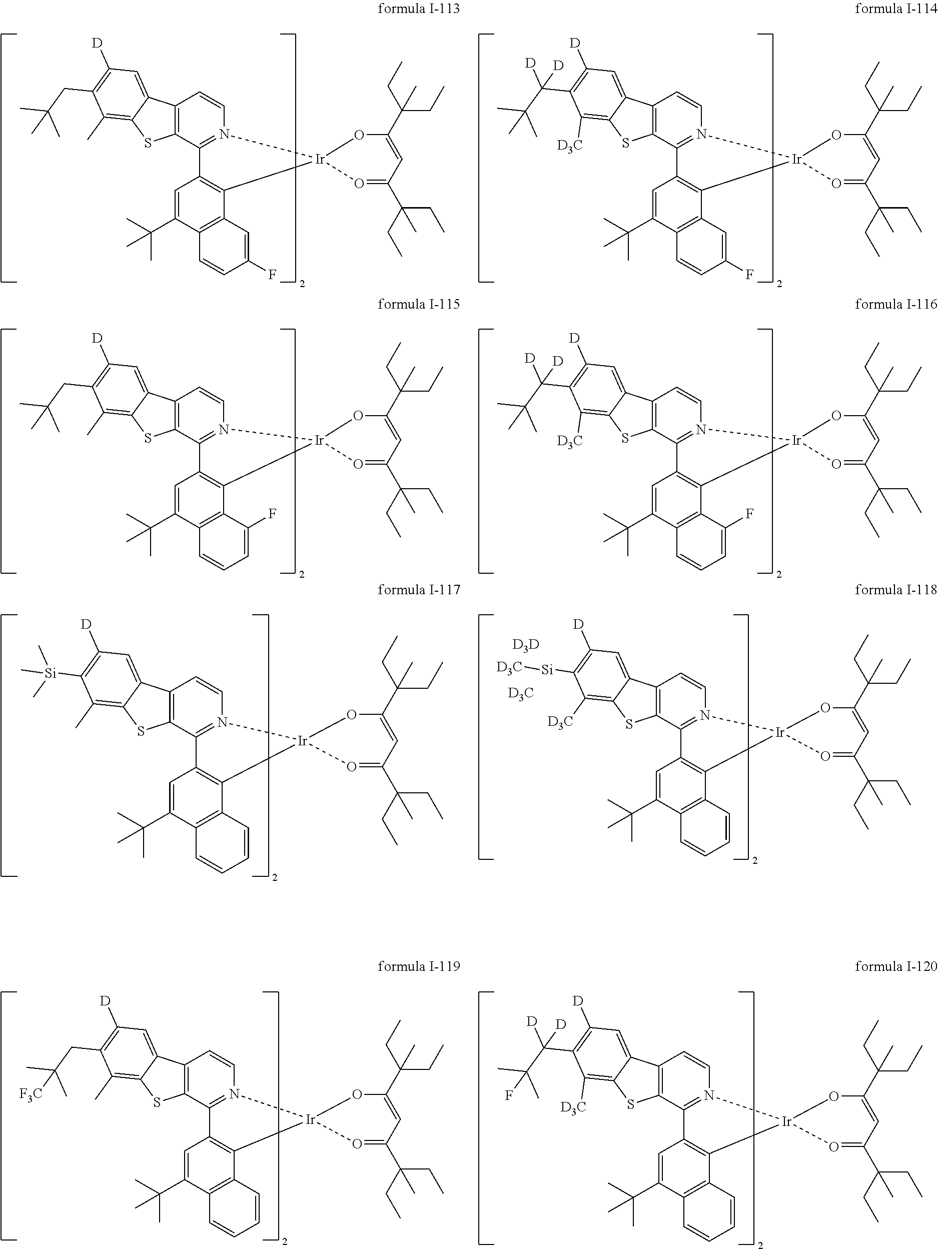

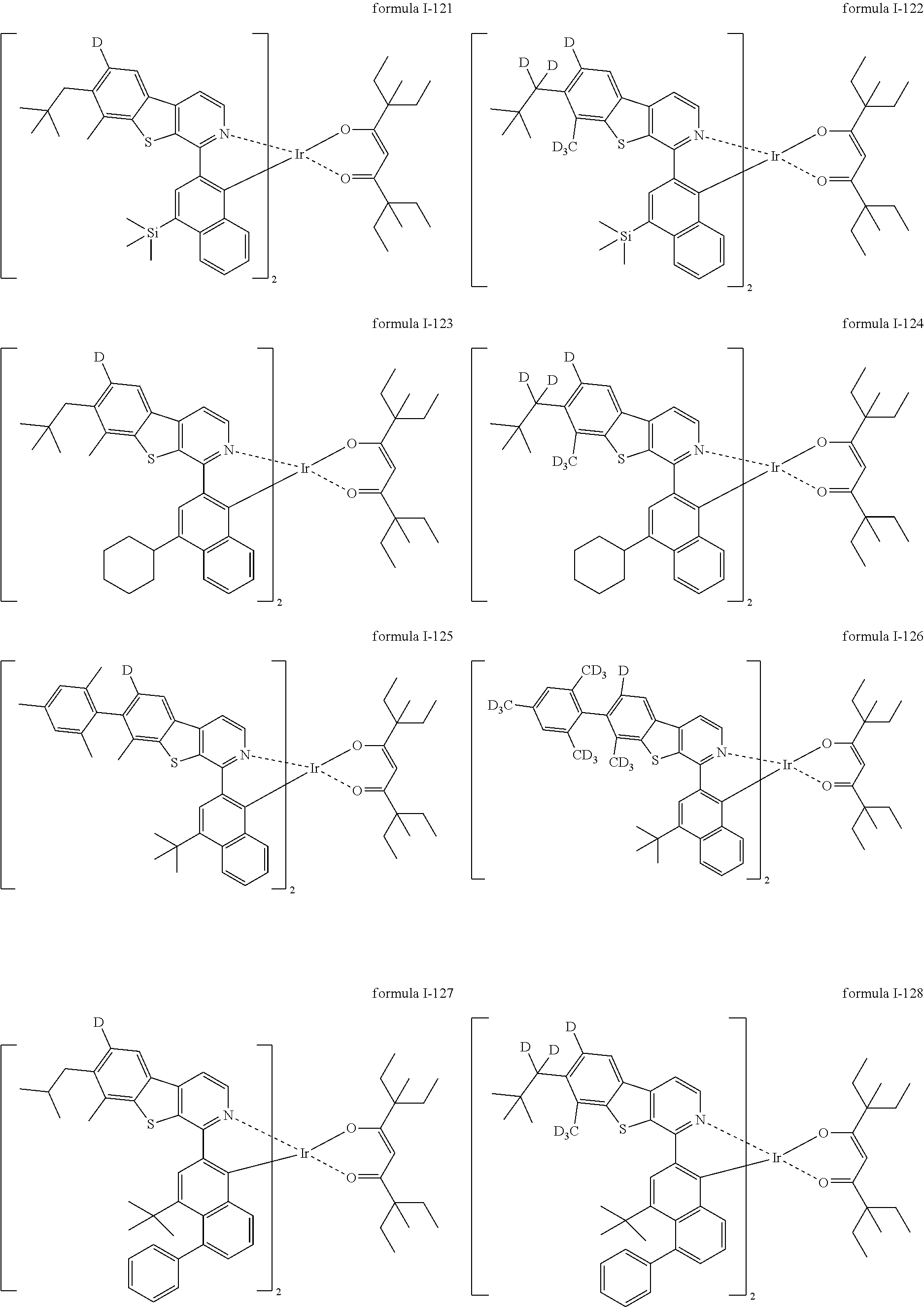

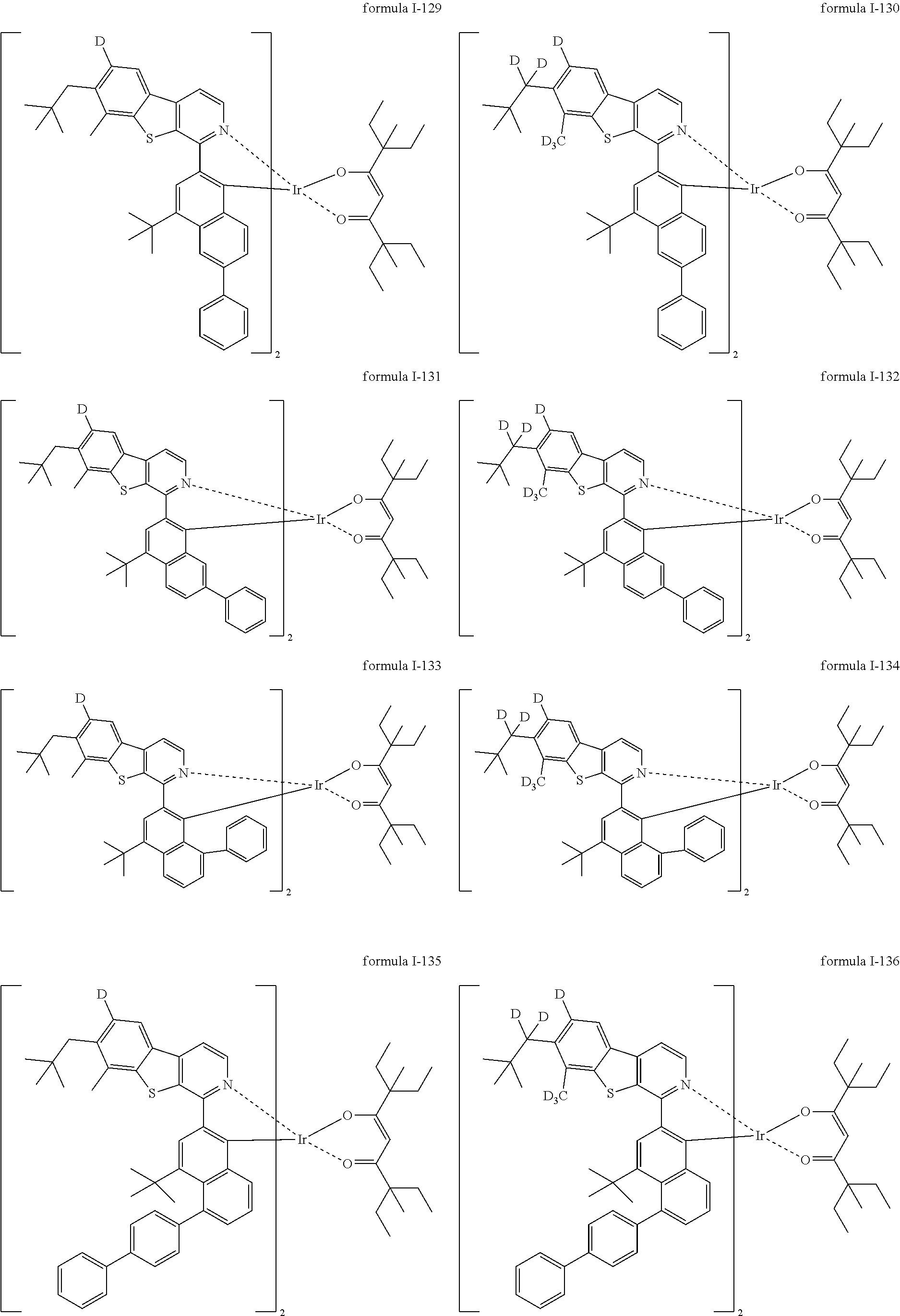

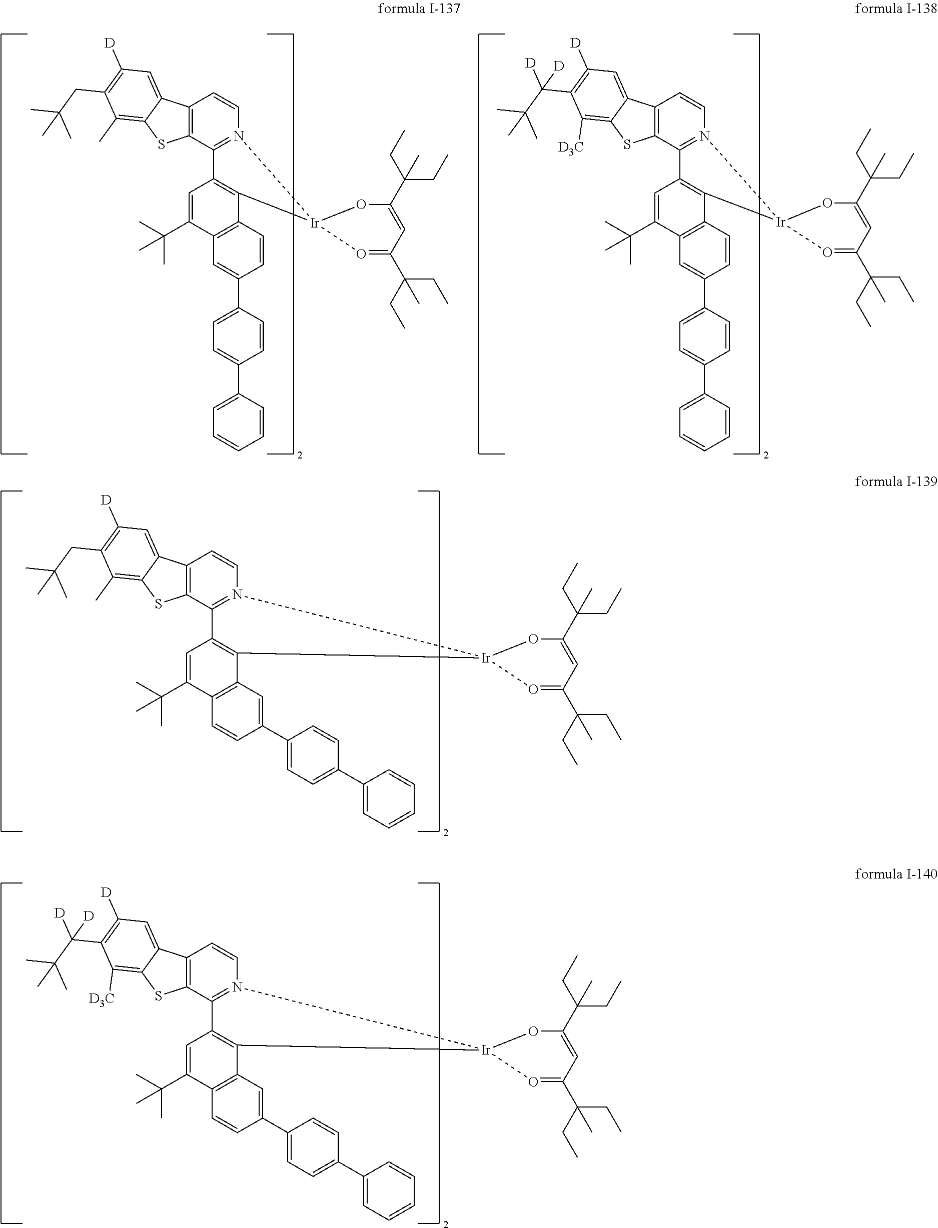

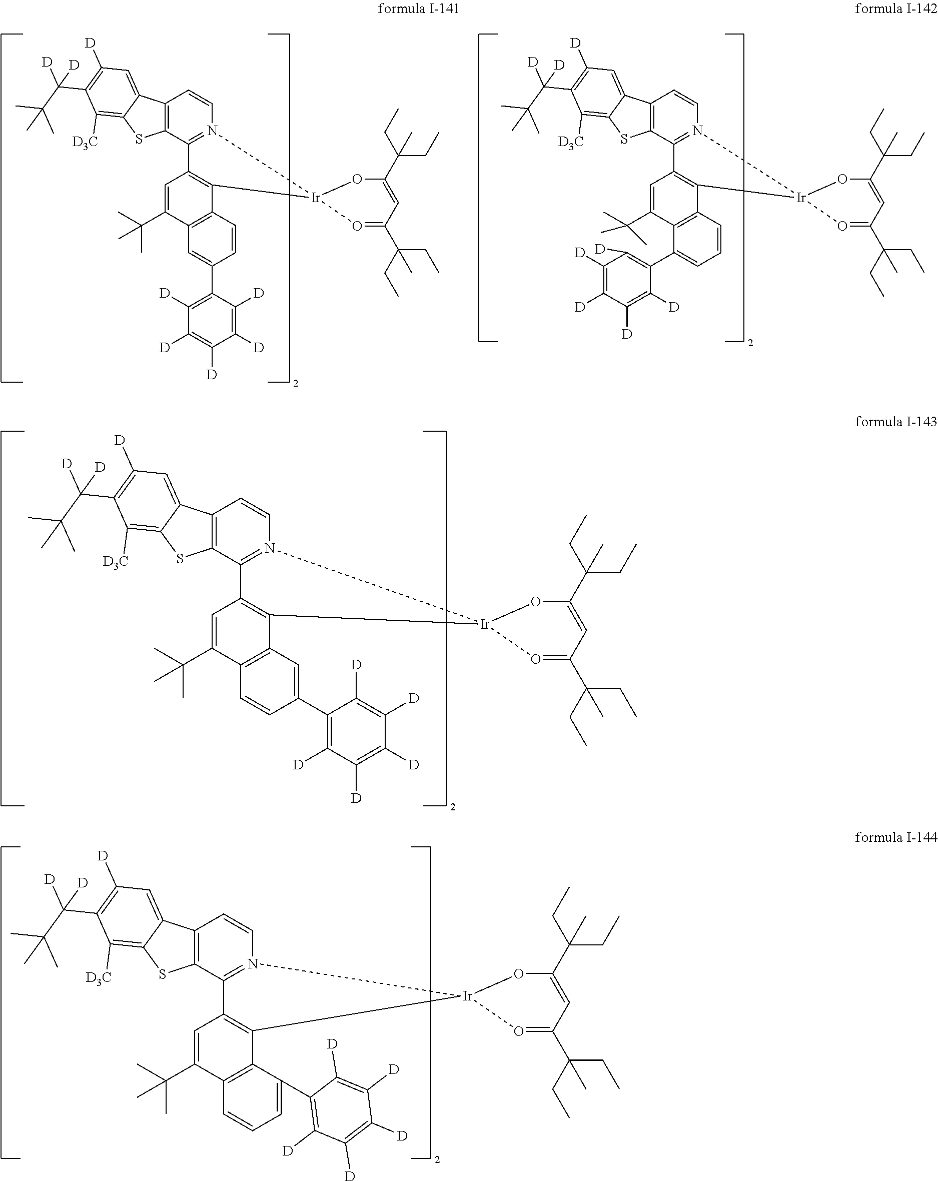

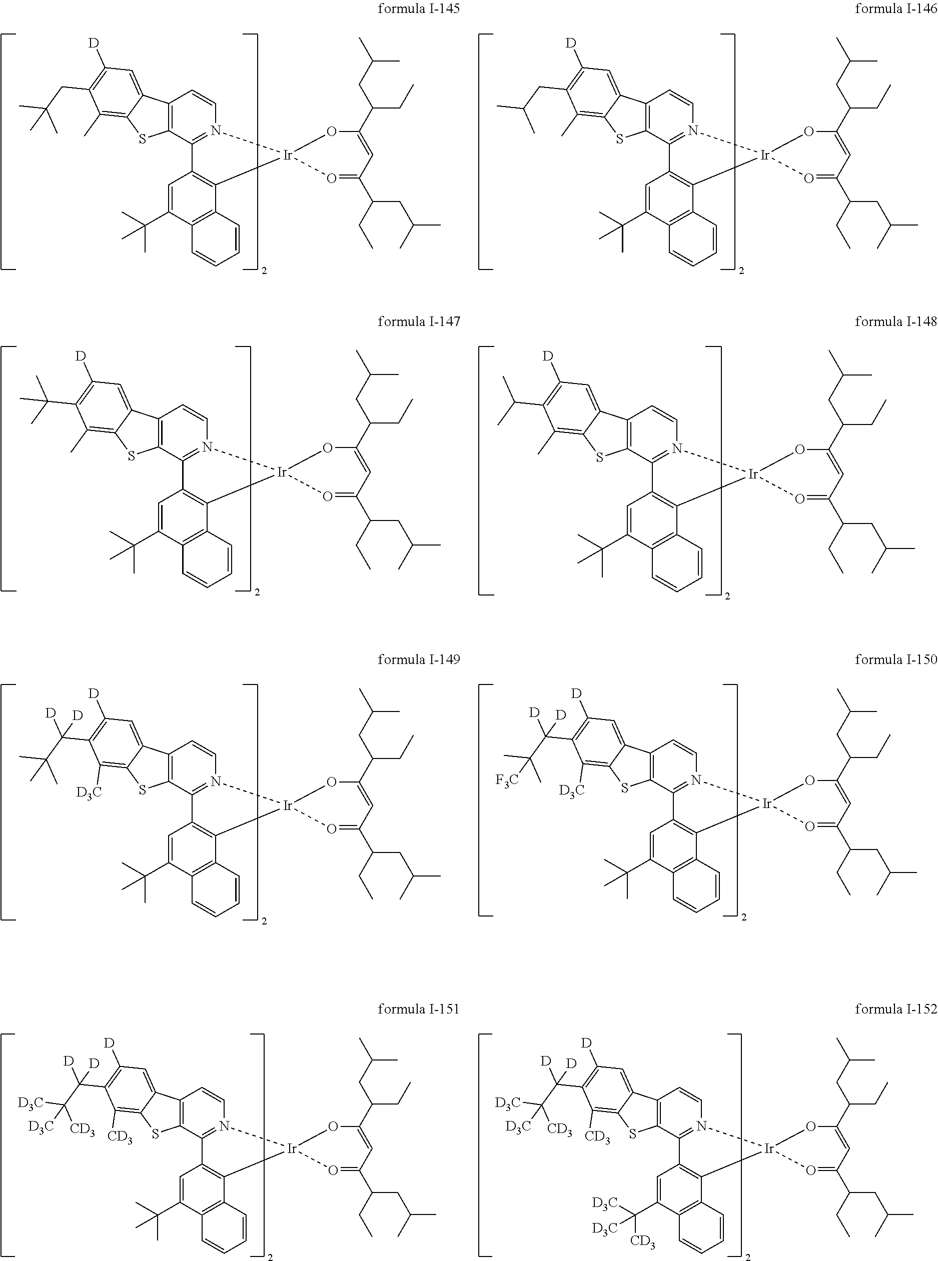

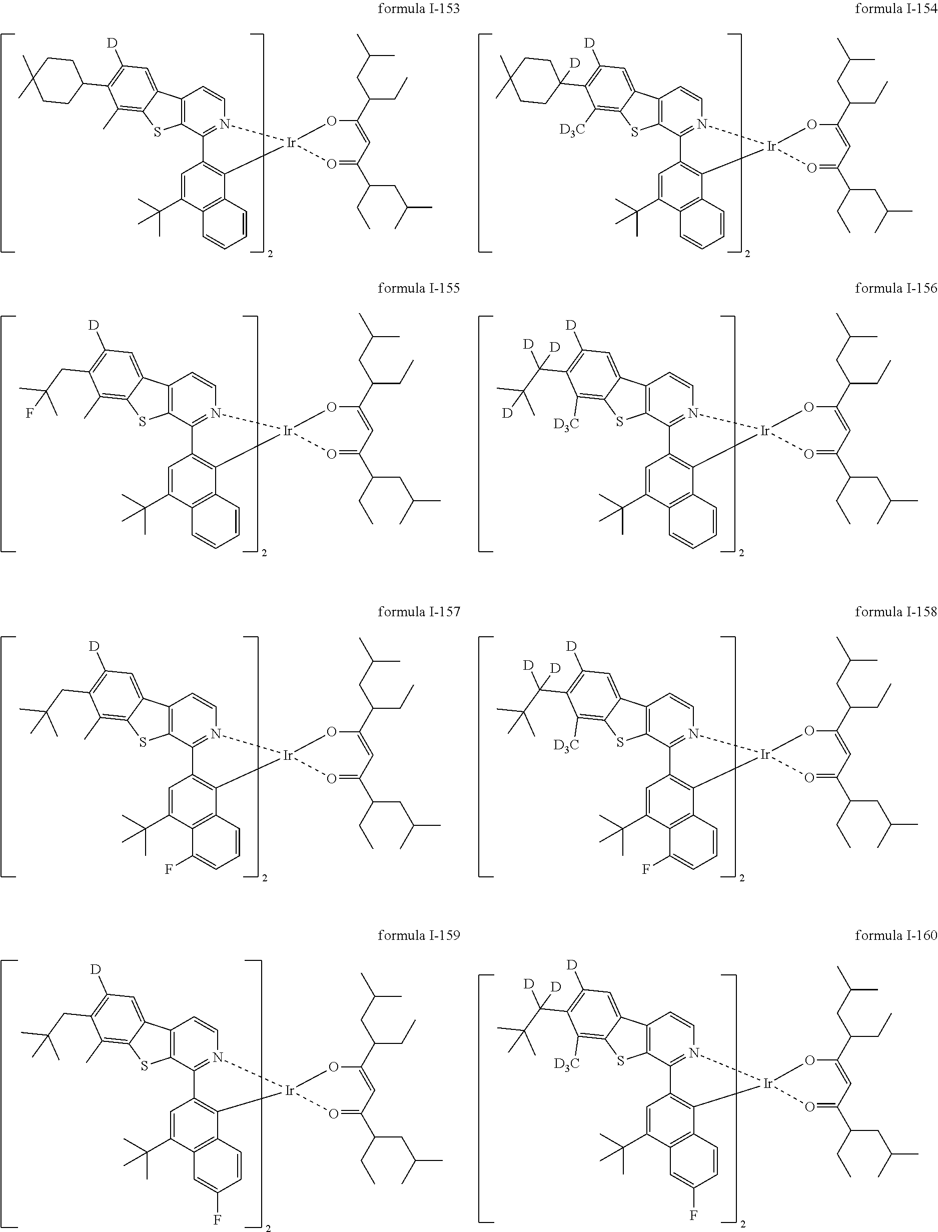

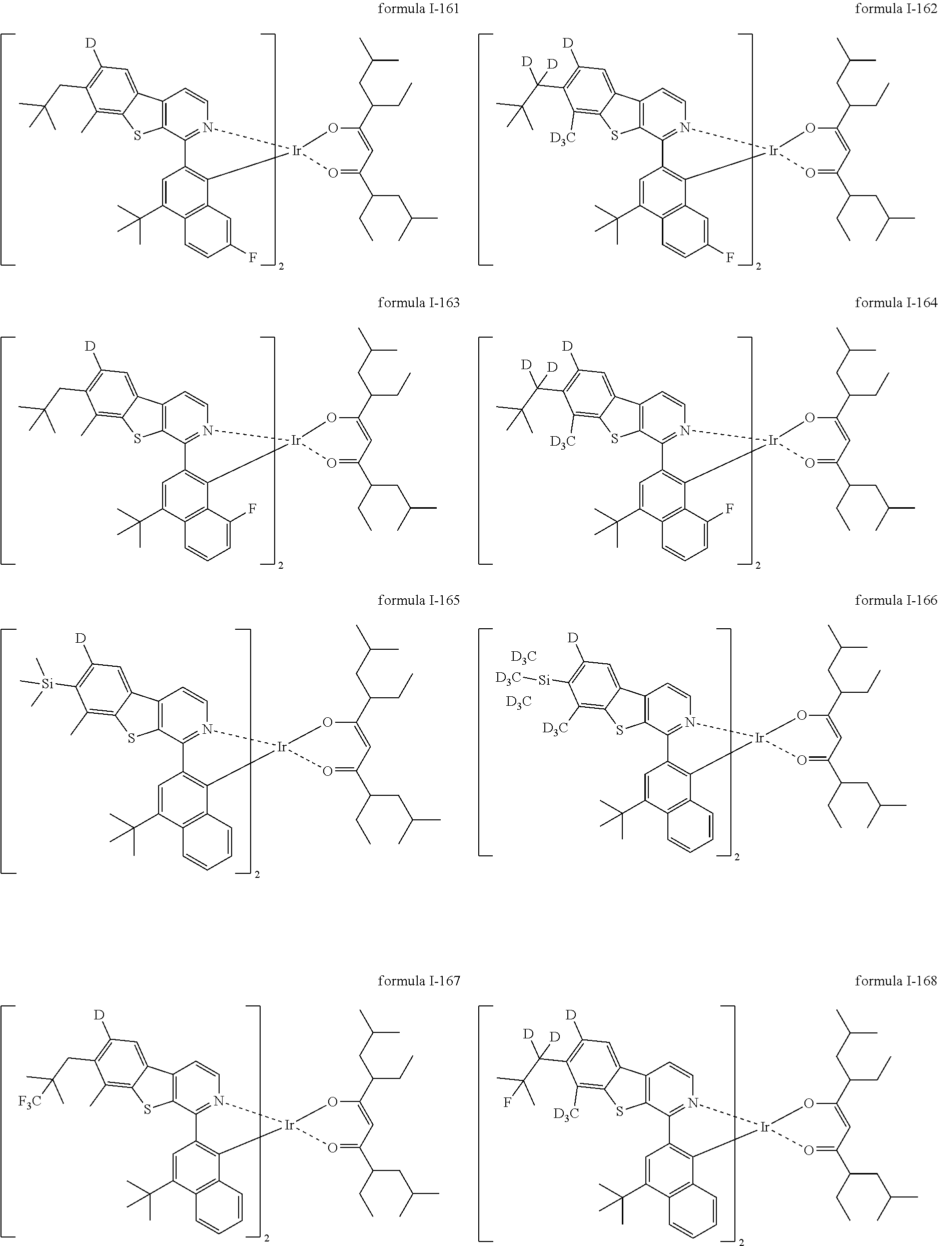

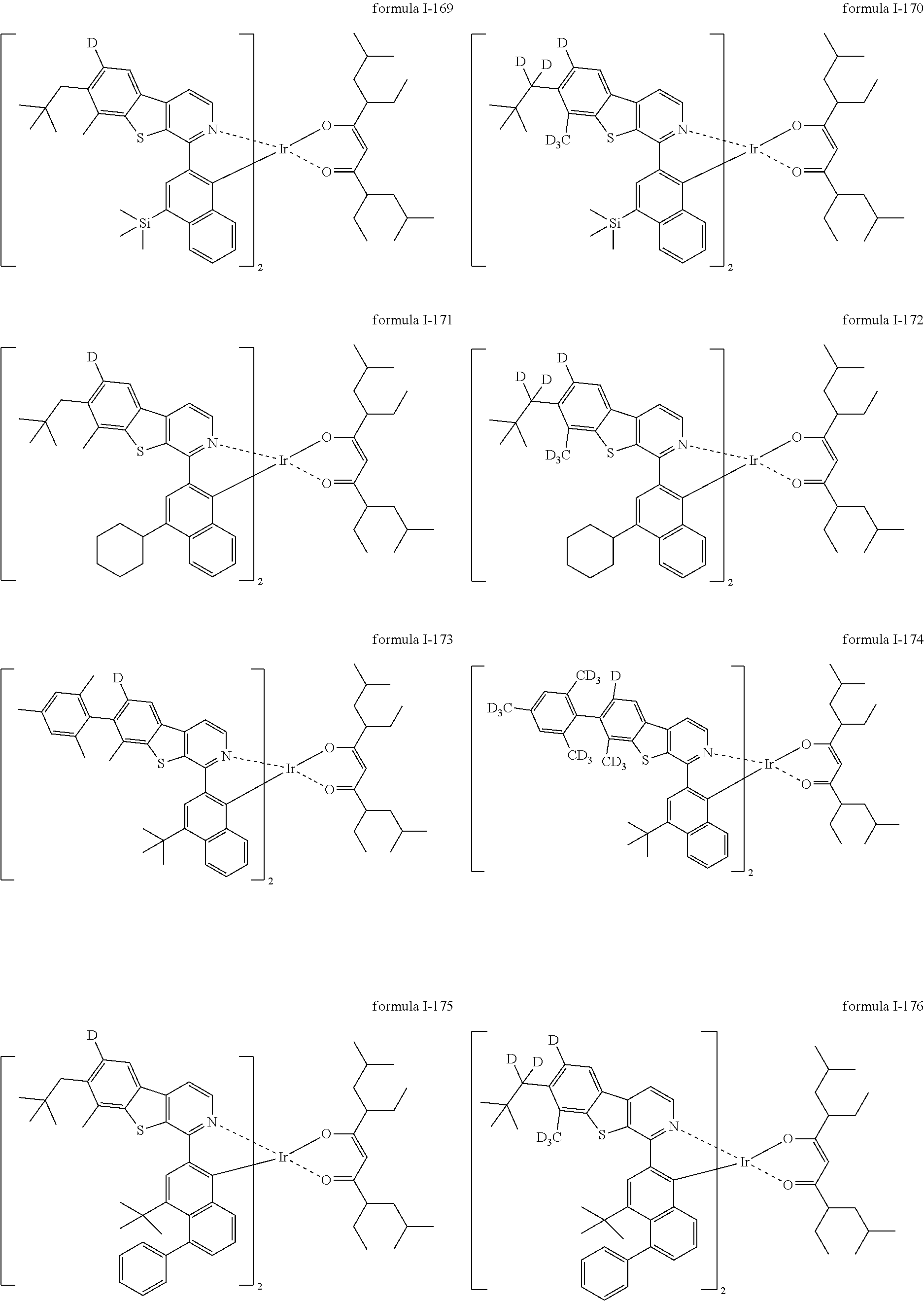

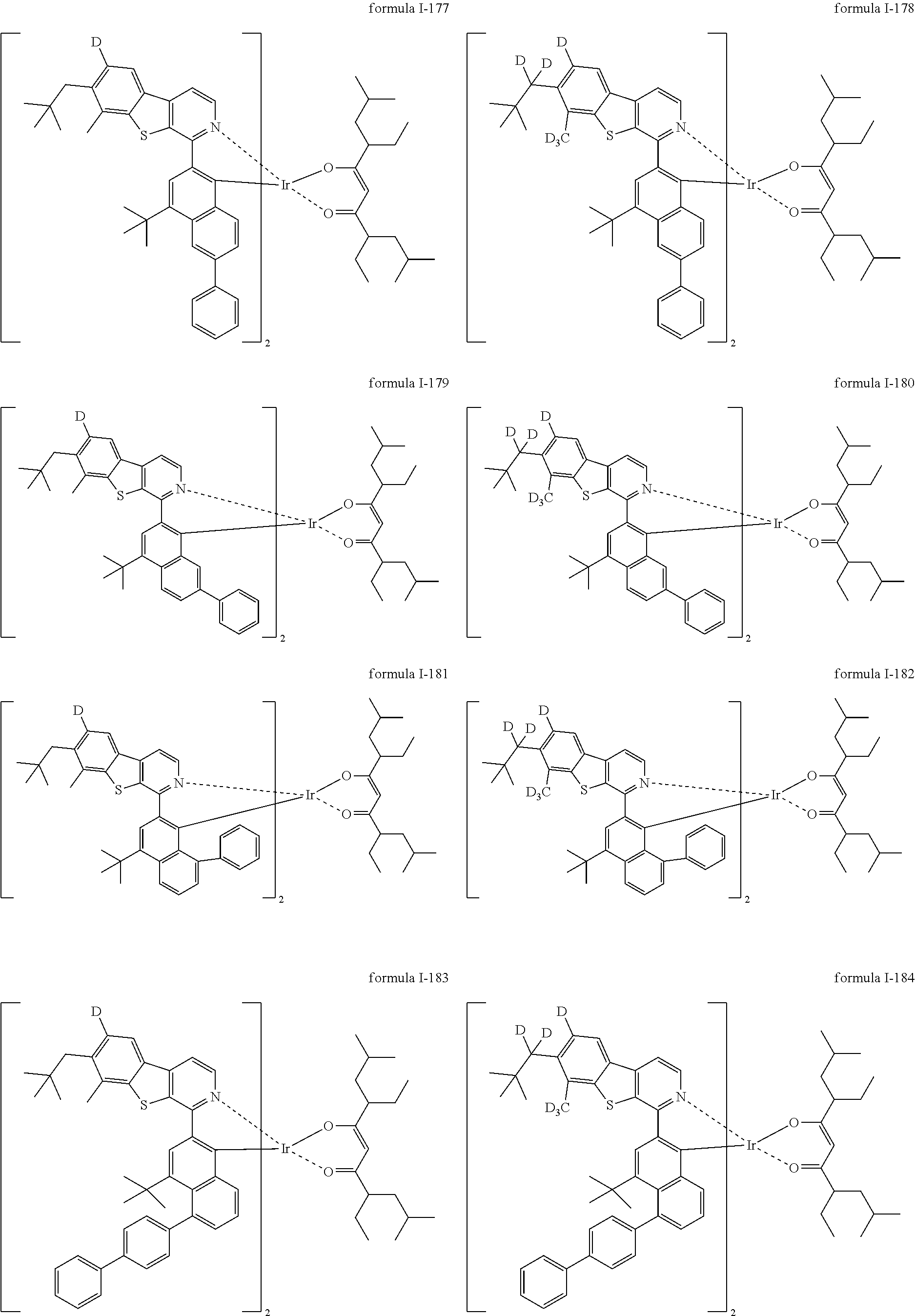

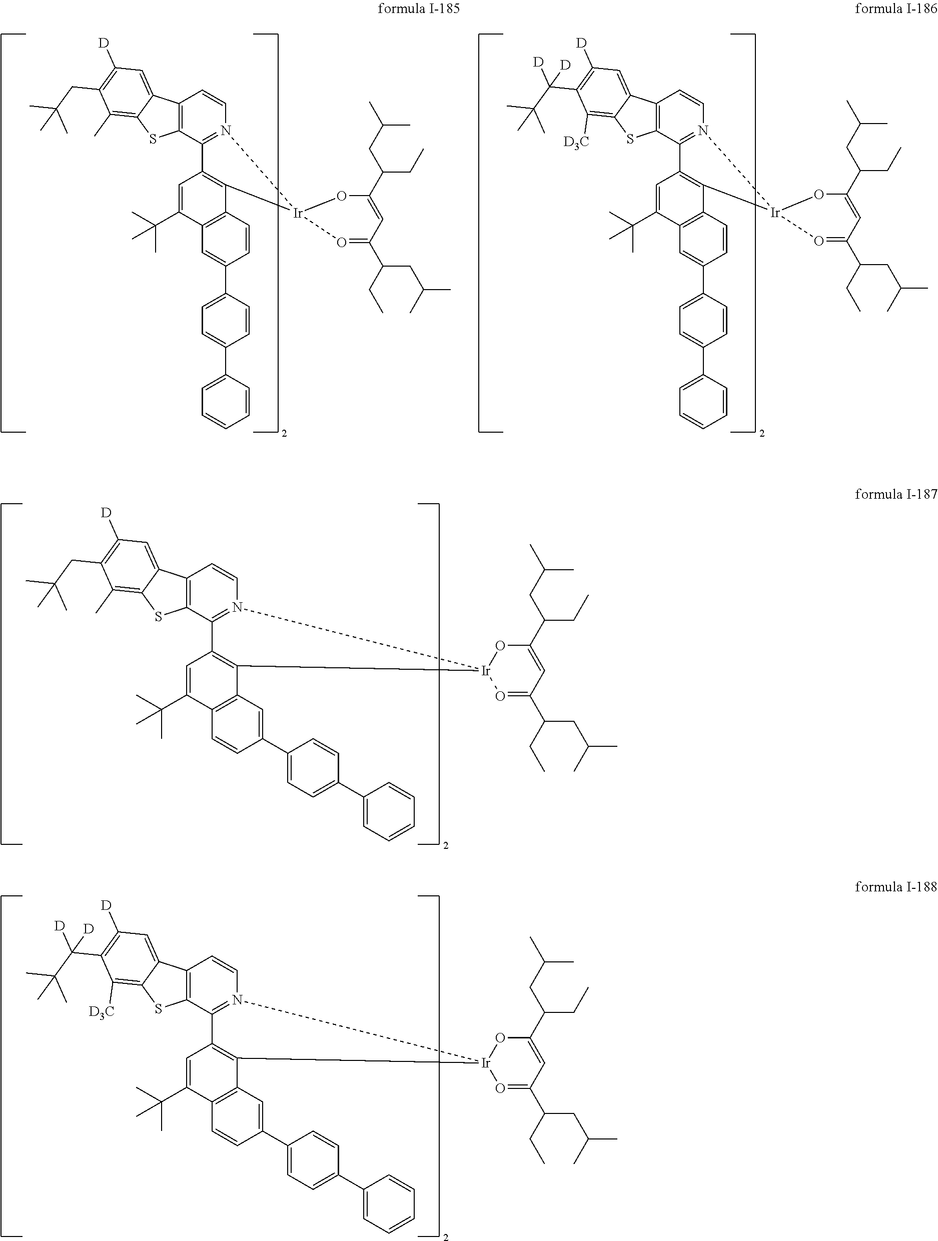

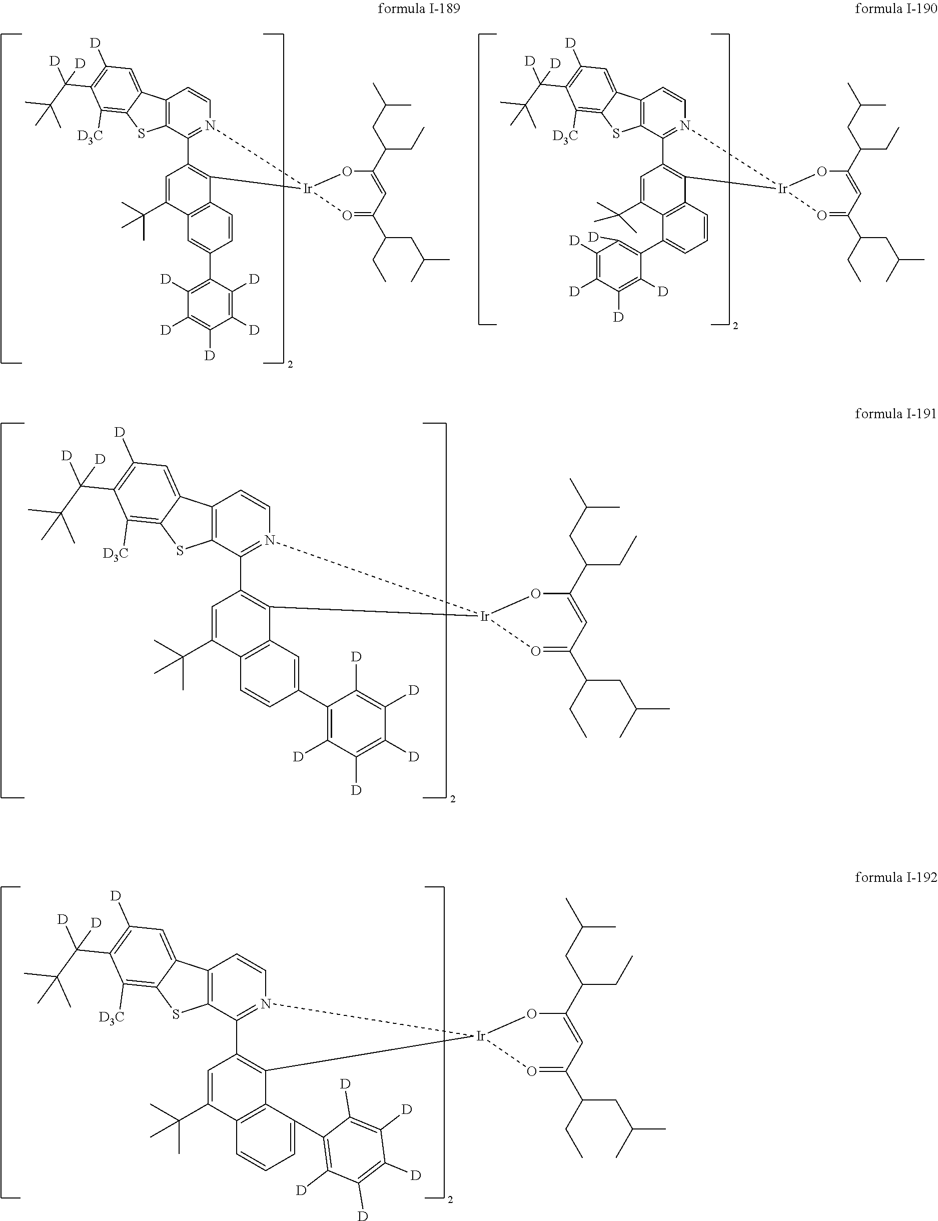

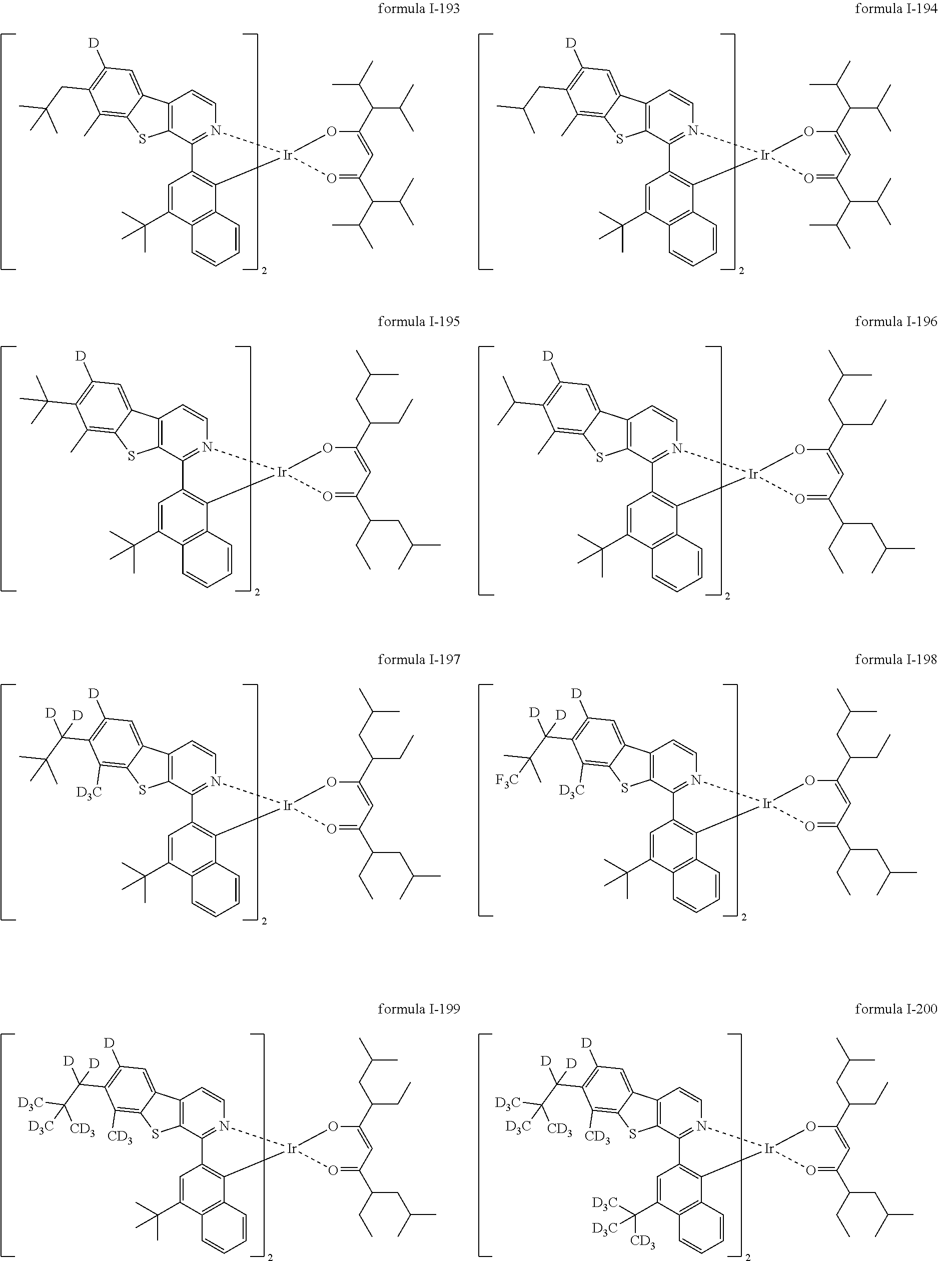

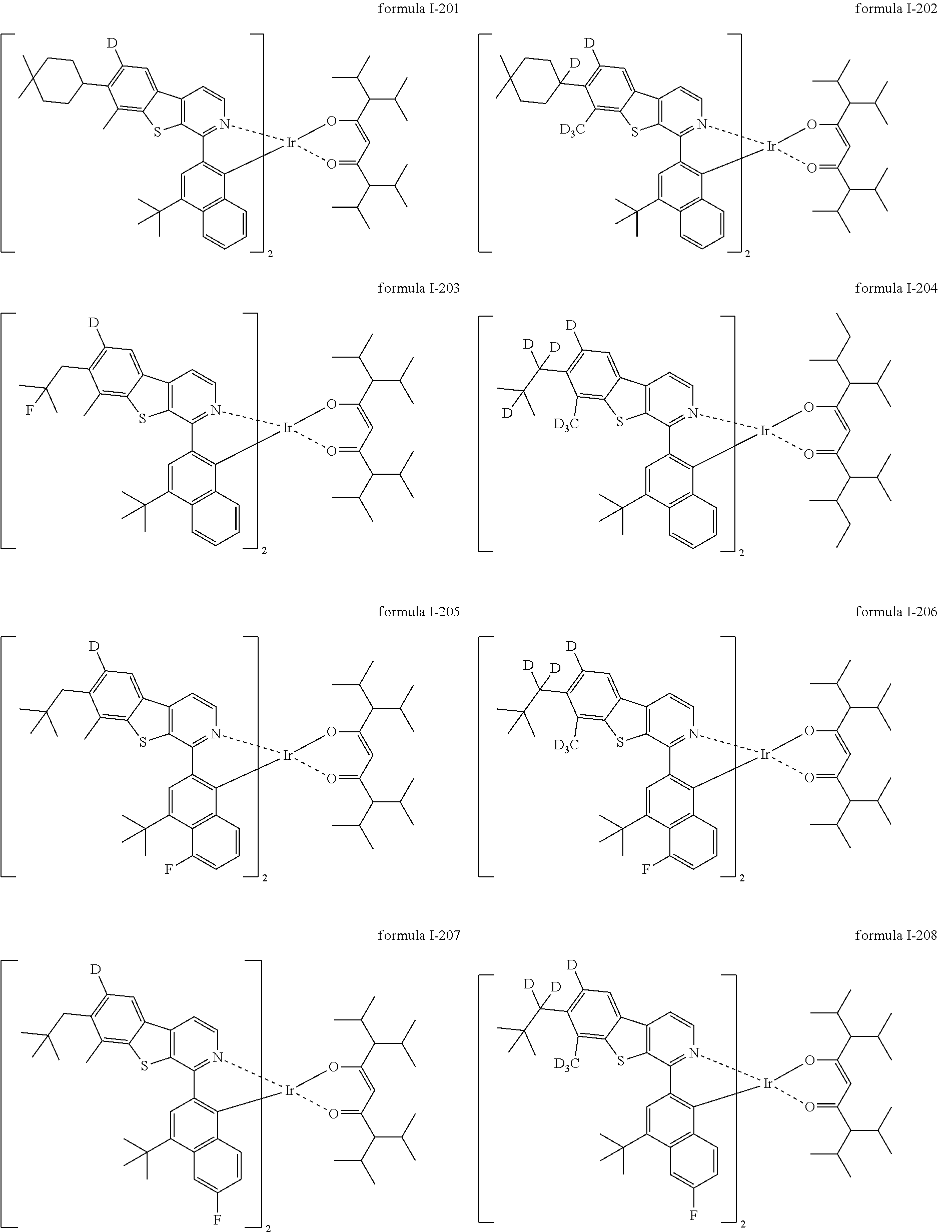

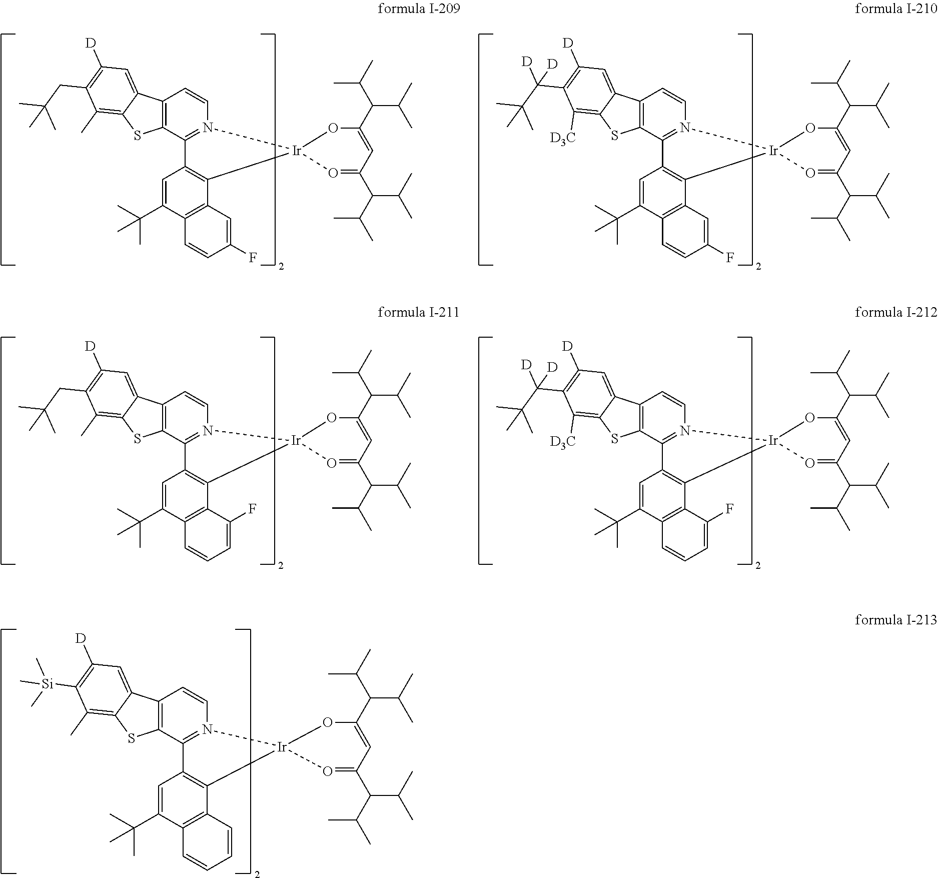

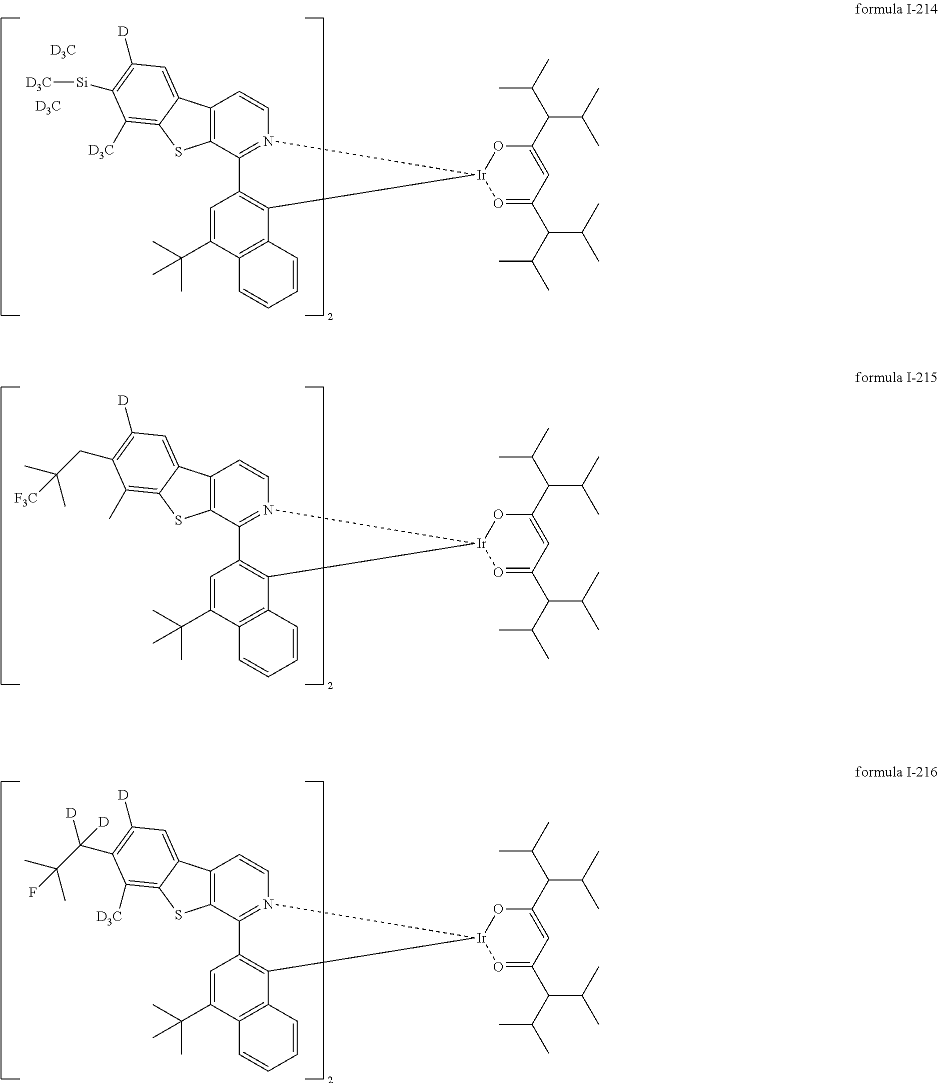

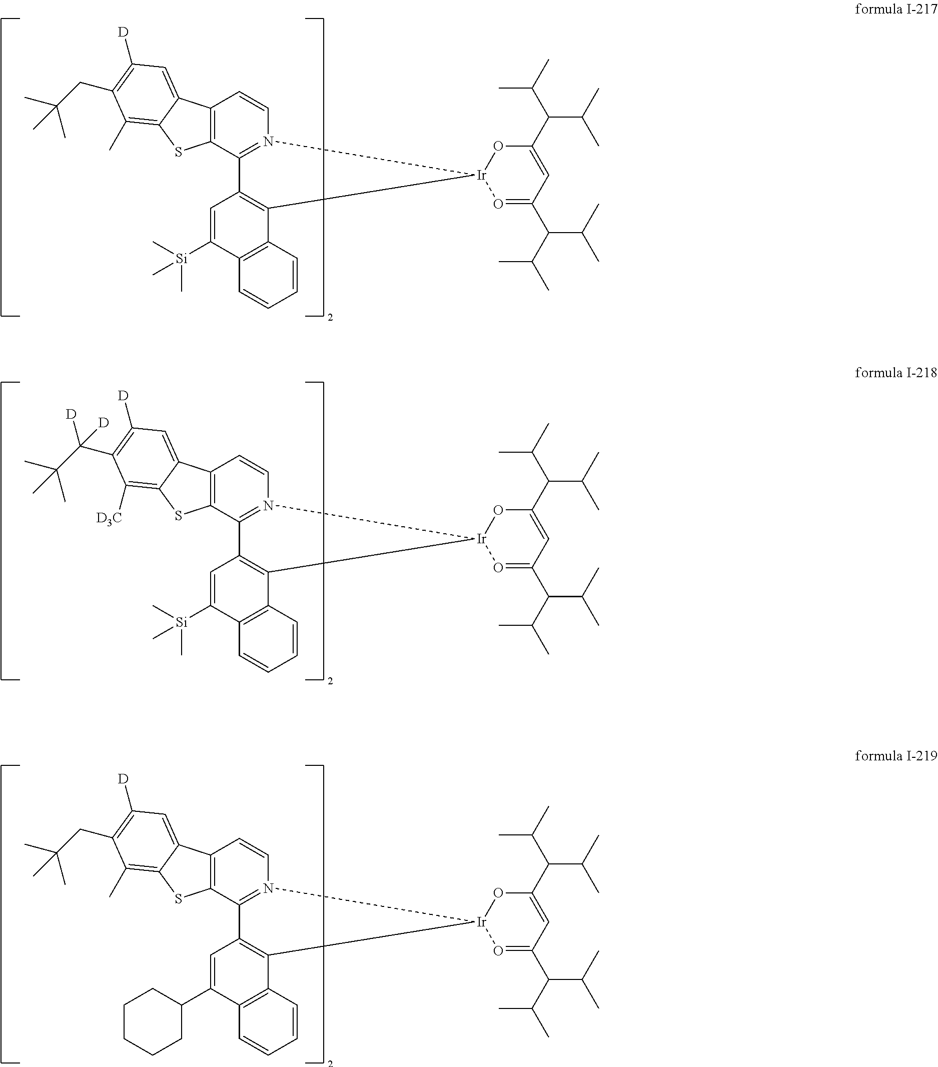

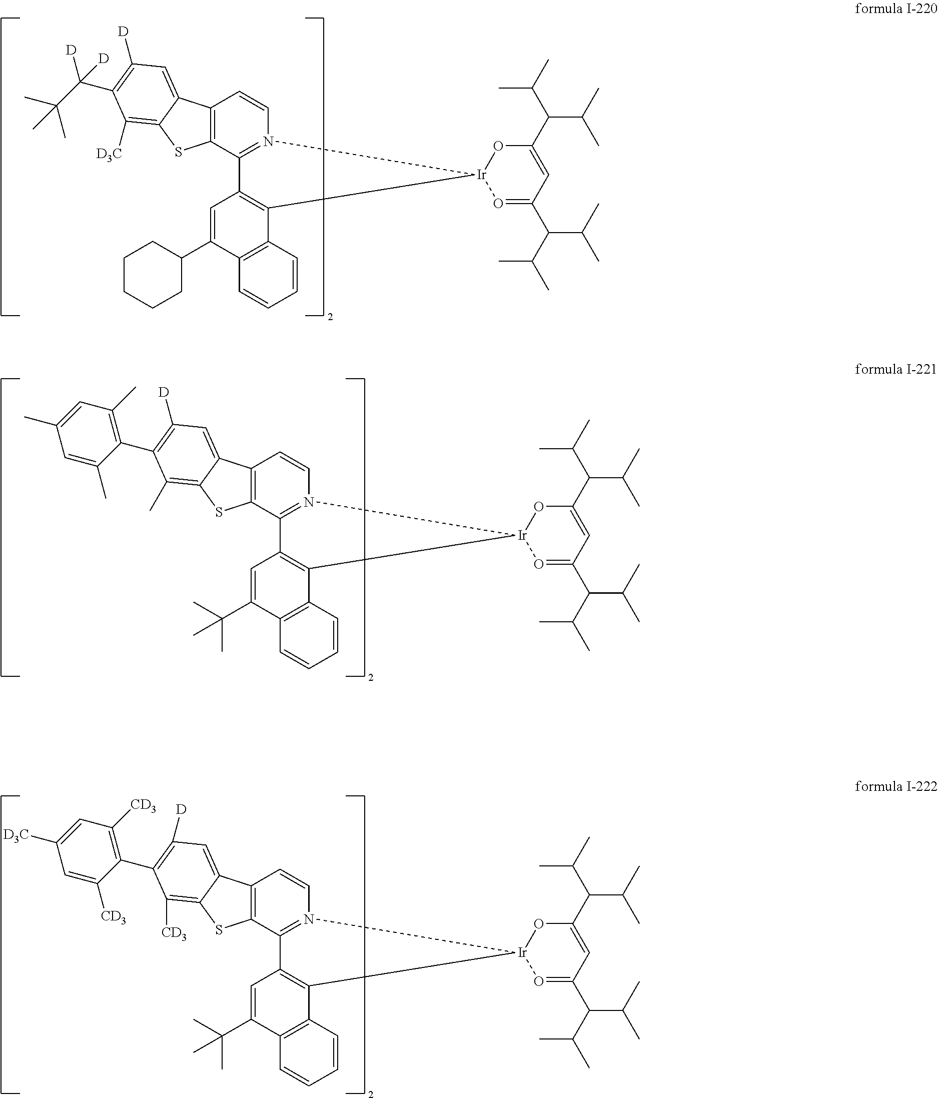

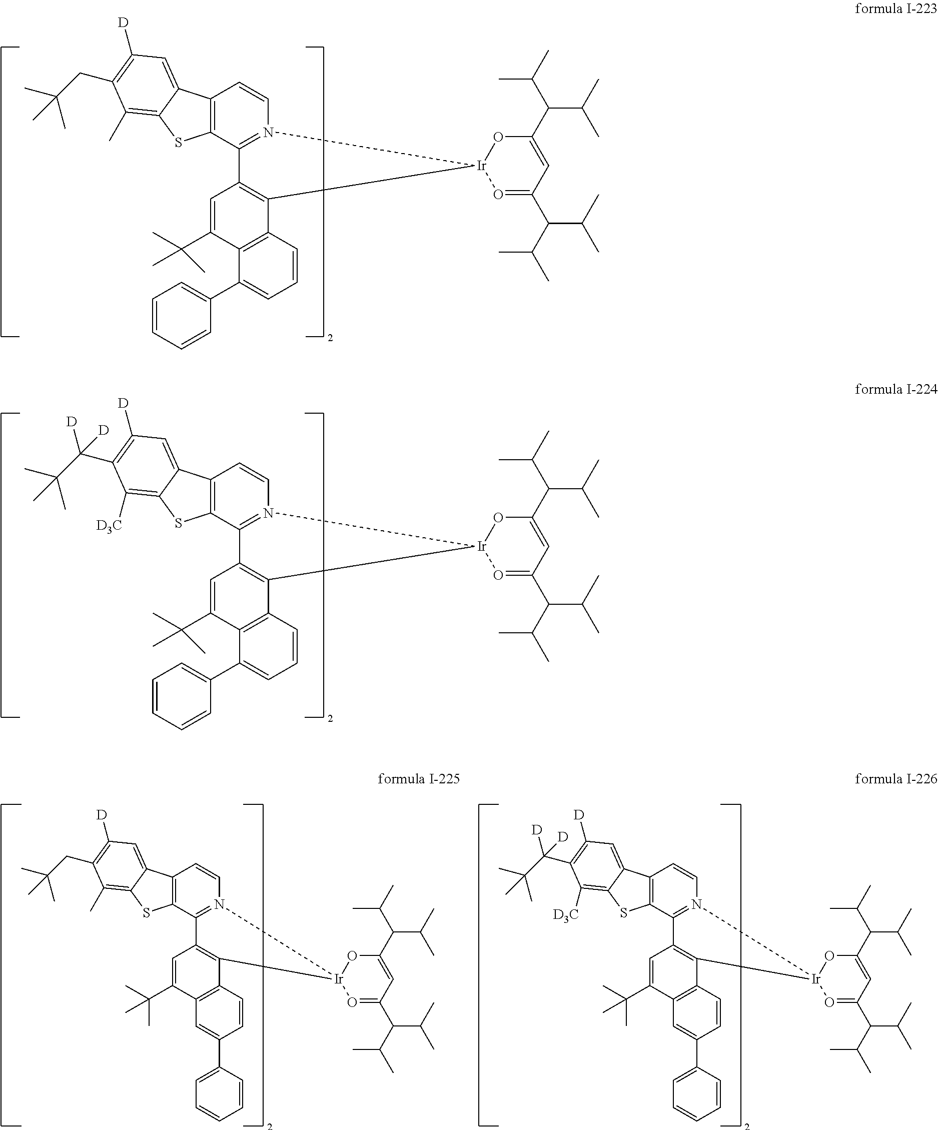

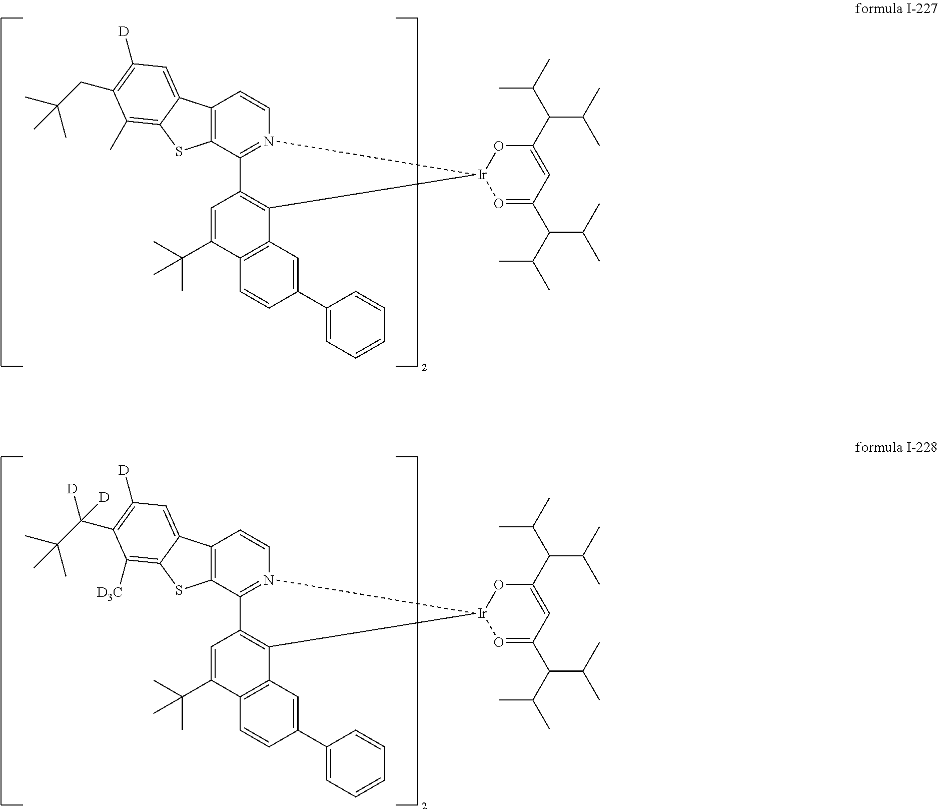

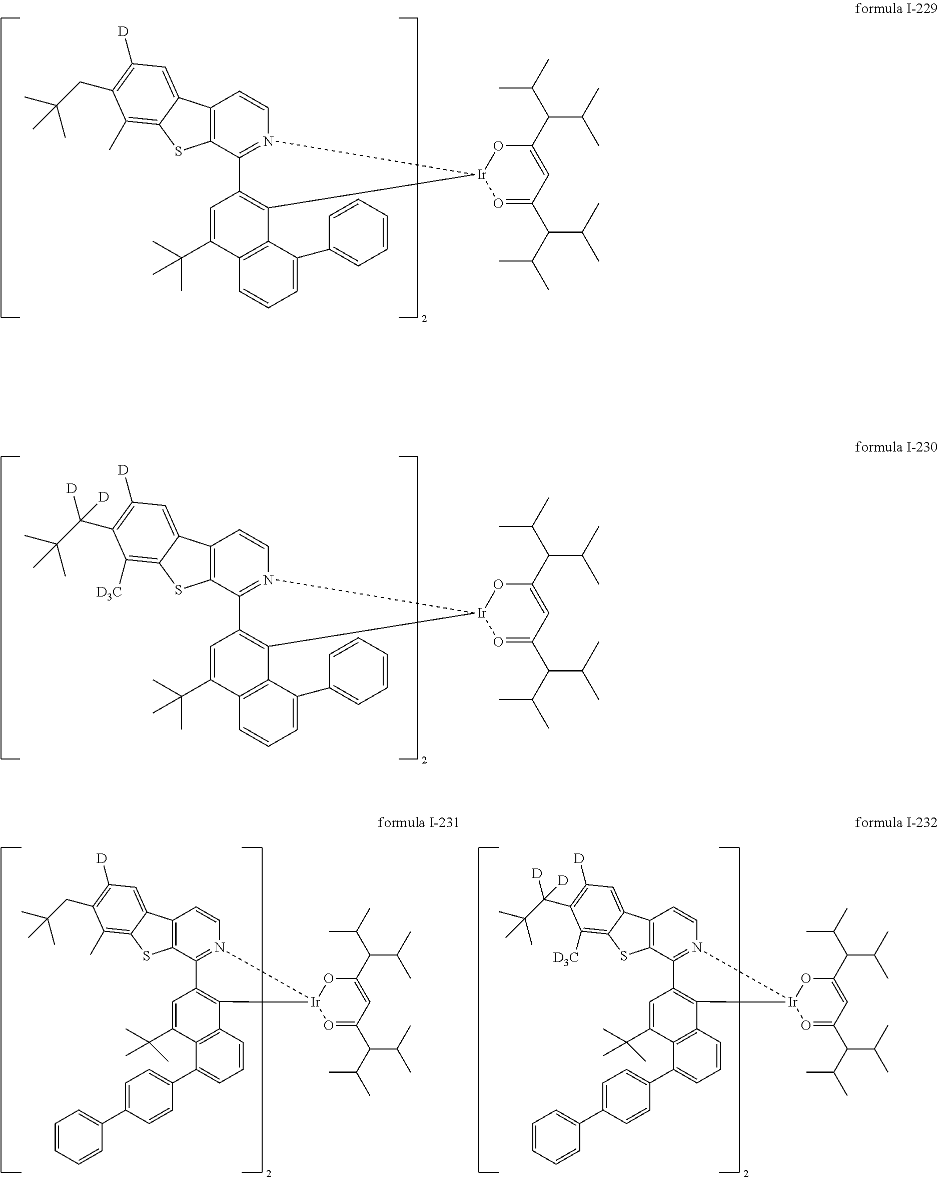

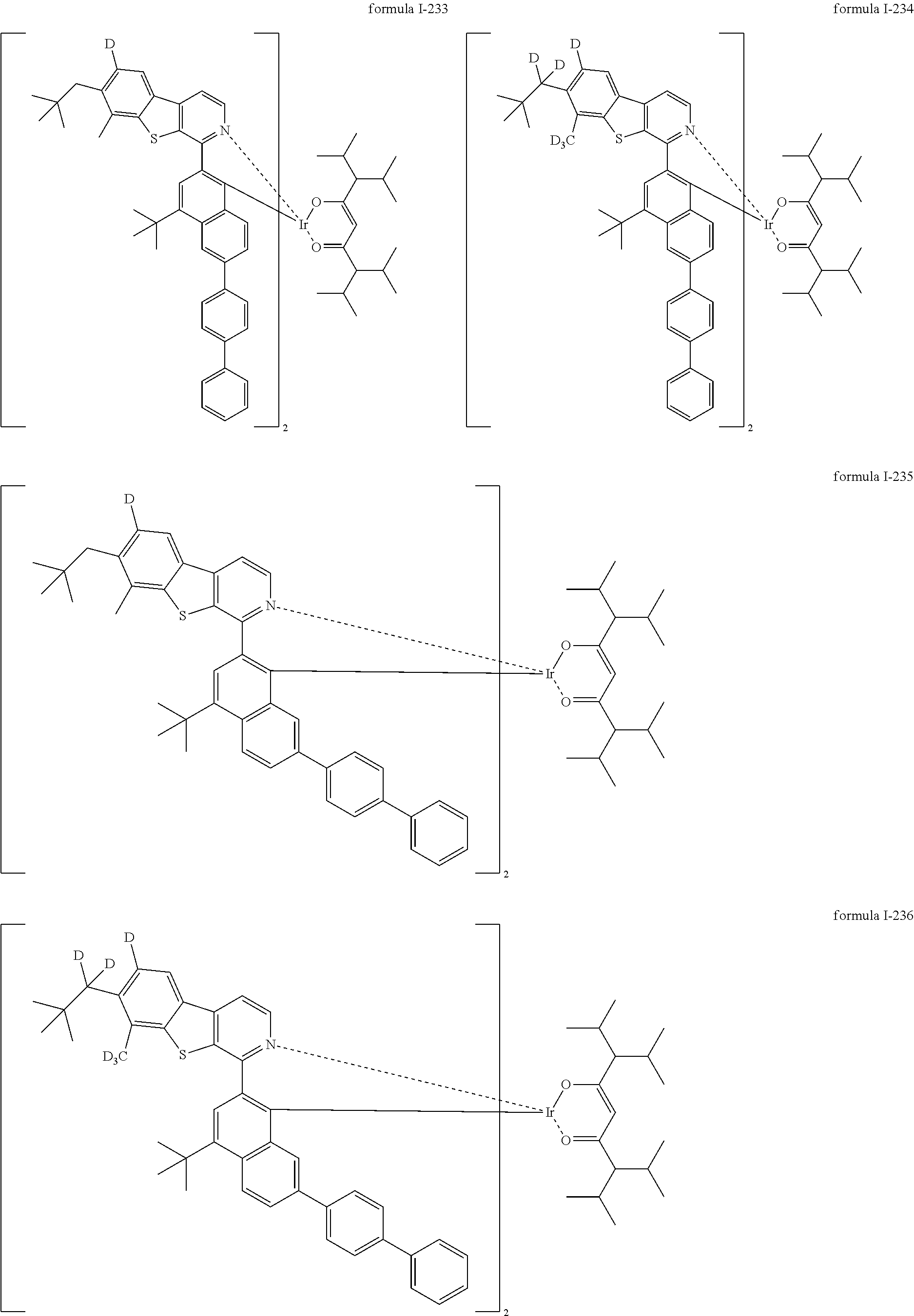

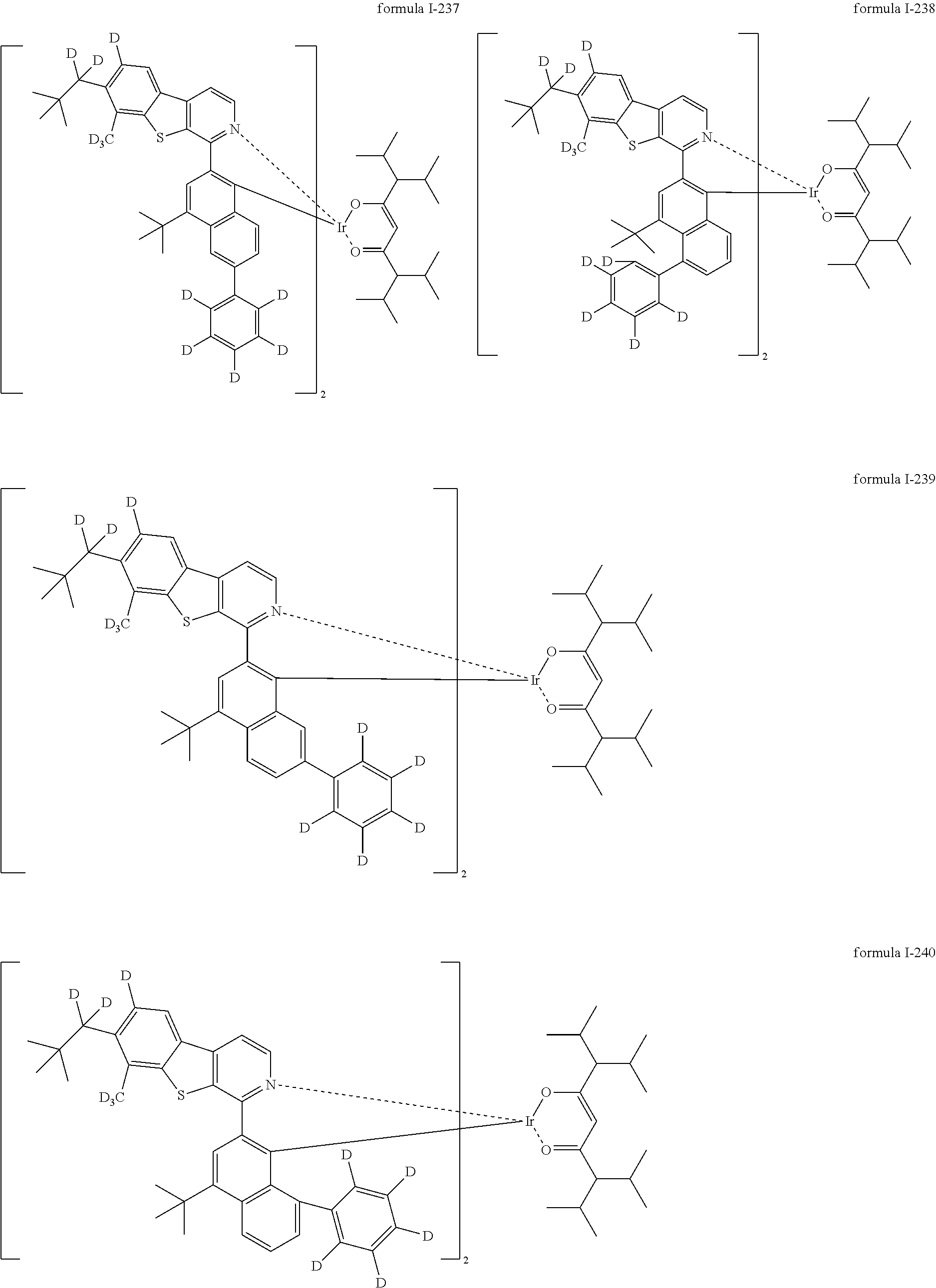

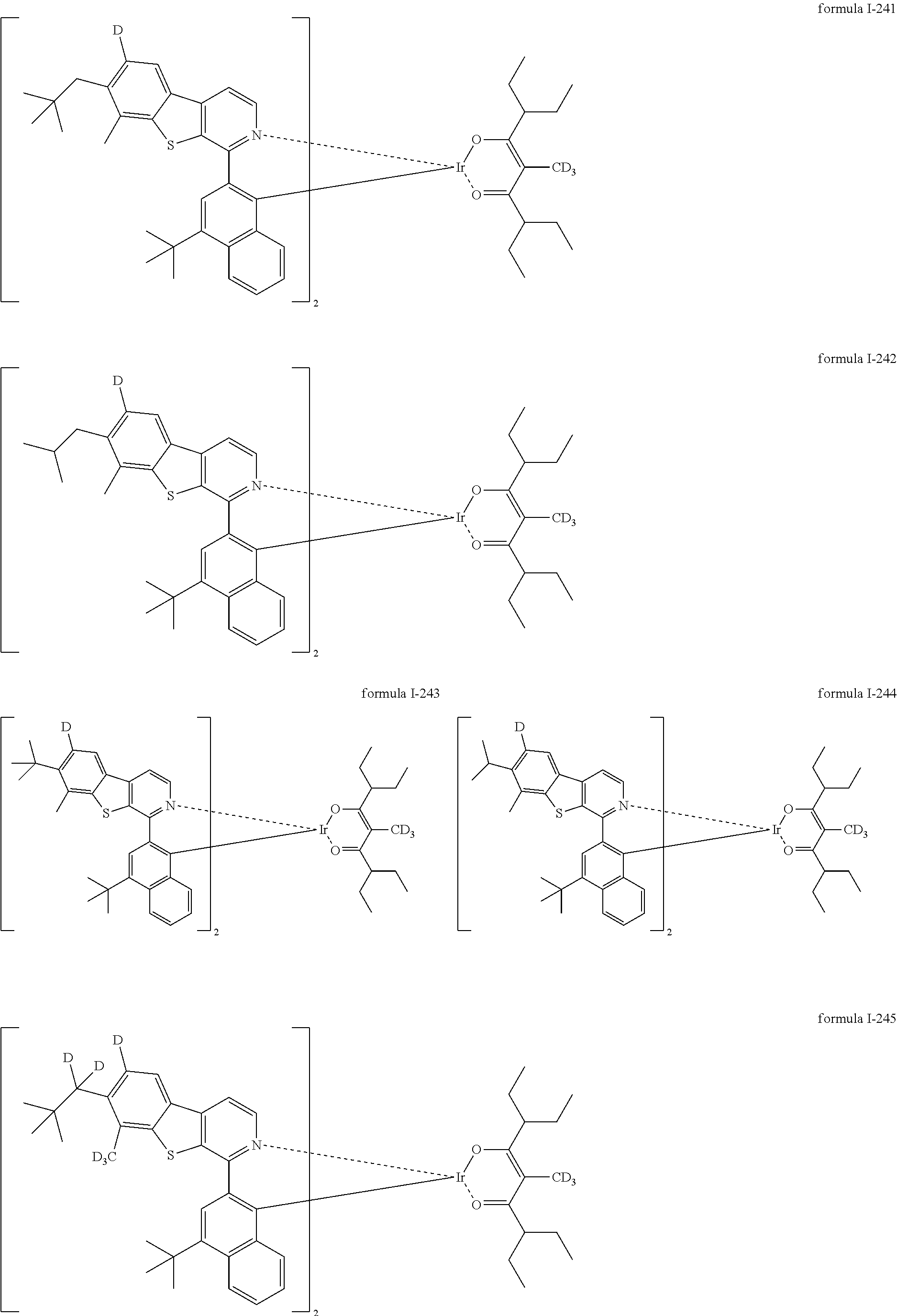

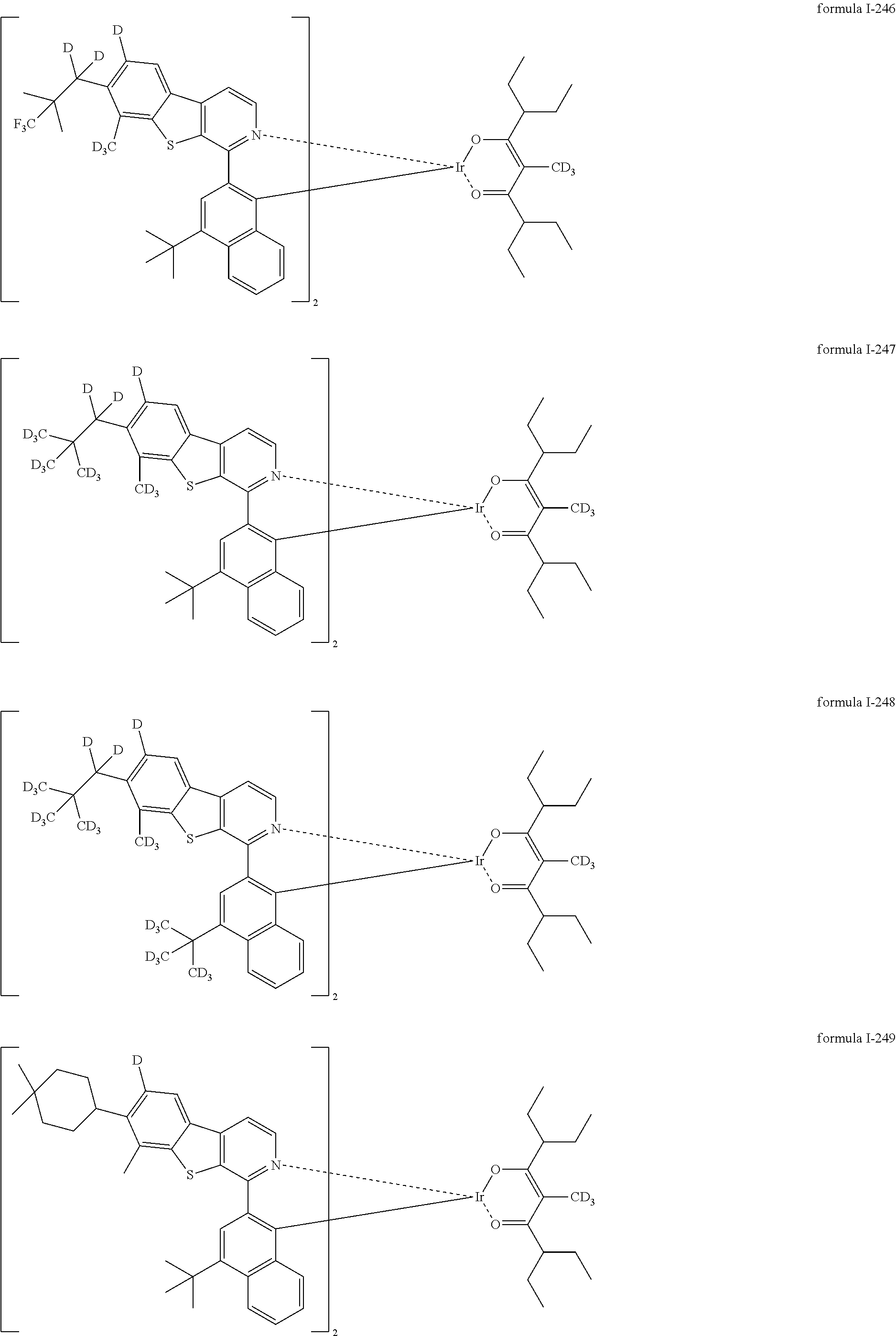

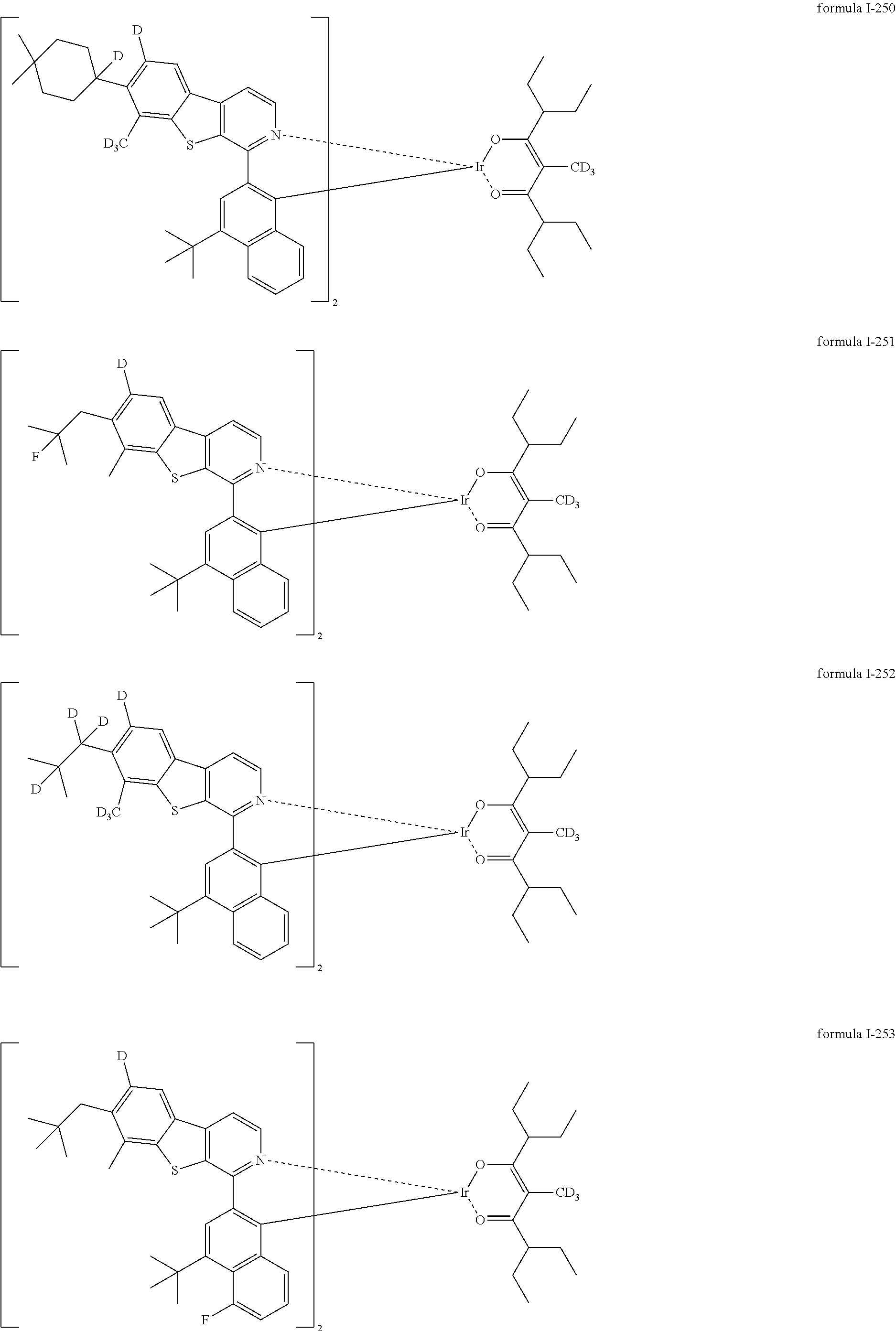

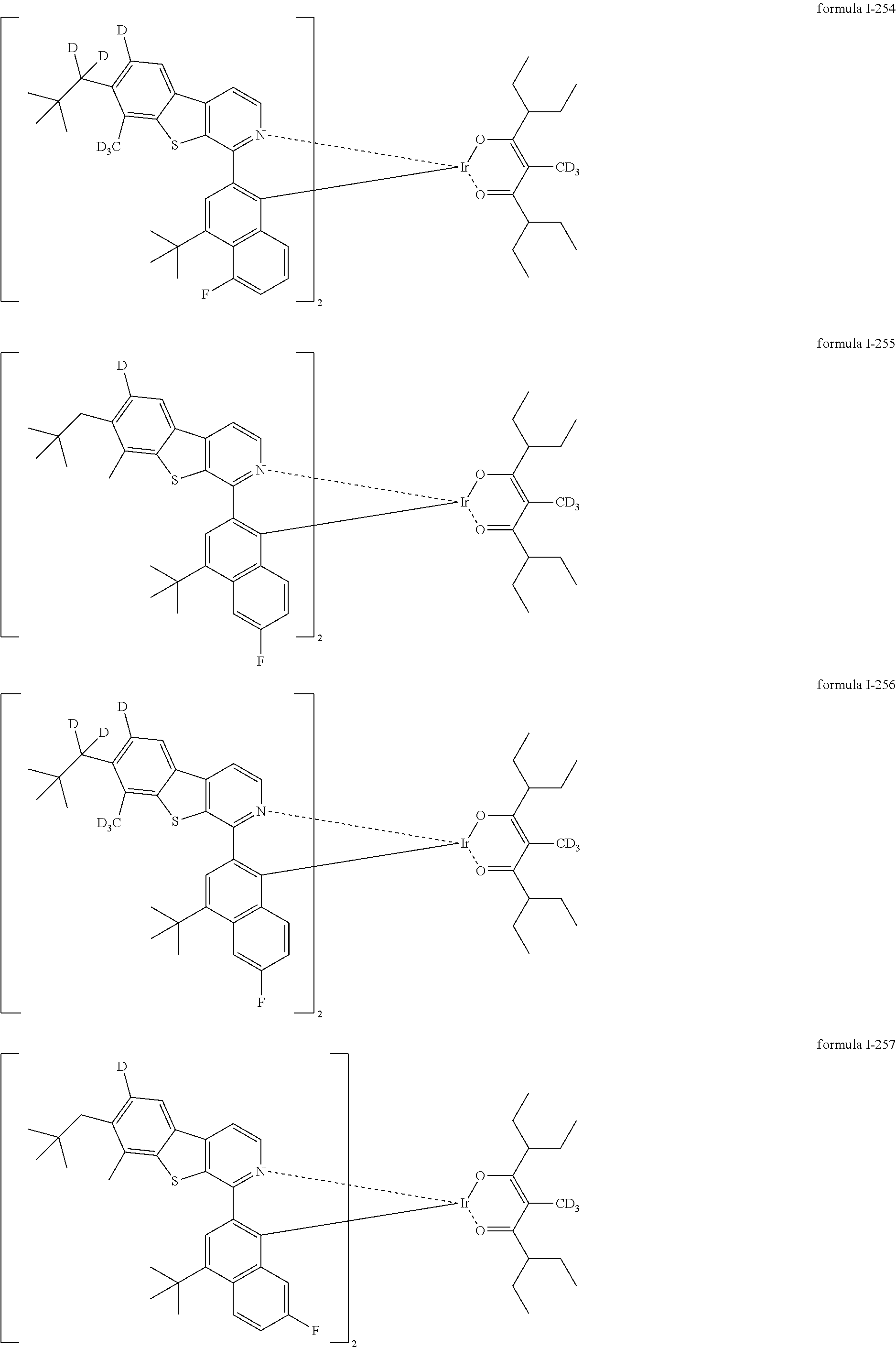

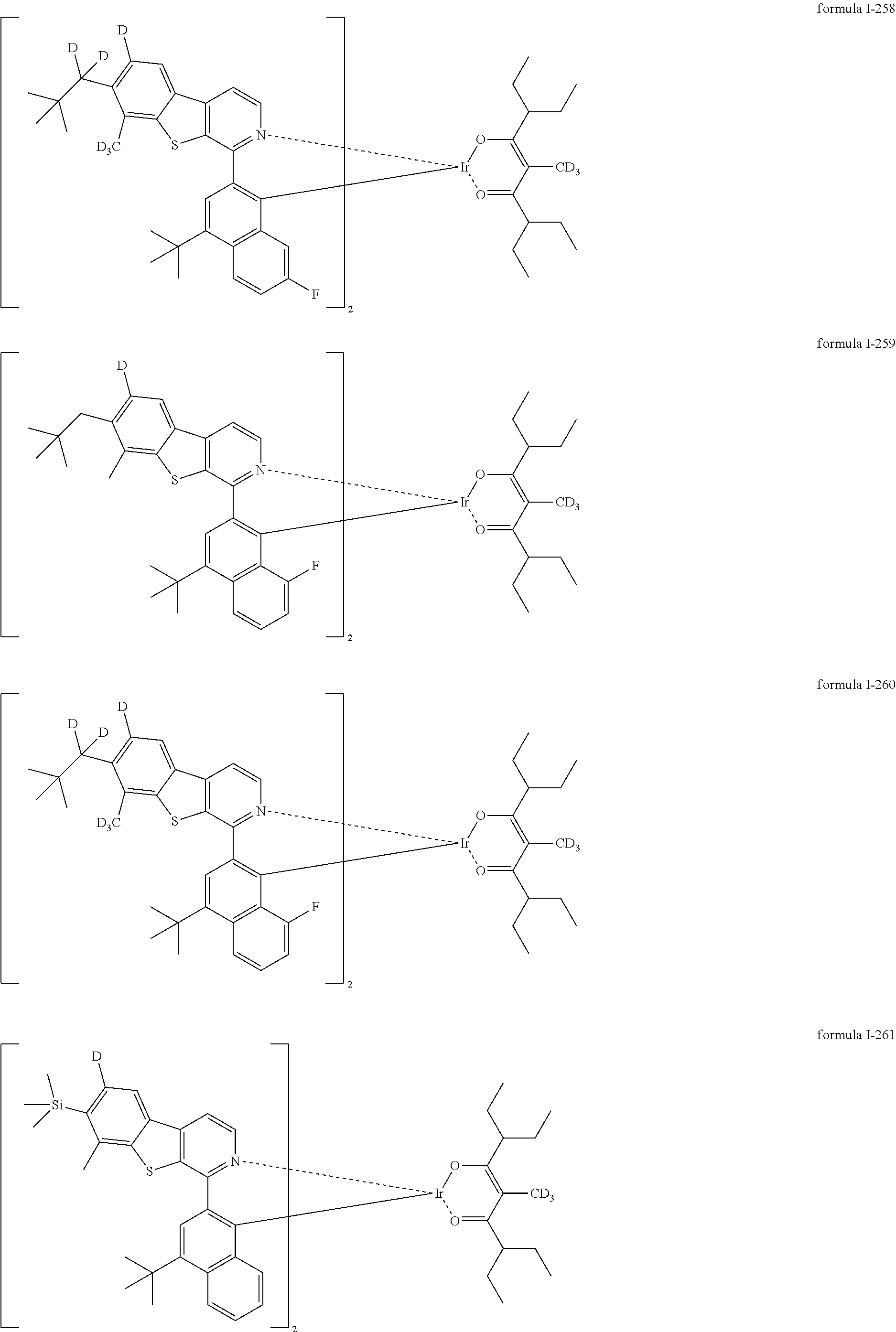

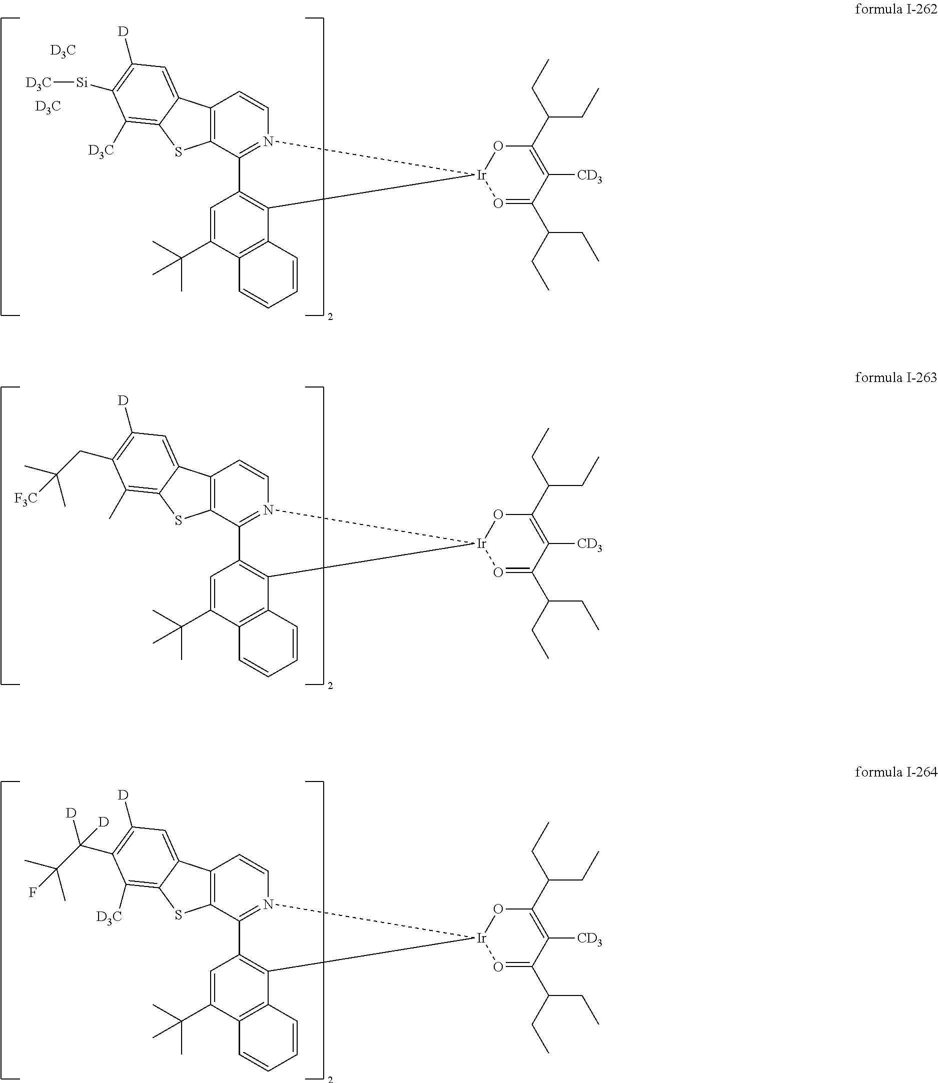

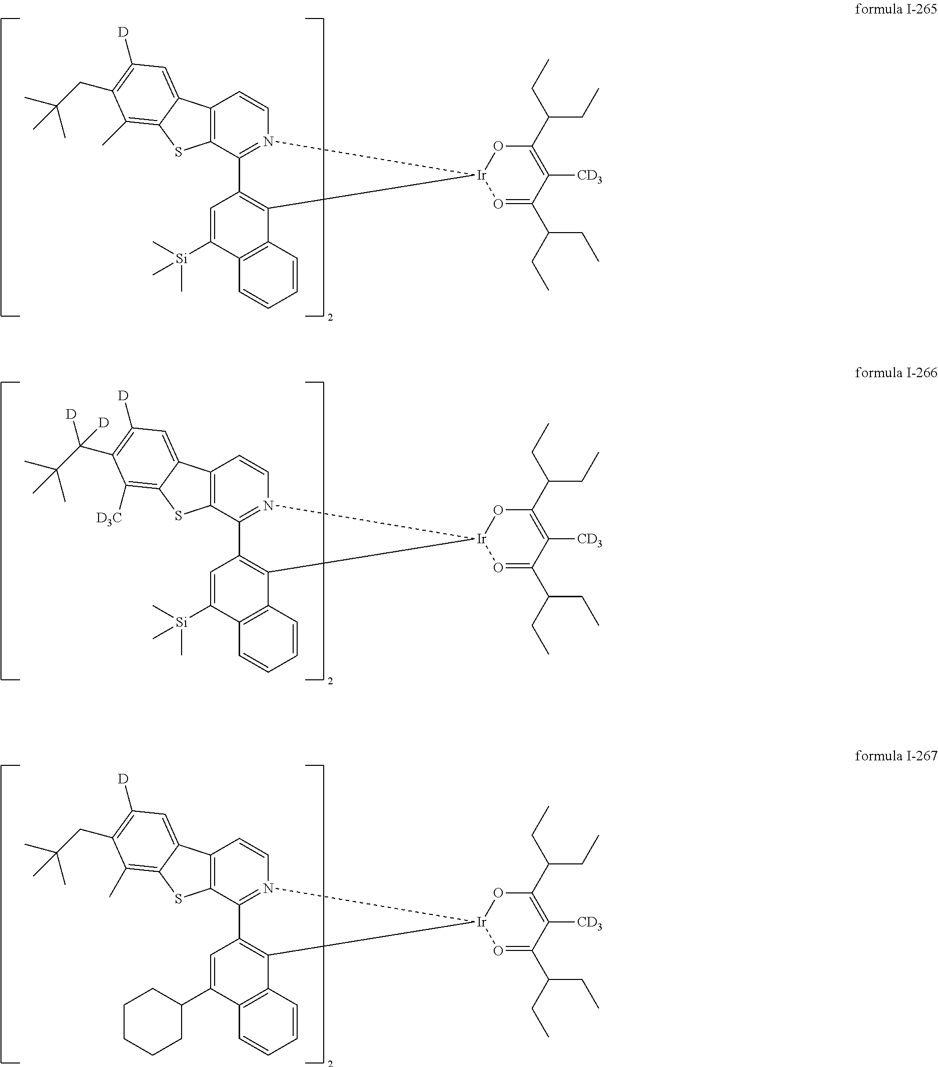

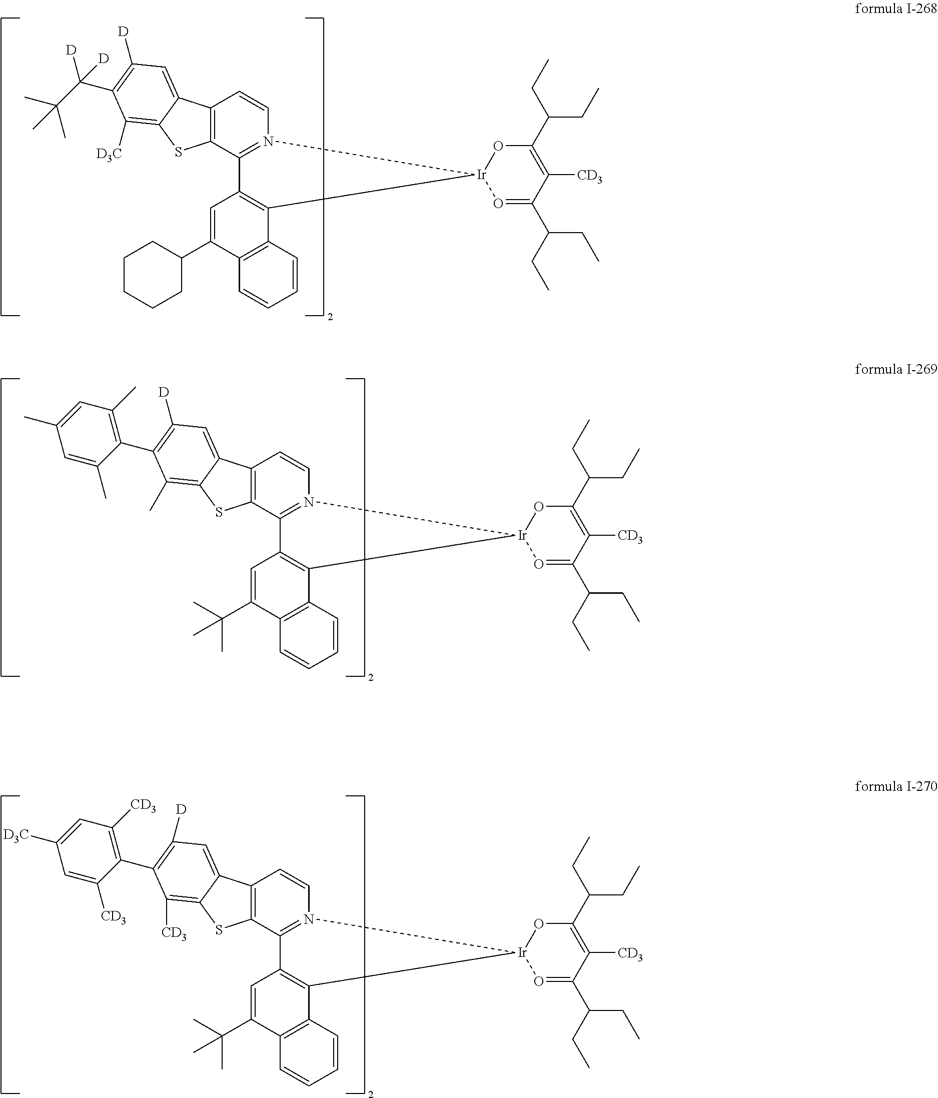

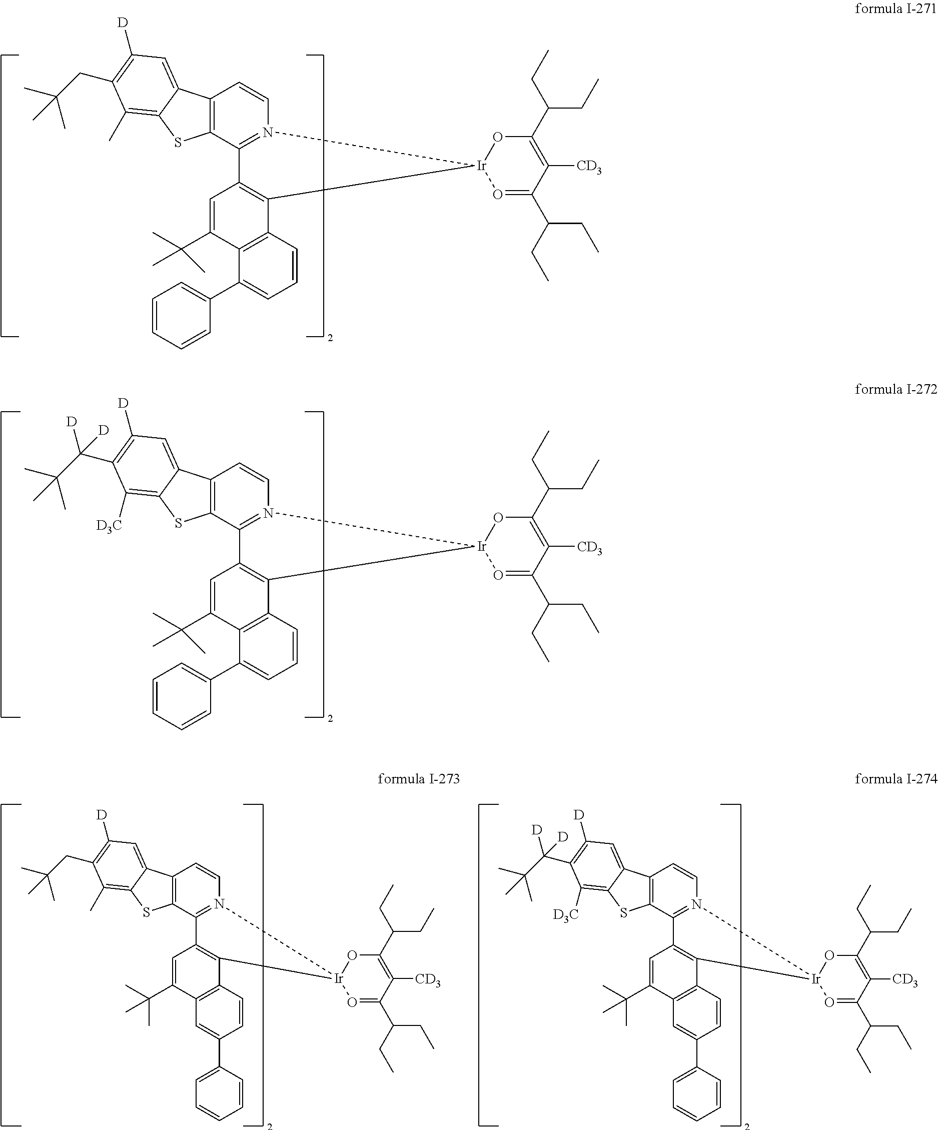

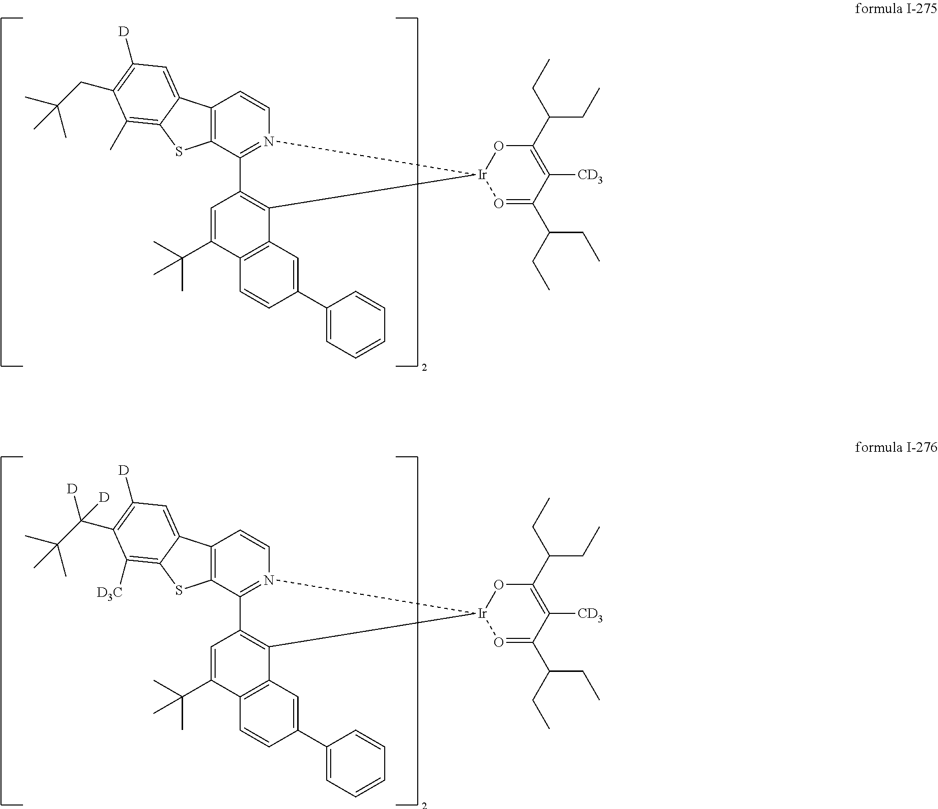

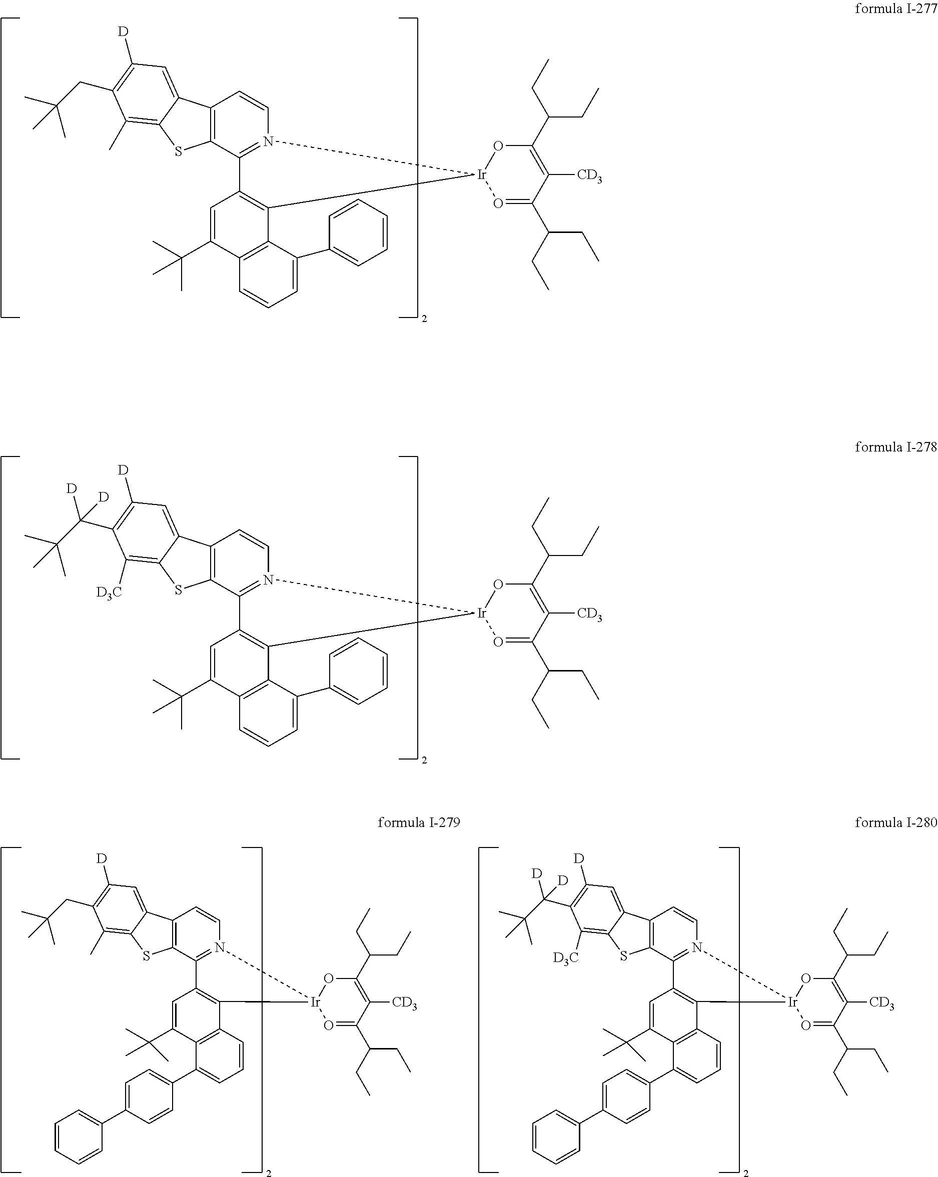

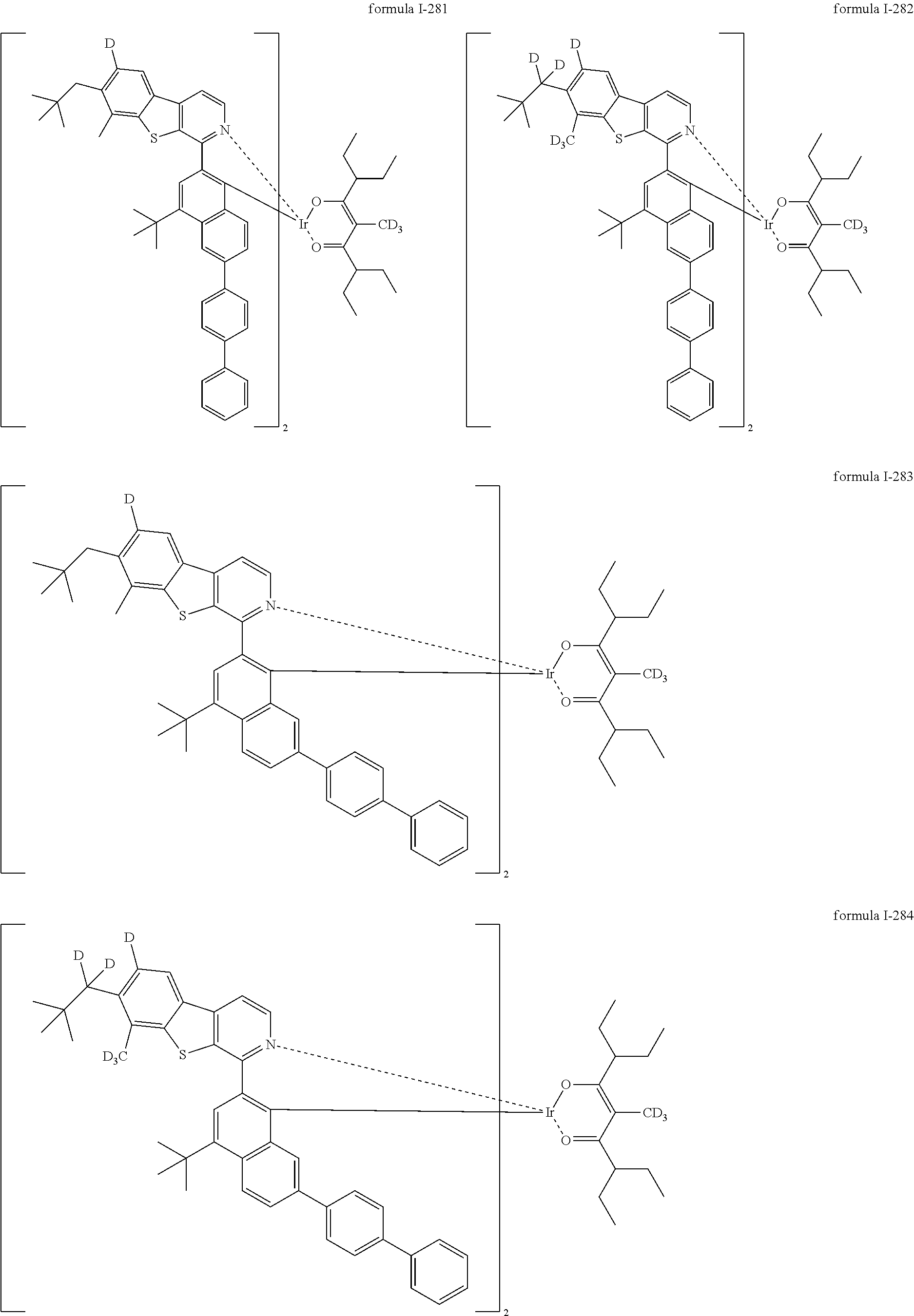

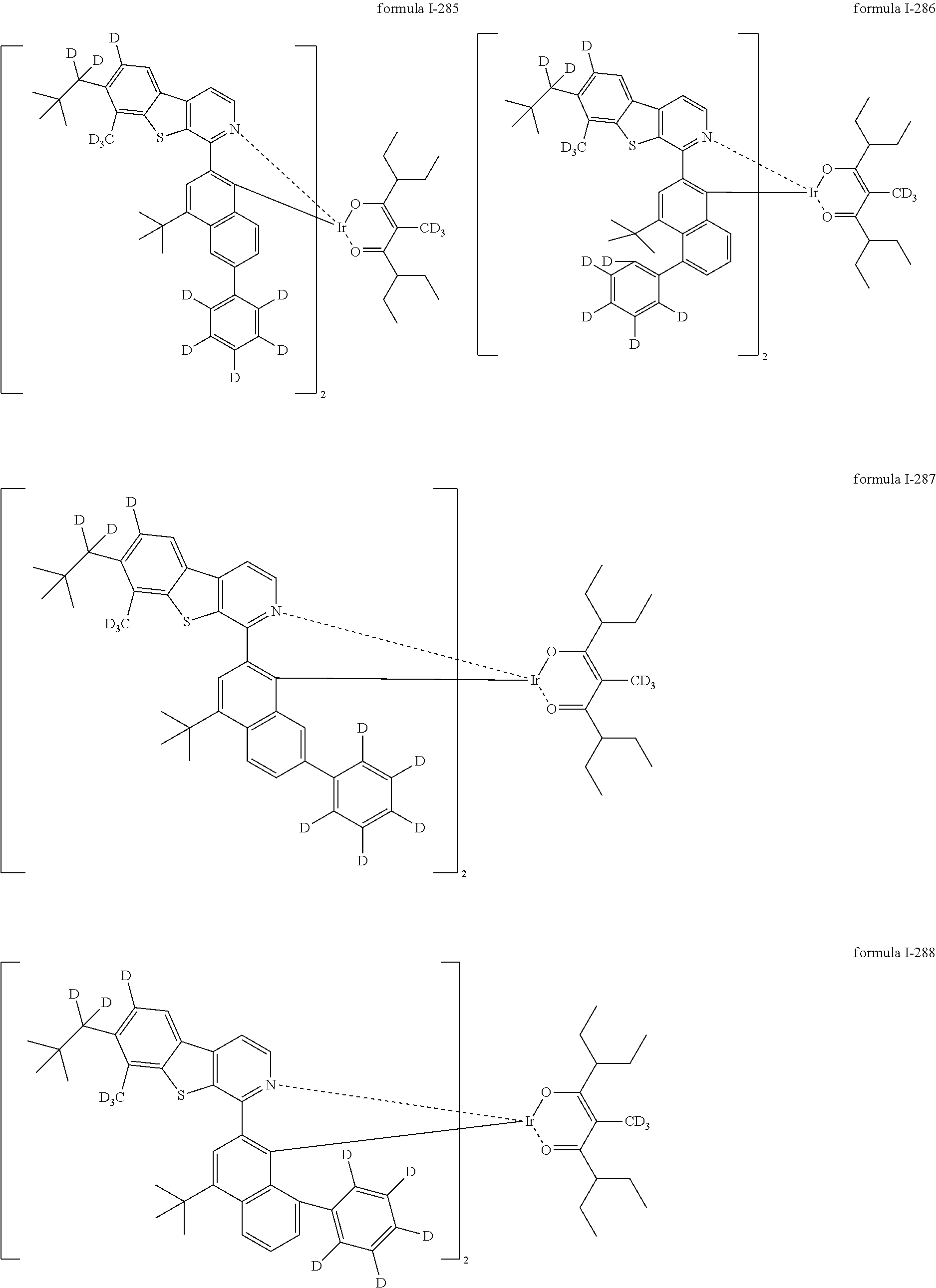

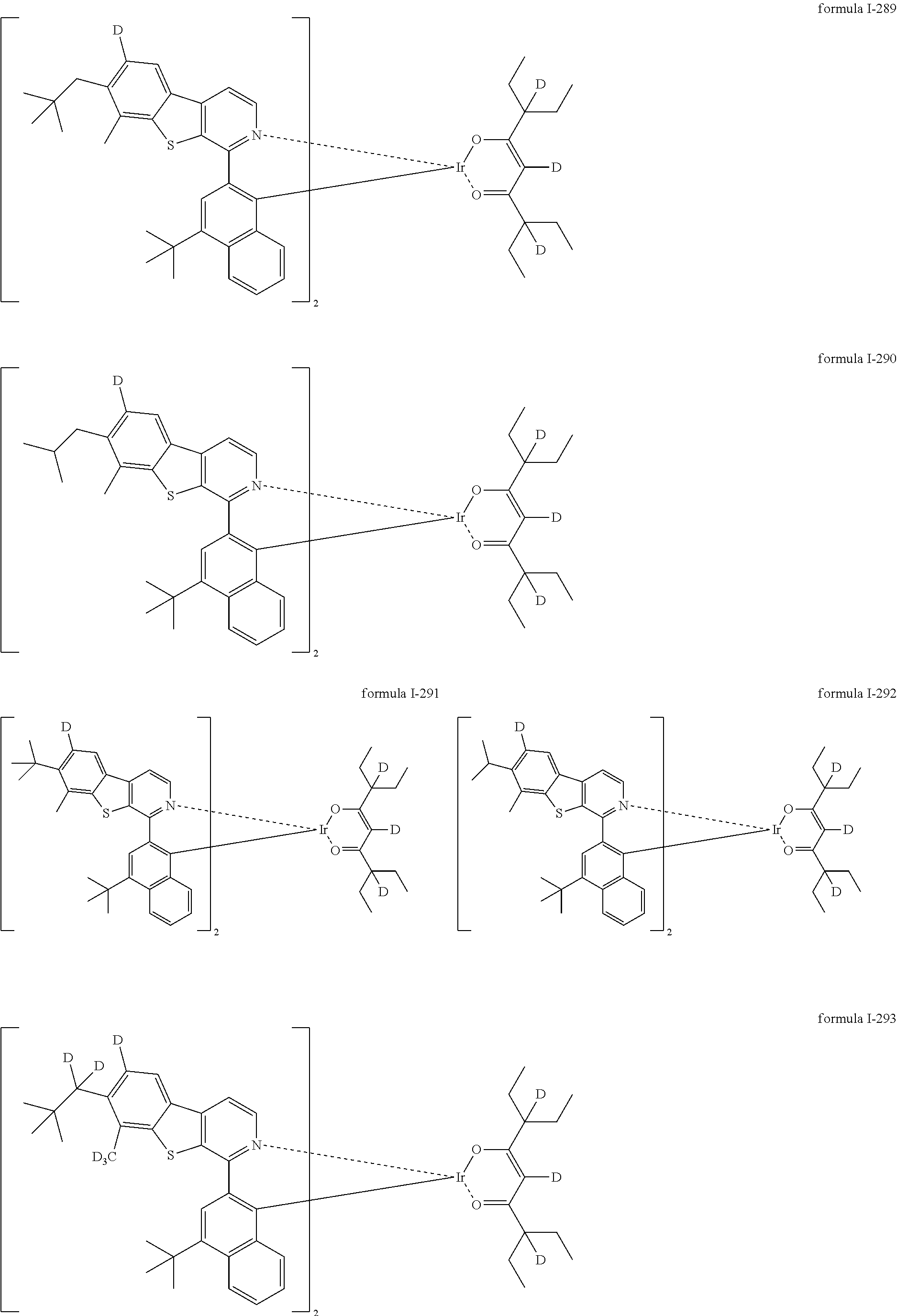

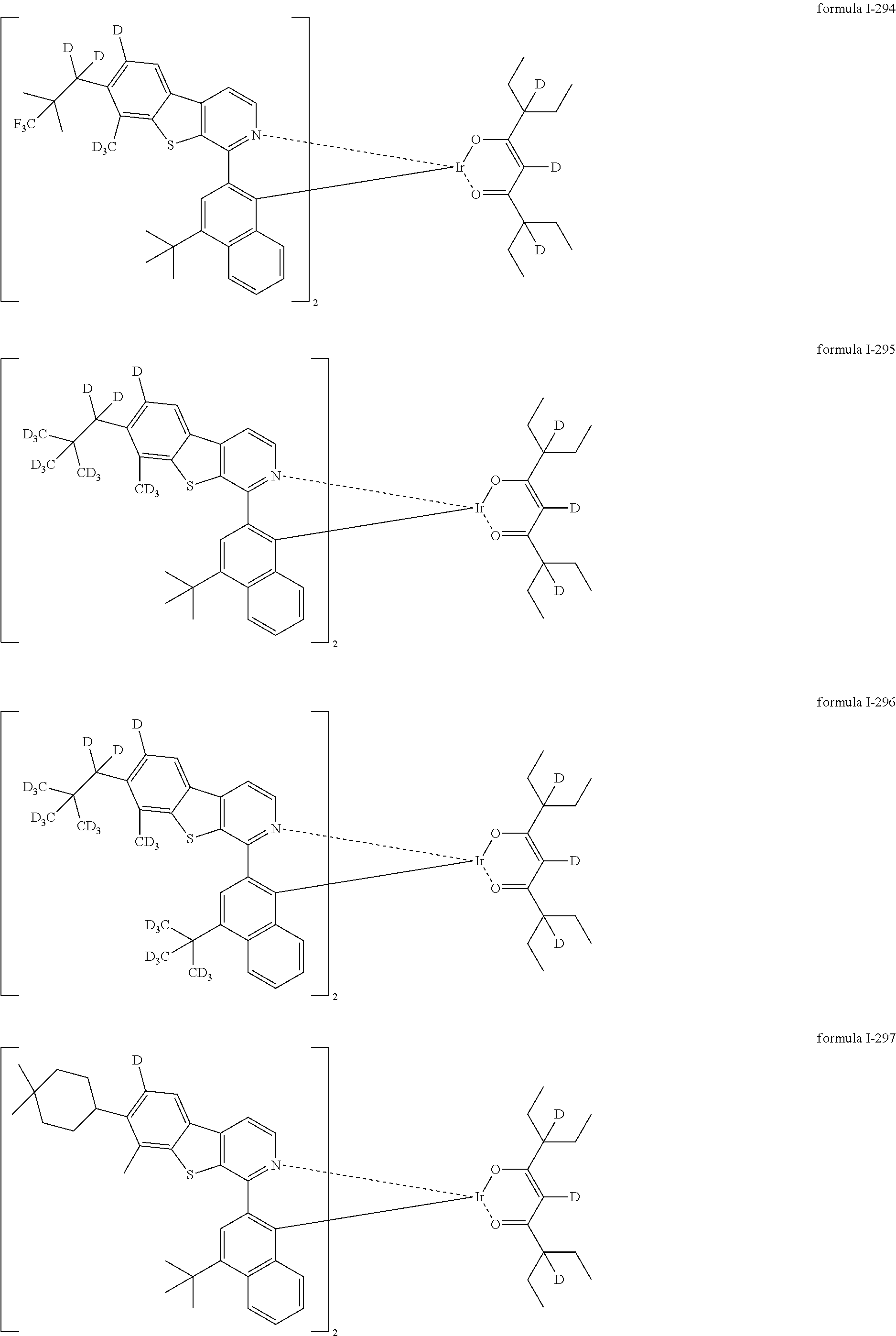

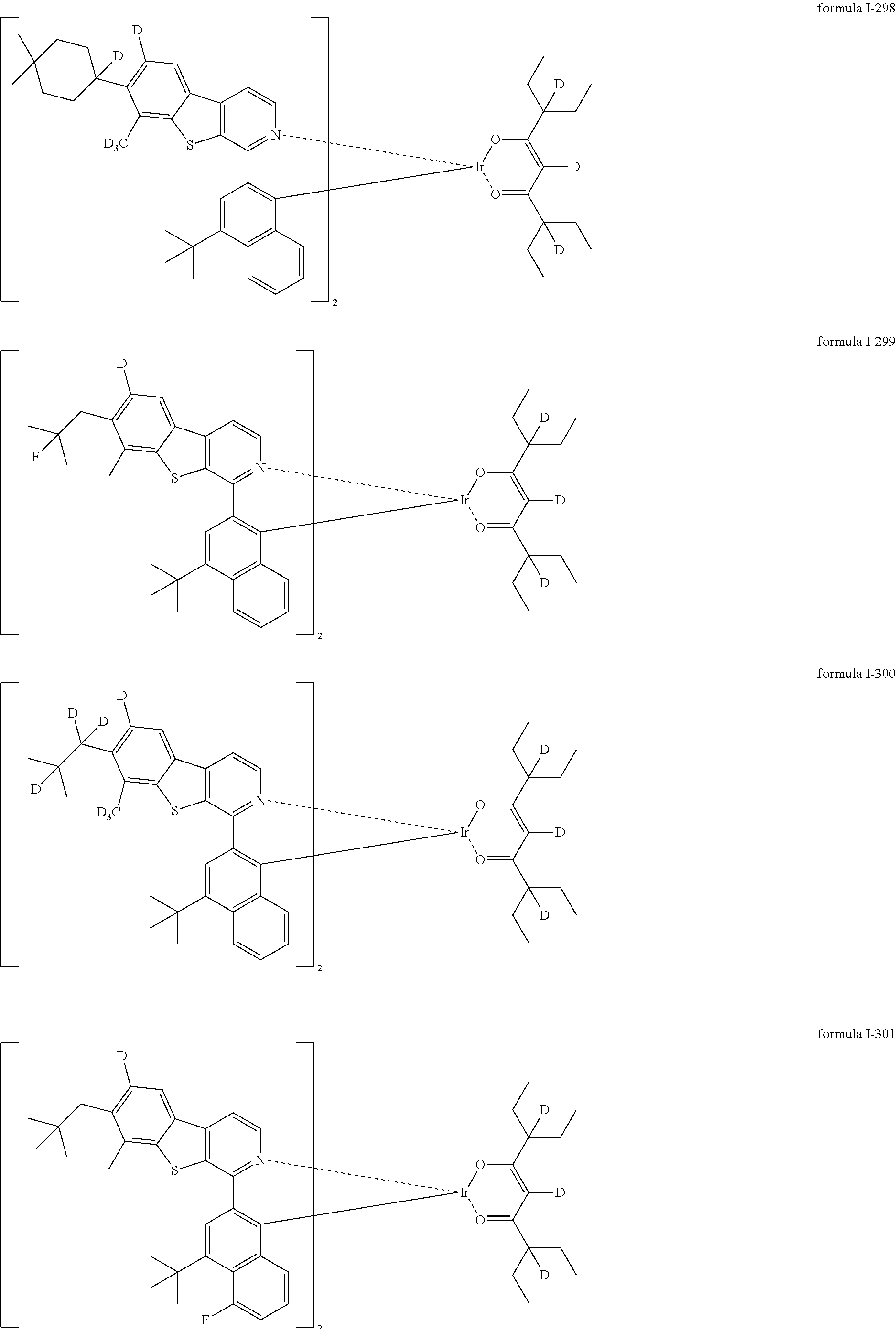

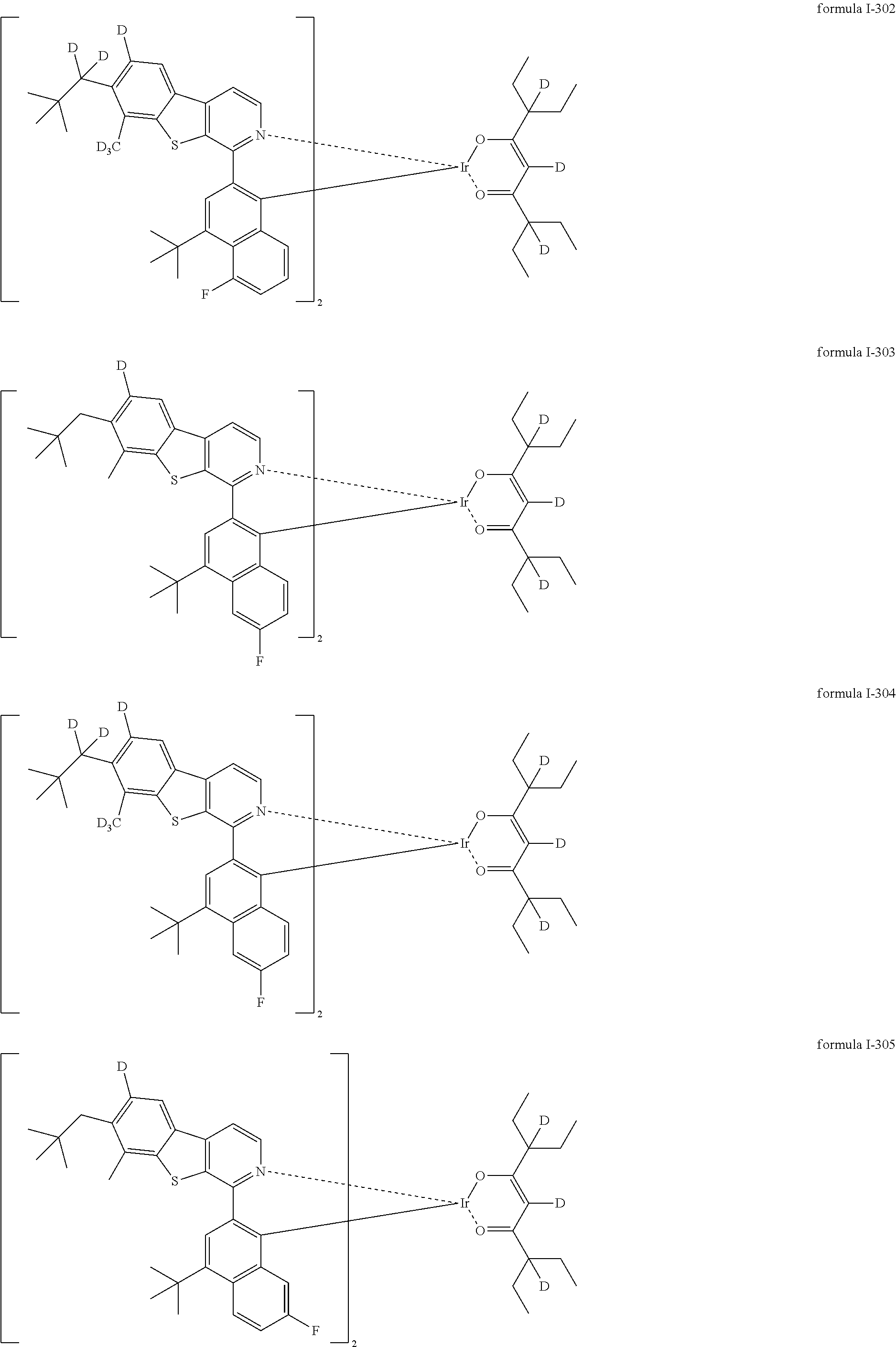

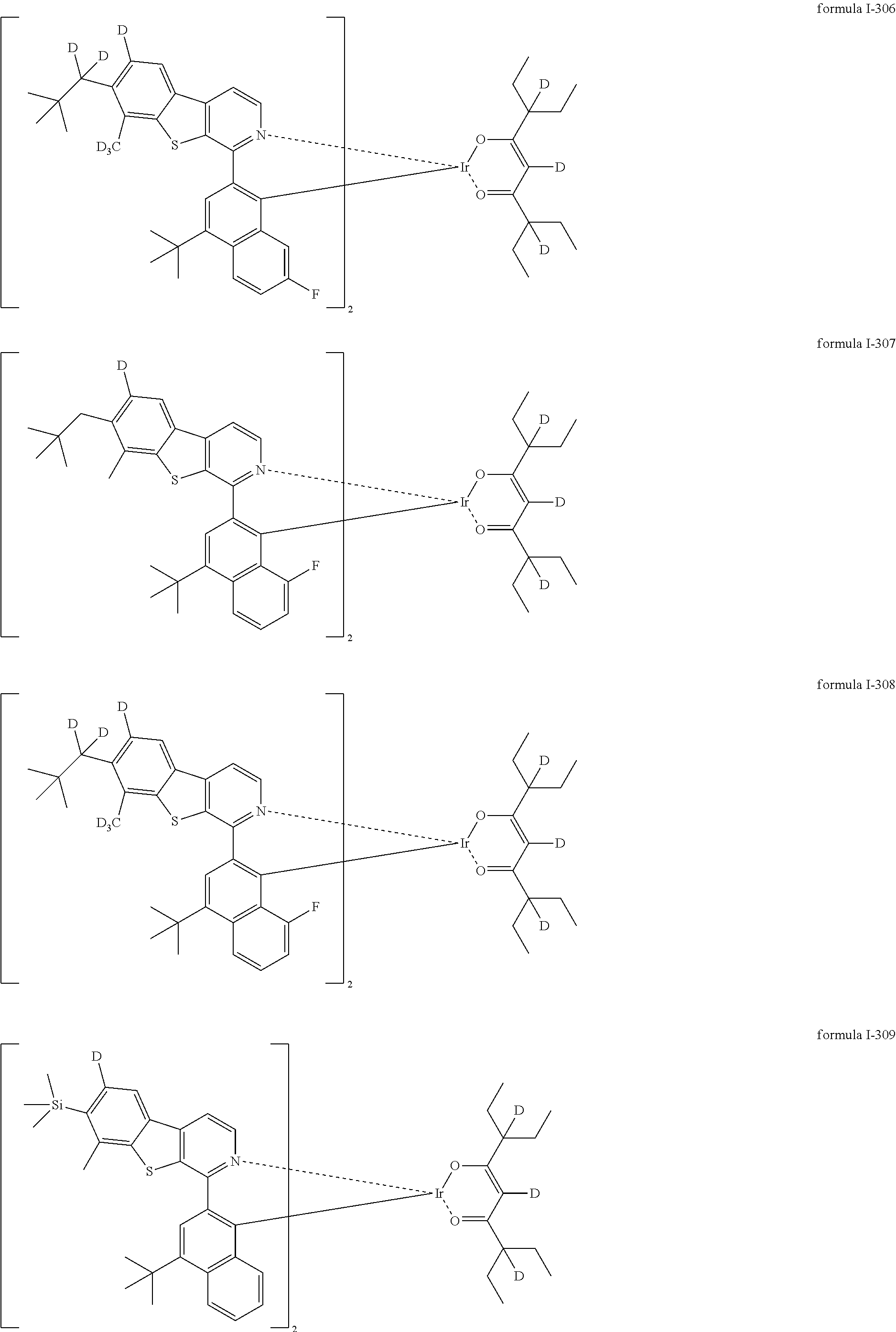

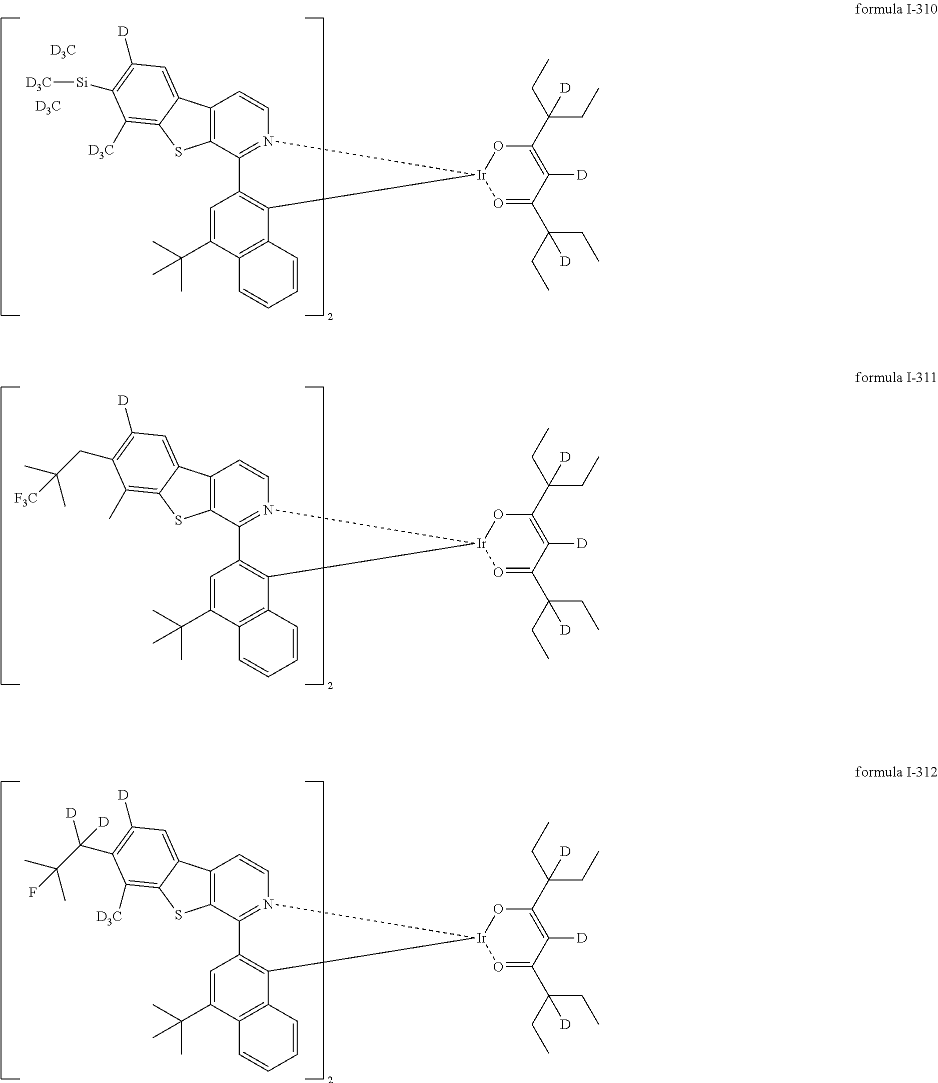

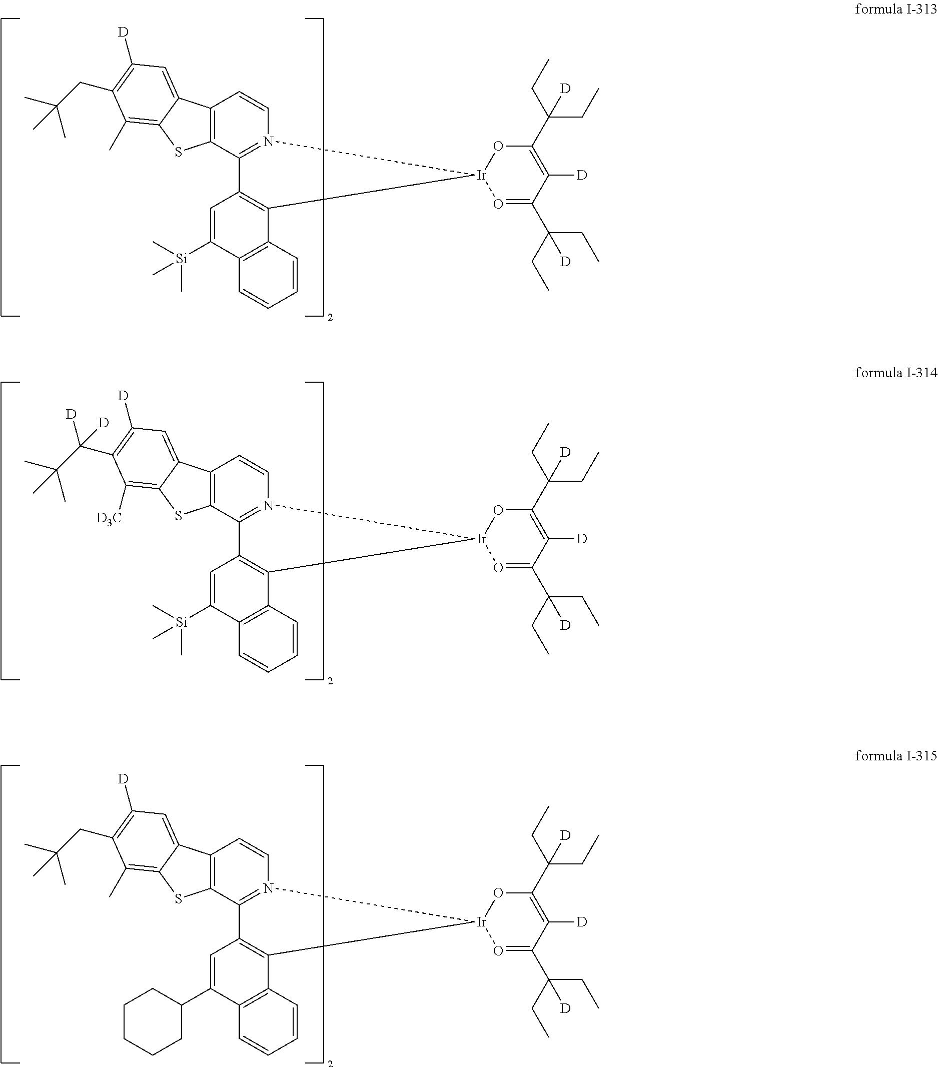

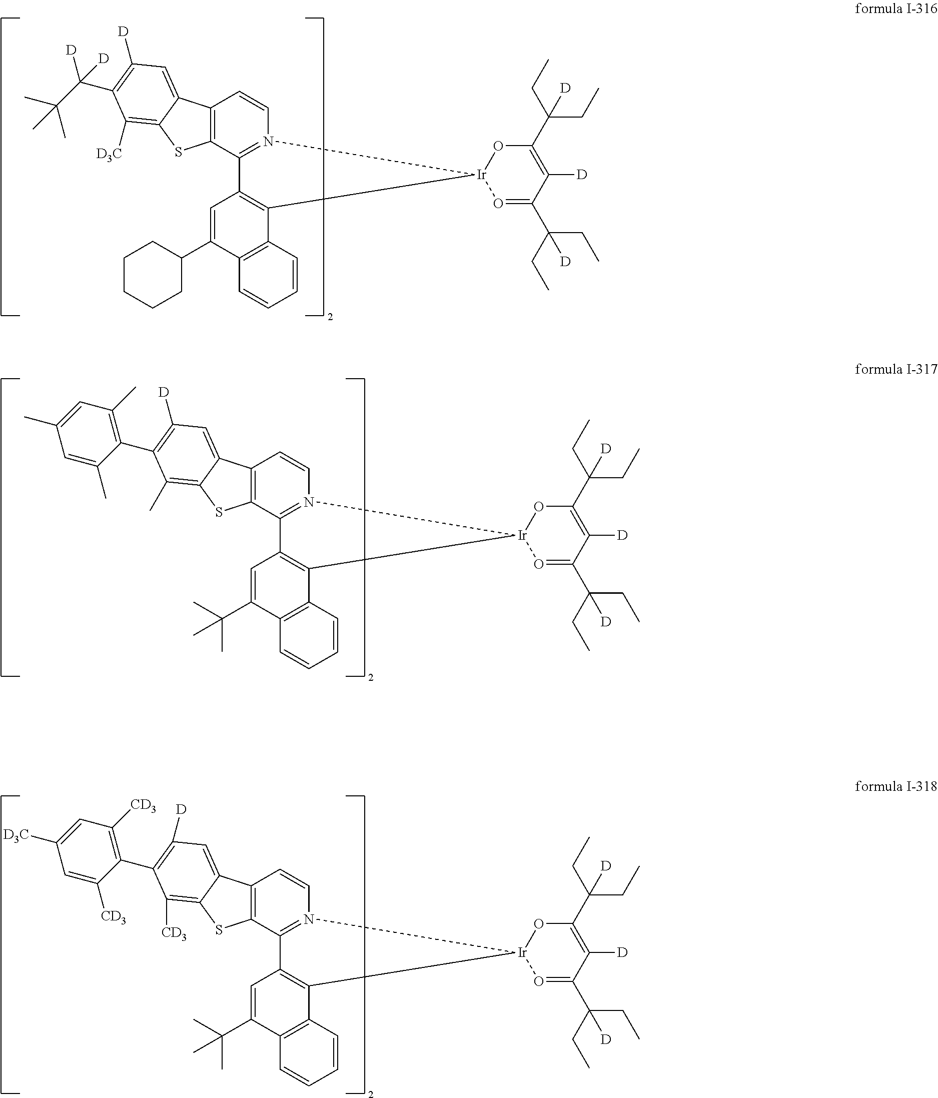

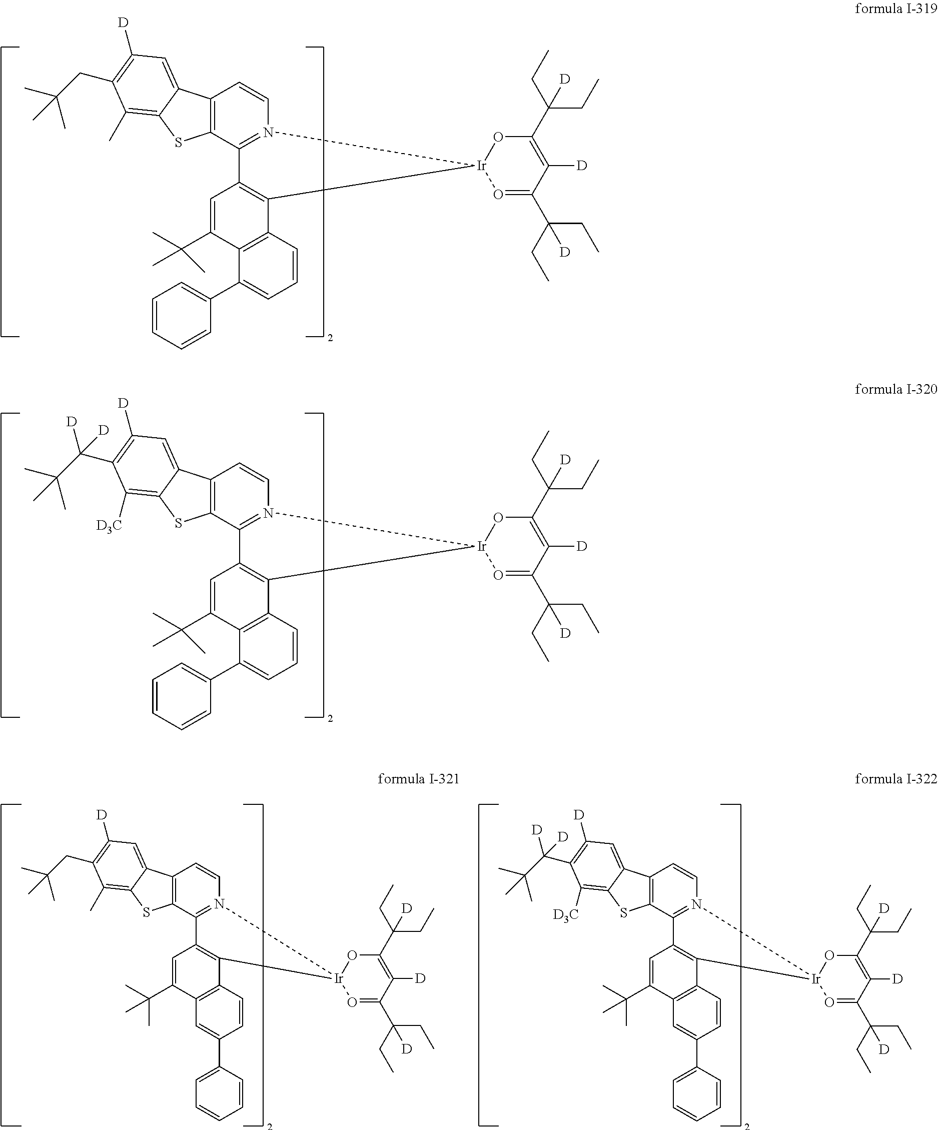

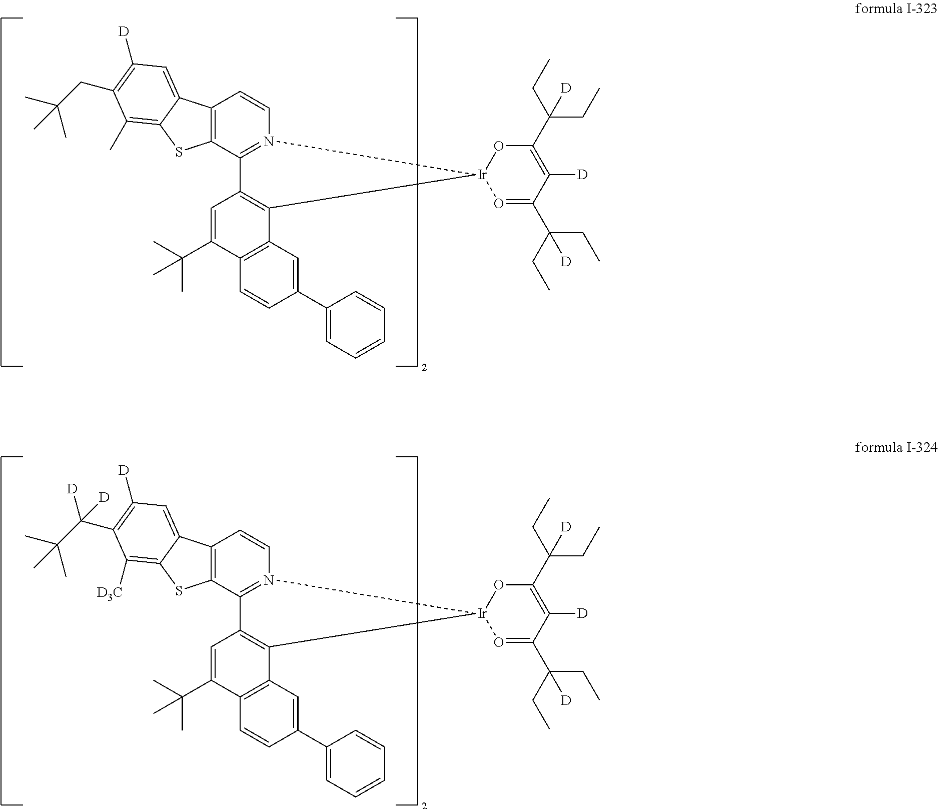

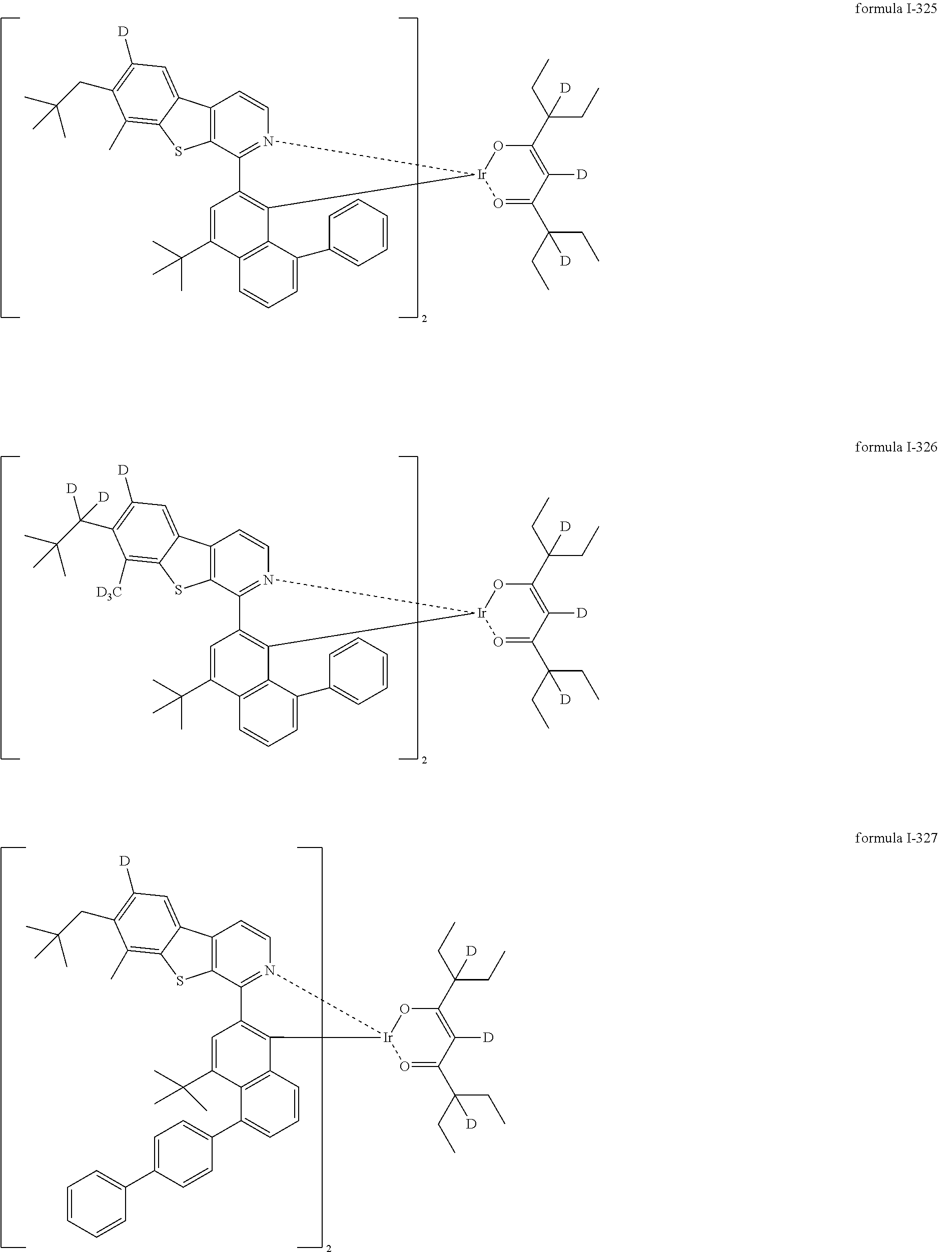

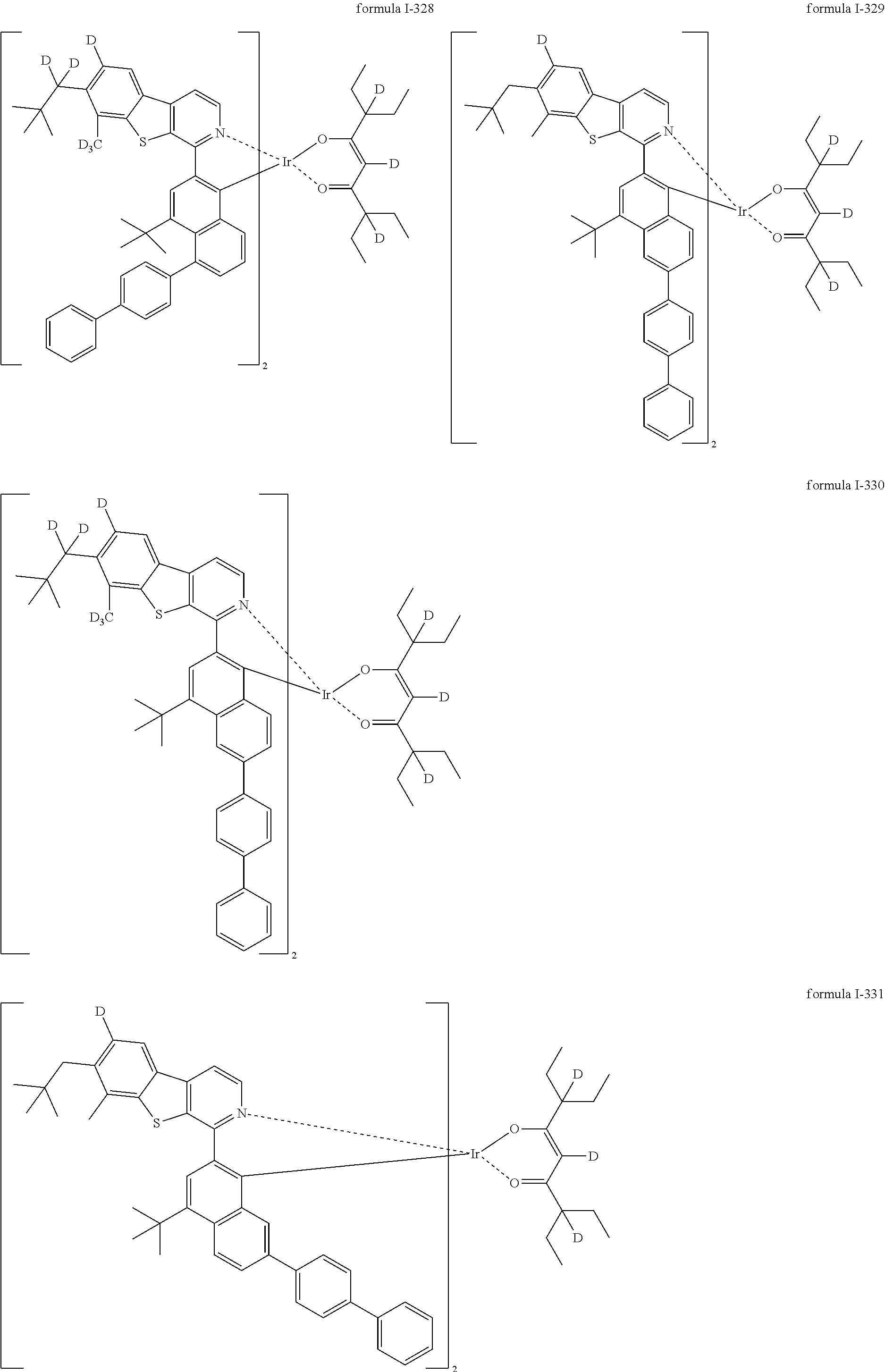

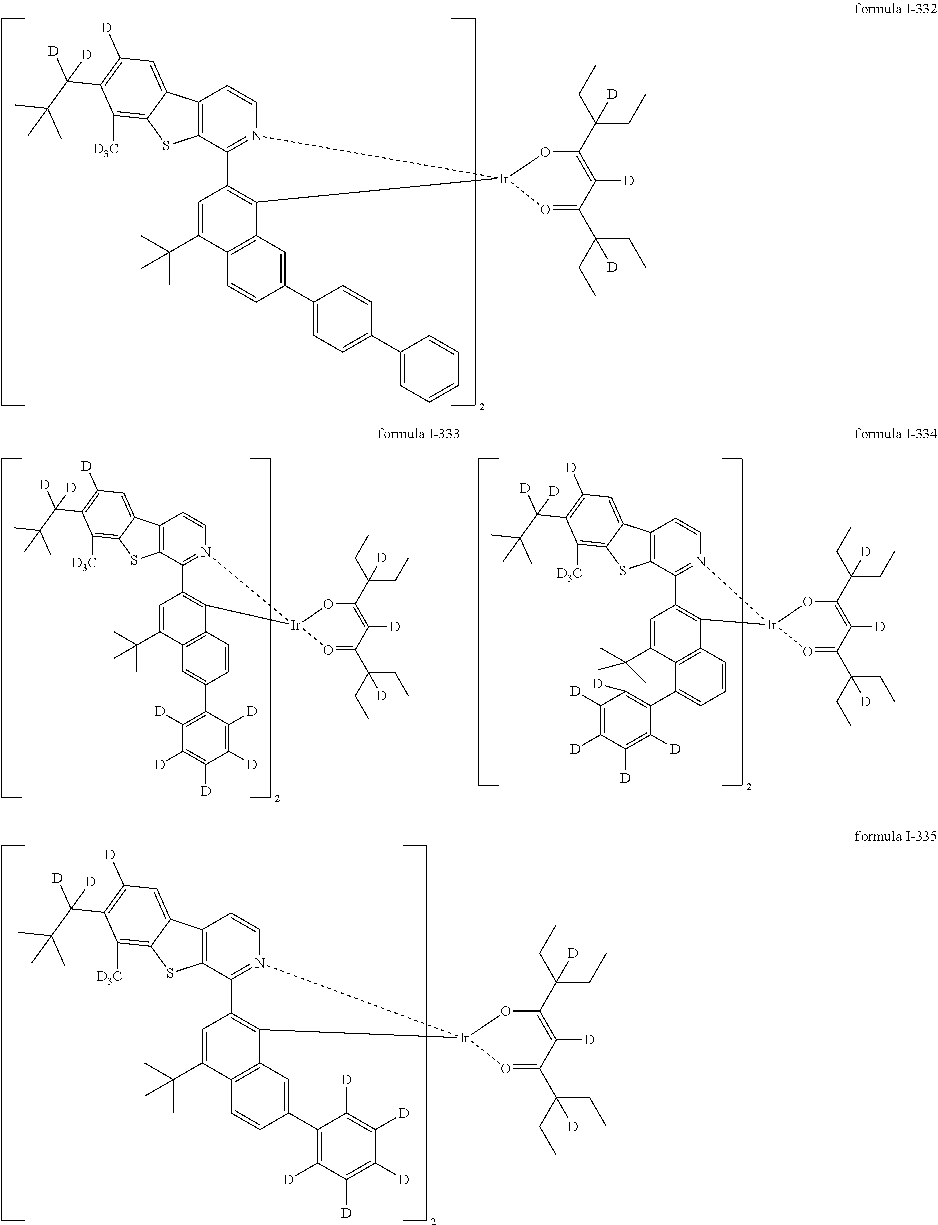

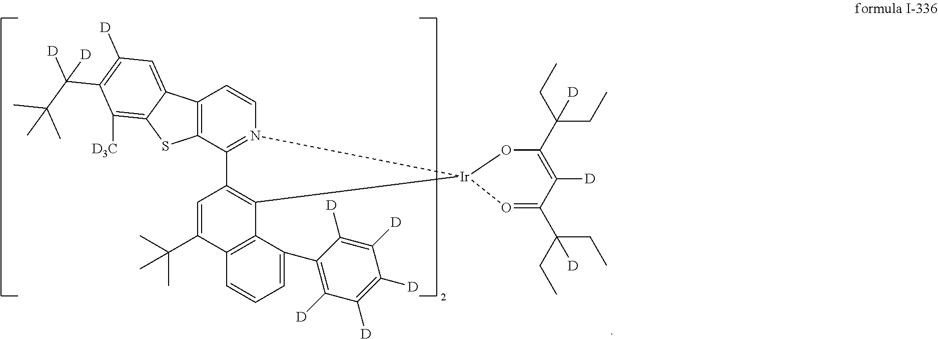

7. An organic electroluminescent device, comprising a first electrode, a second electrode, and an organic material layer located between the first electrode and the second electrode, wherein the organic material layer comprises a hole transport region, an emissive layer, and an electron transport region, and the emissive layer comprises the organic electroluminescent dopant material according to claim 1.

8. The organic electroluminescent device according to claim 7, wherein the hole transport region is a hole transport layer with a single-layer structure, and the hole transport layer with a single-layer structure is a single-layer hole transport layer containing only one compound or a single-layer hole transport layer containing a plurality of compounds; or the hole transport region comprises a multi-layer structure of at least one of a hole injection layer, a hole transport layer, and an electron blocking layer.

9. The organic electroluminescent device according to claim 7, wherein the electron transport region is an electron transport layer with a single-layer structure, and the electron transport layer with a single-layer structure is a single-layer electron transport layer containing only one compound or a single-layer electron transport layer containing a plurality of compounds; or the electron transport region comprises a multi-layer structure of at least one of an electron injection layer, an electron transport layer, and a hole blocking layer.

10. An organic electroluminescent device, comprising a first electrode, a second electrode, and an organic material layer located between the first electrode and the second electrode, wherein the organic material layer comprises a hole transport region, an emissive layer, and an electron transport region, and the emissive layer comprises the organic electroluminescent dopant material according to claim 6.

11. The organic electroluminescent device according to claim 10, wherein the hole transport region is a hole transport layer with a single-layer structure, and the hole transport layer with a single-layer structure is a single-layer hole transport layer containing only one compound or a single-layer hole transport layer containing a plurality of compounds;
or the hole transport region comprises a multi-layer structure of at least one of a hole injection layer, a hole transport layer, and an electron blocking layer.

12. The organic electroluminescent device according to claim 10, wherein the electron transport region is an electron transport layer with a single-layer structure, and the electron transport layer with a single-layer structure is a single-layer electron transport layer containing only one compound or a single-layer electron transport layer containing a plurality of compounds;
or the electron transport region comprises a multi-layer structure of at least one of an electron injection layer, an electron transport layer, and a hole blocking layer.
